(19) United States
(12) Patent Application Publication
(10) Pub. No.: US 2017/0174869 A1
(43) Pub. Date: Jun. 22, 2017

(54) COMPOSITION, METHOD OF MANUFACTURING COMPOSITION, CURABLE COMPOSITION, CURED FILM, NEAR-INFRARED CUT FILTER, SOLID-STATE IMAGING DEVICE, INFRARED SENSOR, AND CAMERA MODULE

(71) Applicant: FUJIFILM Corporation, Tokyo (JP)

(72) Inventors: Kyohei ARAYAMA, Haibara-gun (JP); Takuya TSURUTA, Haibara-gun (JP); Kazutaka TAKAHASHI, Haibara-gun (JP); Tetsuya KAMIMURA, Haibara-gun (JP); Masahiro MORI, Haibara-gun (JP)

(73) Assignee: FUJIFILM Corporation, Tokyo (JP)

(21) Appl. No.: 15/447,335

(22) Filed: Mar. 2, 2017

Related U.S. Application Data
(63) Continuation of application No. PCT/JP2015/074378, filed on Aug. 28, 2015.

(30) Foreign Application Priority Data
Sep. 4, 2014 (JP) 2014-180048
Feb. 24, 2015 (JP) 2015-033794

(51) Int. Cl. C08K 5/55; C08K 5/42; C08K 5/3432; C08K 5/20; C08K 5/435; C08K 5/3447; G03F 7/16; G03F 7/20; G03F 7/32; G03F 7/40; G03F 7/004; G03F 7/033; G03F 7/031; C09B 57/00; G02B 5/20; G02B 5/22; H01L 27/146

(52) U.S. Cl. CPC C08K 5/55; H01L 27/146; H01L 27/14625; C08K 5/42; C08K 5/3432; C08K 5/20; C08K 5/435; C08K 5/3447; G03F 7/162; G03F 7/168; G03F 7/2004; G03F 7/32; G03F 7/40; G03F 7/0045; G03F 7/033; G03F 7/031; C09B 57/00; G02B 5/208; G02B 5/223; C08K 2201/003

(57) ABSTRACT

Provided are a composition of which dispersibility of particles including a pyrrolopyrrole coloring agent is satisfactory, a method of manufacturing a composition, a curable composition, a cured film using a curable composition, a near-infrared cut filter, a solid-state imaging device, an infrared sensor, and a camera module. The composition includes particles including a coloring agent represented by Formula (1), in which an average secondary particle diameter of the particles is 500 nm or less. R^{1a} and R^{1b} each independently represent an alkyl group, an aryl group, or a heteroaryl group, R² and R³ each independently represent a hydrogen atom or a substituent, R² and R³ may be bonded to each other to form a ring, R⁴'s each independently represent a hydrogen atom, an alkyl group, an aryl group, a heteroaryl group, —BR^{4A}R^{4B}, or a metal atom, R⁴'s may form a covalent bond or a coordinate bond with at least one selected form R^{1a}, R^{1b}, or R³, and R^{4A} and R^{4B} each independently represent a hydrogen atom or a substituent.

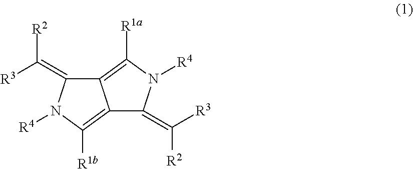

### CROSS-REFERENCE TO RELATED APPLICATIONS

This application is a Continuation of PCT International Application No. PCT/JP2015/074378 filed on Aug. 28, 2015, which claims priority under 35 U.S.C §119(a) to Japanese Patent Application No. 2014-180048 filed on Sep. 4, 2014 and Japanese Patent Application No. 2015-033794 filed on Feb. 24, 2015. Each of the above application(s) is hereby expressly incorporated by reference, in its entirety, into the present application

### BACKGROUND OF THE INVENTION

1. Field of the Invention

The invention relates to a composition including a pyrrolopyrrole coloring agent, a method of manufacturing a composition, a curable composition, a cured film, a near-infrared cut filter, a solid-state imaging device, an infrared sensor, and a camera module.

2. Description of the Related Art

In a video camera, a digital still camera, or a cellular phone with a camera function, a CCD or a CMOS which is a solid-state imaging device for a color image is used. In such a solid-state imaging device, a silicon photodiode having sensitivity to a near-infrared ray in a light receiving section thereof is used. Therefore, visibility correction is required and near-infrared ray absorption filters and the like are used in many cases.

As a compound having a near-infrared ray absorption function, a pyrrolopyrrole coloring agent or the like is known (for example, JP2011-68731A).

In WO2012/102399A, disclosed is a pigment composition including a specific diketopyrrolopyrrole pigment and a pigment derivative.

### SUMMARY OF THE INVENTION

The pyrrolopyrrole coloring agent is a near-infrared absorption coloring agent having absorption at a near-infrared region and excellent invisibility. However, if the pyrrolopyrrole coloring agent is used in a molecular dispersion state in which the pyrrolopyrrole coloring agent is dissolved in a solvent, light fastness tends to decrease. If the pyrrolopyrrole coloring agent is used in a solid dispersion state (dispersion liquid), light fastness enhances, but the pyrrolopyrrole coloring agent tends to have insufficient dispersibility. Therefore, it was found that particles of the pyrrolopyrrole coloring agent became coarse and influenced on pattern formation or the like, in some cases.

In WO2012/102399A, disclosed is a pigment composition including a specific diketopyrrolopyrrole pigment and a pigment derivative, but the specific diketopyrrolopyrrole pigment disclosed in WO2012/102399A is a red pigment and different from a near-infrared absorption coloring agent. In WO2012/102399A, there is no disclosure relating to dispersibility of the pyrrolopyrrole coloring agent.

Accordingly, an object of the invention is to provide a composition in which dispersibility of particles including a pyrrolopyrrole coloring agent is satisfactory. The invention also provides a method of manufacturing a composition, a curable composition including a composition, a cured film using a curable composition, a near-infrared cut filter, a solid-state imaging device, an infrared sensor, and a camera module.

The present inventors diligently conducted research, found that if an average secondary particle diameter of particles is caused to be 500 nm or less, or a coloring agent derivative represented by Formula (2) described below is used in a composition containing particles including a pyrrolopyrrole coloring agent, dispersibility became satisfactory, and completed the invention. The invention provides below.

<1> A composition comprising: particles including a coloring agent represented by Formula (1), in which an average secondary particle diameter of the particles is 500 nm or less,

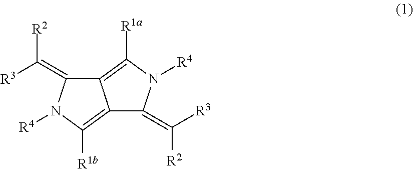

in Formula (1), R^{1a} and R^{1b} each independently represent an alkyl group, an aryl group, or a heteroaryl group, R² and R³ each independently represent a hydrogen atom or a substituent, and R² and R³ may be bonded to each other to form a ring, R⁴'s each independently represent a hydrogen atom, an alkyl group, an aryl group, a heteroaryl group, —BR^{4A}R^{4B}, or a metal atom, and R⁴'s may form a covalent bond or a coordinate bond with at least one selected form R^{1a}, R^{1b}, or R³, and R^{4A} and R^{4B} each independently represent a hydrogen atom or a substituent.

<2> The composition according to <1>, further comprising: a coloring agent derivative represented by Formula (2) below,

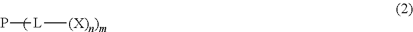

in Formula (2), P represents a coloring agent structure, L represents a single bond or a linking group, X represents an acidic group, a basic group, a group having a salt structure, or a phthalimide group, m represents an integer of 1 or greater, n represents an integer of 1 or greater, and in a case where m is 2 or greater, plural L's and plural X's may be different from each other, and in a case where n is 2 or greater, plural X's may be different from each other.

<3> A composition comprising: a coloring agent represented by Formula (1); and a coloring agent derivative represented by Formula (2) below,

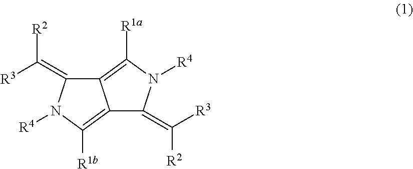

in Formula (1), R^{1a} and R^{1b} each independently represent an alkyl group, an aryl group, or a heteroaryl group,

R² and R³ each independently represent a hydrogen atom or a substituent, and R² and R³ may be bonded to each other to form a ring,

R⁴'s each independently represent a hydrogen atom, an alkyl group, an aryl group, a heteroaryl group, —BR^{4A}R^{4B}, or a metal atom, and R⁴'s may form a covalent bond or a coordinate bond with at least one selected from R^{1a}, R^{1b}, or R³, and

R^{4A} and R^{4B} each independently represent a hydrogen atom or a substituent, and

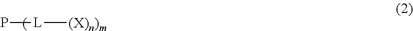

in Formula (2), P represents a coloring agent structure, L represents a single bond or a linking group, X represents an acidic group, a basic group, a group having a salt structure, or a phthalimide group, m represents an integer of 1 or greater, n represents 1 or greater, in a case where m is 2 or greater, plural L's and plural X's may be different from each other, and in a case where n is 2 or greater, plural X's may be different from each other.

<4> The composition according to any one of <1> to <3>, in which the composition has viscosity of 100 mPa·s or less at 25° C.

<5> The composition according to any one of <2> to <4>, in which, in Formula (2), P is at least one selected from a pyrrolopyrrole coloring agent structure, a diketopyrrolopyrrole coloring agent structure, a quinacridone coloring agent structure, an anthraquinone coloring agent structure, a dianthraquinone coloring agent structure, a benzoisoindole coloring agent structure, a thiazine indigo coloring agent structure, an azo coloring agent structure, a quinophthalone coloring agent structure, a phthalocyanine coloring agent structure, a dioxazine coloring agent structure, a perylene coloring agent structure, a perinone coloring agent structure, or a benzimidazolinone coloring agent structure.

<6> The composition according to any one of <2> to <5>, in which, in Formula (2), P is at least one selected from a pyrrolopyrrole coloring agent structure, a diketopyrrolopyrrole coloring agent structure, a quinacridone coloring agent structure, or a benzimidazolinone coloring agent structure.

<7> The composition according to any one of <2> to <6>, in which, in Formula (2), X is at least one selected from a carboxyl group, a sulfo group, a phthalimide group, or groups represented by Formulae (X-1) to (X-9);

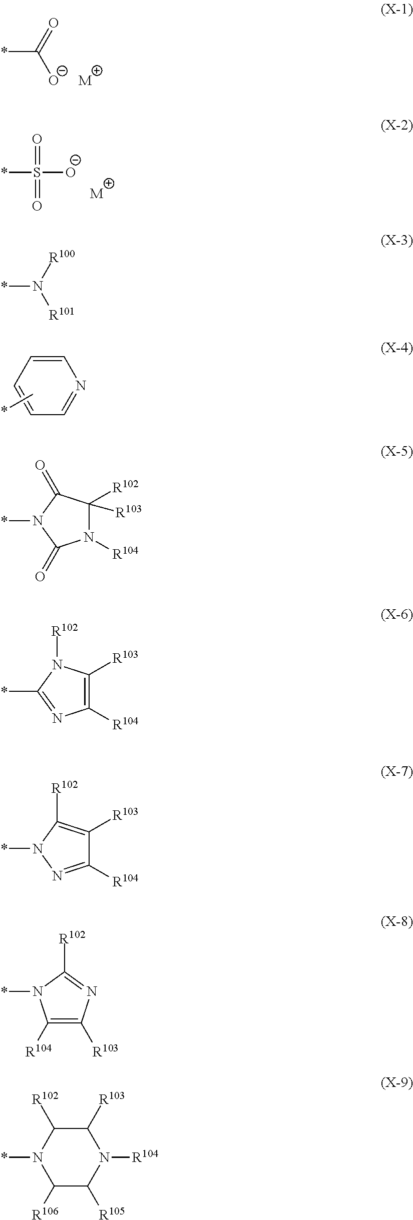

in Formulae (X-1) to (X-9), * represents a coupler hand with L of Formula (2), R¹⁰⁰ to R¹⁰⁶ each independently represent a hydrogen atom, an alkyl group, an alkenyl group, or an aryl group, R¹⁰⁰ and R¹⁰¹ may be linked to each other to form a ring, and M represents an atom or an atomic group that forms an anion or salt.

<8> The composition according to any one of <2> to <7>, in which the coloring agent derivative is a compound represented by Formula (3),

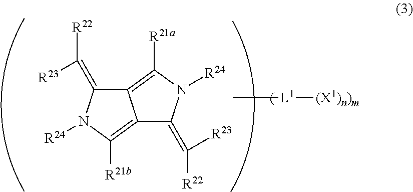

in Formula (3), R^{21a} and R^{21b} each independently represent an alkyl group, an aryl group, or a heteroaryl group,

R²² and R²³ each independently represent a cyano group, an acyl group, an alkoxycarbonyl group, an alkyl group, an arylsulfinyl group, or a heteroaryl group, and R²² and R²³ may be bonded to each other to form a ring,

R²⁴'s each independently represent a hydrogen atom, an alkyl group, an aryl group, a heteroaryl group, —BR^{24A}R^{24B}, or a metal atom, and R²⁴'s may form a covalent bond or a coordinate bond with at least one selected from R^{21a}, R^{21b}, or R²³,

R^{24A} and R^{24B} each independently represent a hydrogen atom, a halogen atom, an alkyl group, an aryl group, or a heteroaryl group,
L¹ represents a single bond or a linking group consisting of an alkylene group, a nitrogen-containing heterocyclic group, —NR′—, —CO—, or —SO₂—, or a combination thereof,

R′ represents a hydrogen atom, an alkyl group, or an aryl group,

X¹ represents an acidic group, a basic group, a group having a salt structure, or a phthalimide group,

m represents an integer of 1 or greater, n represents an integer of 1 or greater, in a case where m is 2 or greater, plural L¹'s and plural X¹'s may be different from each other, and in a case where n is 2 or greater, plural X¹'s may be different from each other.

<9> The composition according to any one of <2> to <8>, in which 1 to 30 parts by mass of the coloring agent derivative represented by Formula (2) with respect to 100 parts by mass of the coloring agent represented by Formula (1) is included.

<10> The composition according to any one of <1> to <9>, in which a maximum absorption wavelength of the coloring agent represented by Formula (1) is in a range of 700 to 1,200 nm.

<11> The composition according to any one of <1> to <10>, in which an average primary particle diameter of particles including a coloring agent represented by Formula (1) is 5 to 100 nm.

<12> The composition according to any one of <1> to <11>, further comprising: at least one selected from a resin, an organic solvent, or a coloring agent different from the coloring agent represented by Formula (1).

<13> A method of manufacturing composition comprising: dispersing a coloring agent represented by Formula (1) and a coloring agent other than the coloring agent represented by Formula (1) in presence of at least one selected from a resin or an organic solvent,

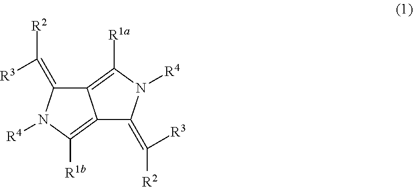

in Formula (1), R^{1a} and R^{1b} each independently represent an alkyl group, an aryl group, or a heteroaryl group,

R² and R³ each independently represent a hydrogen atom or a substituent, and R² and R³ may be bonded to each other to form a ring,

R⁴'s each independently represent a hydrogen atom, an alkyl group, an aryl group, a heteroaryl group, —BR^{4A}R^{4B}, or a metal atom, and R⁴'s may form a covalent bond or a coordinate bond with at least one selected from R^{1a}, R^{1b}, or R³, and R^{4A} and R^{4B} each independently represent a hydrogen atom or a substituent.

<14> The method of manufacturing a composition according to <13>, in which the dispersion is further performed in presence of a coloring agent derivative represented by Formula (2),

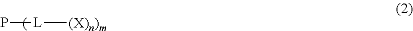

in Formula (2), P represents a coloring agent structure, L represents a single bond or a linking group, X represents an acidic group, a basic group, a group having a salt structure, or a phthalimide group, m represents an integer of 1 or greater, n represents an integer of 1 or greater, in a case where m is 2 or greater, plural L's and plural X's may be different from each other, and in a case where n is 2 or greater, plural X's may be different from each other.

<15> A curable composition comprising: the composition according to any one of <1> to <12>; and a curable compound.

<16> The curable composition according to <15>, further comprising: a photopolymerization initiator, in which the curable compound is a polymerizable compound.

<17> A cured film obtained by hardening the curable composition according to <15> or <16>.

<18> A near-infrared cut filter obtained by using the curable composition according to <15> or <16>.

<19> A solid-state imaging device comprising: a cured film obtained by using the curable composition according to <15> or <16>.

<20> An infrared sensor comprising: a cured film obtained by using the curable composition according to <15> or <16>.

<21> A camera module comprising: a solid-state imaging device; and the near-infrared cut filter according to <18>.

<22> A compound represented by Formula (3) below,

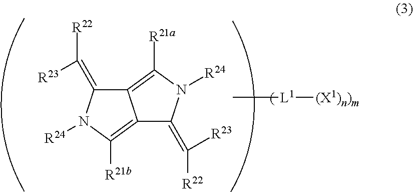

in Formula (3), R^{21a} and R^{21b} each independently represent an alkyl group, an aryl group, or a heteroaryl group,

R²² and R²³ each independently represent a cyano group, an acyl group, an alkoxycarbonyl group, an alkyl group, an arylsulfinyl group, or a heteroaryl group, and R²² and R²³ may be bonded to each other to form a ring,

R²⁴'s each independently represent a hydrogen atom, an alkyl group, an aryl group, a heteroaryl group, —BR^{24A}R^{24B}, or a metal atom, and R²⁴'s may form a covalent bond or a coordinate bond with at least one selected from R^{21a}, R^{21b}, or R²³,

R^{24A} and R^{24B} each independently represent a hydrogen atom, a halogen atom, an alkyl group, an aryl group, or a heteroaryl group,

L¹ represents a single bond or a linking group consisting of an alkylene group, a nitrogen-containing heterocyclic group, —NR′—, —CO—, or —SO₂—, or a combination thereof,

R′ represents a hydrogen atom, an alkyl group, or an aryl group,

X¹ represents an acidic group, a basic group, a group having a salt structure, or a phthalimide group,

m represents an integer of 1 or greater, n represents an integer of 1 or greater, in a case where m is 2 or greater, plural L¹'s and plural X¹'s may be different from each other, and in a case where n is 2 or greater, plural X¹'s may be different from each other.

According to the invention, it is possible to provide a composition in which dispersibility of particles including a pyrrolopyrrole coloring agent is satisfactory. Also, if this composition is used, satisfactory pattern shape can be formed. The invention can provide a method of manufacturing a composition, a curable composition, a cured film, a near-infrared cut filter, a solid-state imaging device, an infrared sensor, and a camera module.

### BRIEF DESCRIPTION OF THE DRAWINGS

FIG. 1 is a diagram schematically illustrating a configuration of an infrared sensor according to an embodiment of the invention.

FIG. 2 is a block diagram illustrating functions of an image pick-up device to which an infrared sensor according to the invention is applied.

### DESCRIPTION OF THE PREFERRED EMBODIMENTS

Hereinafter, the content of the invention is described in detail. In this specification, the expression “to” is used in a meaning of including numerical values indicated before and after the expression as a lower limit and an upper limit.

In this specification, “(meth)acrylate” represents both or any one of “acrylate” and “methacrylate”, “(meth)acryl” represents both or any one of “acryl” and “methacryl”, “(meth)allyl” represents both or any one of “allyl” and “methallyl”, and “(meth)acryloyl” represents both or any one of “acryloyl” and “methacryloyl”.

In the description of a group (atomic group) in this specification, a denotation without substitution and unsubstitution include a group with a substituent, together with a group without a substituent. For example, an “alkyl group” includes not only an alkyl group (unsubstituted alkyl group) without a substituent but also an alkyl group (substituted alkyl group) with a substituent.

In the description of a group (atomic group) in this specification, a denotation without substitution and unsubstitution include a group (atomic group) with a substituent, together with a group (atomic group) without a substituent.

In this specification, Me in a chemical formula represents a methyl group, Et represents an ethyl group, Pr represents a propyl group, Bu represents a butyl group, and Ph represents a phenyl group.

In this specification, a near-infrared ray refers to light having a wavelength range of 700 to 2,500 nm (electromagnetic wave).

In this specification, a total solid content refers to a total mass of components except for a solvent from the entire content of a composition.

In this specification, a solid content is a solid content at 25° C.

In this specification, a weight-average molecular weight is defined as a value in terms of polystyrene by GPC measurement. In this specification, a weight-average molecular weight (Mw) and a number-average molecular weight (Mn) can be obtained, for example, by using HLC-8220 (manufactured by Tosoh Corporation), using TSK gel Super AWM-H (manufactured by Tosoh Corporation, 6.0 mm ID×15.0 cm) as a column, and using a 10 mmol/L lithium bromide NMP (N-methylpyrrolidinone) solution as an eluent.

<Composition>

A first composition according to the invention contains particles including a coloring agent represented by Formula (1), and an average secondary particle diameter of the particles described above is 500 nm or less. If an average secondary particle diameter of the particles including the coloring agent represented by Formula (1) is 500 nm or less, the composition according to the invention can become a composition having satisfactory dispersibility. If the composition according to the invention is used, a satisfactory pattern shape can be formed.

A second composition according to the invention is a composition containing the coloring agent represented by Formula (1) and a coloring agent derivative represented by Formula (2). If the composition according to the invention contains the coloring agent represented by Formula (1) and a coloring agent derivative represented by Formula (2), the composition according to the invention can be a composition having satisfactory dispersibility.

In the second composition according to the invention, an average secondary particle diameter of the particles including the coloring agent represented by Formula (1) is preferably 500 nm or less.

Examples of the method of causing an average secondary particle diameter of the particles to be 500 nm or less include a method of using a coloring agent derivative, a method of using a dispersed resin, a method of using a dispersing solvent having high compatibility with a stereo repulsive chain of a dispersed resin, a method of increasing dispersion strength of particles (for example, increasing dispersion time, increasing dispersion temperature, and using particles having a smaller dispersion bead diameter), and a method of a combination thereof. Examples thereof also include a method of dispersing the coloring agent represented by Formula (1) and a coloring agent different from the coloring agent represented by Formula (1) at the same time (also referred to as codispersion).

Among these, dispersibility of the particles can be increased by using a coloring agent derivative represented by Formula (2) described below, and an average secondary particle diameter can be easily adjusted to 500 nm or less. Particularly, the dispersibility of the particles can be further increased by using a coloring agent derivative represented by Formula (2) and codispersing the coloring agent represented by Formula (1) and a coloring agent different from the coloring agent represented by Formula (1). Further, thixotropy can be suppressed to be low. In a case where the coloring agent represented by Formula (1) and a coloring agent different from the coloring agent represented by Formula (1) are codispersed, an average secondary particle diameter of the particles including a coloring agent included in the entire composition may be 500 nm or less. Here, the thixotropy means a phenomenon in which viscosity decreases as shear force increases, when shear force is applied to a fluid. According to the invention, the expression “thixotropy is low” means that a viscosity change of the fluid is small, when shear force applied to fluid is increased.

According to the invention, an average primary particle diameter of the particles including the coloring agent represented by Formula (1) is preferably 5 to 100 nm. The upper limit is preferably 90 nm or less and more preferably 80 nm or less. The lower limit is preferably 10 nm or greater and more preferably 15 nm or greater. If the average primary particle is in this range, dispersion stability and pattern forming properties are satisfactory. Examples of the method of decreasing the primary particle diameter of the particles include a milling treatment. The milling treatment is a method of mechanically kneading particles, water soluble inorganic salt, and an organic solvent, crushing particles, and removing water soluble inorganic salt and an organic solvent by washing. In the milling treatment, if a coloring agent derivative or a resin is used together, particles hardly aggregate, and an average secondary particle diameter can be reduced.

According to the invention, an average secondary particle diameter of the particles including the coloring agent represented by Formula (1) is 500 nm or less, preferably 400 nm or less, and more preferably 300 nm or less. The lower limit is preferably 10 nm or greater and more preferably 20 nm or greater.

In this specification, the average secondary particle diameter means an average particle diameter with respect to secondary particles obtained by gathering primary particles (single crystal) of a coloring agent.

According to the invention, an average primary particle diameter and an average secondary particle diameter are values obtained by methods described in the example below.

In the composition according to the invention, viscosity at 25° C. is preferably 100 mPa·s or less, more preferably 50 mPa·s or less, and even more preferably 20 mPa·s or less. The lower limit is preferably 0.1 mPa·s or greater, more preferably 0.5 mPa·s or greater, and even more preferably 1 mPa·s or greater.

Hereinafter, respective components of the composition according to the invention are described.

<<Coloring Agent Represented by Formula (1)>>

The composition according to the invention contains particles including the coloring agent represented by Formula (1). The maximum absorption wavelength of the coloring agent represented by Formula (1) is preferably in the range of 700 to 1,200 nm, more preferably in the range of 700 to 1,000 nm, even more preferably in the range of 730 to 980 nm, and still even more preferably in the range of 750 to 950 nm. If the maximum absorption wavelength is in the range described above, the coloring agent has excellent visible transmittance. The maximum absorption wavelength is designed according to required performances of an optical device such as a solid-state imaging device or an infrared sensor described below.

First, the coloring agent represented by Formula (1) is described.

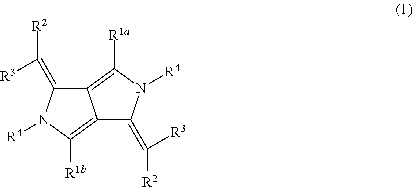

In Formula (1), R^{1a} and R^{1b} each independently represent an alkyl group, an aryl group, or a heteroaryl group, R² and R³ each independently represent a hydrogen atom or a substituent, R² and R³ are bonded to each other to form a ring, R⁴'s represent a hydrogen atom, an alkyl group, an aryl group, a heteroaryl group, —BR^{4A}R^{4B}, or a metal atom, R⁴'s may form a covalent bond or a coordinate bond with at least one selected from R^{1a}, R^{1b}, or R³, and R^{4A} and R^{4B} each independently represent a hydrogen atom or a substituent.

In Formula (1), the number of carbon atoms of an alkyl group represented by R^{1a} or R^{1b} is preferably 1 to 30, more preferably 1 to 20, and particularly preferably 1 to 10.

The number of carbon atoms of an aryl group represented by R^{1a} or R^{1b} is preferably 6 to 30, more preferably 6 to 20, and particularly preferably 6 to 12.

The number of carbon atoms of the heteroaryl group represented by R^{1a} or R^{1b} is preferably 1 to 30 and more preferably 1 to 12. Examples of the heteroatom include a nitrogen atom, an oxygen atom, and a sulfur atom.

A group represented by R^{1a} or R^{1b} is preferably an aryl group having an alkoxy group having a branched alkyl group as a substituent or an aryl group having a hydroxyl group as a substituent. The number of carbon atoms of the branched alkyl group is preferably 3 to 30 and more preferably 3 to 20.

Examples of the group represented by R^{1a} or R^{1b} include 4-(2-ethylhexyloxy)phenyl, 4-(2-methylbutyloxy)phenyl, 4-(2-octyldodecyloxy)phenyl, and 4-hydroxyphenyl.

R^{1a} and R^{1b} in Formula (1) may be identical to or different from each other.

R² and R³ each independently represent a hydrogen atom or a substituent. R² and R³ are bonded to each other to form a ring. At least one of R² or R³ is preferably an electron-withdrawing group. It is preferable that R² and R³ each independently represent a cyano group or a heteroaryl group.

Examples of the substituent include substituents disclosed in paragraph numbers 0020 to 0022 of JP2009-263614A. The contents are incorporated to this specification.

Examples of the substituent include a substituent T below.

(Substituent T)

An alkyl group (preferably having 1 to 30 carbon atoms), an alkenyl group (preferably having 2 to 30 carbon atoms), an alkynyl group (preferably having 2 to 30 carbon atoms), an aryl group (preferably having 6 to 30 carbon atoms), an amino group (preferably having 0 to 30 carbon atoms), an alkoxy group (preferably having 1 to 30 carbon atoms), an aryloxy group (preferably having 6 to 30 carbon atoms), a heteroaryloxy group (preferably having 1 to 30 carbon atoms), an acyl group (preferably having 1 to 30 carbon atoms), an alkoxycarbonyl group (preferably 2 to 30 carbon atoms), an aryloxycarbonyl group (preferably having 7 to 30 carbon atoms), an acyloxy group (preferably having 2 to 30 carbon atoms), an acylamino group (preferably having 2 to 30 carbon atoms), an alkoxycarbonylamino group (preferably having 2 to 30 carbon atoms), an aryloxycarbonylamino group (preferably having 7 to 30 carbon atoms), a sulfonylamino group (preferably having 1 to 30 carbon atoms), a sulfamoyl group (preferably having 0 to 30 carbon atoms), a carbamoyl group (preferably having 1 to 30 carbon atoms), an alkylthio group (preferably having 1 to 30 carbon atoms), an arylthio group (preferably having 6 to 30 carbon atoms), a heteroarylthio group (preferably having 1 to 30 carbon atoms), an alkylsulfonyl group (preferably having 1 to 30 carbon atoms), an arylsulfonyl group (preferably having 6 to 30 carbon atoms), an alkylsulfinyl group (preferably having 1 to 30 carbon atoms), arylsulfinyl group (preferably having 6 to 30 carbon atoms), an ureido group (preferably having 1 to 30 carbon atoms), a phosphoric acid amide group (preferably having 1 to 30 carbon atoms), a hydroxy group, a mercapto group, a halogen atom, a cyano group, a sulfo group, a carboxyl group, a nitro group, a hydroxamic acid group, a sulfino group, a hydrazino group, an imino group, and a heteroaryl group (preferably having 1 to 30 carbon atoms).

At least one of R² or R³ is preferably an electron-withdrawing group. A substituent of which an σp value of Hammett (sigma para value) is positive functions as an electron-withdrawing group.

According to the invention, a substituent having a σp value of Hammett of 0.2 or greater can be exemplified as an electron-withdrawing group. A σp value is preferably 0.25 or greater, more preferably 0.3 or greater, and particularly preferably 0.35 or greater. The upper limit is not particularly limited, but preferably 0.80.

Specific examples thereof include a cyano group (0.66), a carboxyl group (—COOH: 0.45), an alkoxycarbonyl group (—COOMe: 0.45), an aryloxycarbonyl group (—COOPh: 0.44), a carbamoyl group (—CONH₂: 0.36), an alkylcarbonyl group (—COMe: 0.50), an arylcarbonyl group (—COPh: 0.43), an alkylsulfonyl group (—SO₂Me: 0.72), or an arylsulfonyl group (—SO₂Ph: 0.68). Particularly preferably, an example is a cyano group. Here, Me represents a methyl group, and Ph represents a phenyl group.

As a substituent constant c value of Hammett, for example, paragraphs 0017 to 0018 of JP2011-68731A can be referred to, and the content thereof are incorporated to this specification.

In a case where R² and R³ are bonded to each other to form a ring, it is preferable to form a 5-membered to 7-membered ring (preferably 5-membered or 6-membered ring). As the formed ring, a ring that is generally used as an acid nucleus in a merocyanine coloring agent is preferable. As specific examples, for example, paragraphs 0019 to 0021 of JP2011-68731A can be referred to, and the contents thereof are incorporated to this specification.

R³ is particularly preferably a heteroaryl group. The heteroaryl group is preferably a 5-membered ring or a 6-membered ring. The heteroaryl group is preferably a single ring or a fused ring, preferably a single ring or a fused ring having a fused number of 2 to 8, and more preferably a single ring or a fused ring having a fused number of 2 to 4. The number of heteroatoms included in a heteroaryl group is preferably 1 to 3 and more preferably 1 to 2. As the heteroatom, a nitrogen atom, an oxygen atom, and a sulfur atom are exemplified. As a heteroaryl group, a quinoline group, a quinoxaline group, a benzothiazole group, and a naphthothiazole group are preferable, and a benzothiazole group is more preferable. The heteroaryl group may have a substituent or may not be substituted. Examples of the substituent include groups exemplified in the substituent T above. Examples thereof include an alkyl group, an alkoxy group, and a halogen atom.

Two R²'s in Formula (1) may be identical to each other or two R³'s may be identical to or different from each other.

In a case where R⁴'s represent an alkyl group, an aryl group, or a heteroaryl group, the alkyl group, the aryl group, and the heteroaryl group are the same as those described in R^{1a} and R^{1b}, and preferable ranges thereof are also the same.

In a case where R⁴'s represent —BR^{4A}R^{4B}, R^{4A} and R^{4B} each independently represent a hydrogen atom or a substituent, and R^{4A} and R^{4B} are bonded to each other to form a ring. Examples of the substituent represented by R^{4A} and R^{4B} include the substituent T described above. A halogen atom, an alkyl group, an alkoxy group, an aryl group, and a heteroaryl group are preferable, an alkyl group, an aryl group, and a heteroaryl group are more preferable, and an aryl group is particularly preferable. Specific examples of the group represented by —BR^{4A}R^{4B} include difluoroboron, diphenylboron, dibutylboron, dinaphthylboron, and catecholboron. Among these, diphenylboron is particularly preferable.

In a case where R⁴'s represent a metal atom, examples of the metal atom include magnesium, aluminum, calcium, barium, zinc, tin, vanadium, iron, cobalt, nickel, copper, palladium, iridium, and platinum, and particularly preferably aluminum, zinc, vanadium, iron, copper, palladium, iridium, and platinum.

R⁴'s may form a covalent bond or a coordinate bond with at least one of R^{1a}, R^{1b}, or R³, and R⁴ particularly preferably forms a coordinate bond with R³.

R⁴ is preferably a hydrogen atom or a group represented by —BR^{4A}R^{4B} (particularly, diphenylboron).

Two R⁴'s in Formula (1) may be identical to or different from each other.

The compound represented by Formula (1) is preferably a compound represented by any one of Formulae (1a), (1b), and (1c) below.

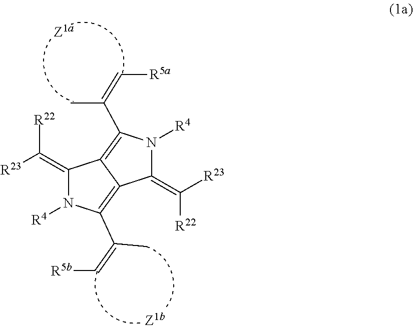

In Formula (1a), Z^{1a} and Z^{1b} each independently represent an atomic group that forms an aryl ring or a heteroaryl ring. R^{5a} and R^{5b} each independently represent an aryl group having 6 to 20 carbon atoms, a heteroaryl group having 4 to 20 carbon atoms, an alkyl group having 1 to 20 carbon atoms, an alkoxy group having 1 to 20 carbon atoms, an alkoxycarbonyl group having 1 to 20 carbon atoms, a carboxyl group, a carbamoyl group having 1 to 20 carbon atoms, a halogen atom, or a cyano group, and R^{5a} or R^{5b} and Z^{1a} or Z^{1b} may be bonded to each other to form a fused ring. R²² and R²³ each independently represent a cyano group, an acyl group having 1 to 6 carbon atoms, an alkoxycarbonyl group having 1 to 6 carbon atoms, an alkyl or arylsulfinyl group having 1 to 10 carbon atoms, or a nitrogen-containing heteroaryl group having 3 to 20 carbon atoms. R²² and R²³ may be bonded to each other to form a cyclic acid nucleus. R⁴'s represent a hydrogen atom, an alkyl group having 1 to 20 carbon atoms, an aryl group having 6 to 20 carbon atoms, a heteroaryl group having 4 to 20 carbon atoms, —BR^{4A}R^{4B}, or a metal atom, R⁴'s may form a covalent bond or a coordinate bond with at least one selected from R^{1a}, R^{1b}, or R³, R^{4A} and R^{4B} each independently represent a hydrogen atom, a halogen atom, an alkyl group having 1 to 10 carbon atoms, an alkoxy group having 1 to 10 carbon atoms, an aryl group having 6 to 20 carbon atoms, or a heteroaryl group having 4 to 20 carbon atoms.

In Formula (1a), Z^{1a} and Z^{1b} each independently represent an atomic group that forms an aryl ring or a heteroaryl ring. The formed aryl ring or the formed heteroaryl ring are the same as the aryl group and the heteroaryl group described as the substituent of R² and R³ in Formula (1), and preferable ranges thereof are also the same. Z^{1a} and Z^{1b} are preferably identical to each other.

R^{5a} and R^{5b} are the same as those described in R² and R³ in Formula (1), and preferable ranges thereof are also the same. It is preferable that R^{5a} and R^{5b} are the same.

R^{5a} or R^{5b} and Z^{1a} or Z^{1b} may be bonded to each other to form a fused ring, and examples of the fused ring include a naphthyl ring and a quinoline ring. Invisibility can be greatly increased by introducing a group represented by R^{5a} or R^{5b} to an aryl ring or a heteroaryl ring formed by Z^{1a} or Z^{1b}.

R²² and R²³ are the same as those described in R² and R³ in Formula (1), and preferable ranges thereof are also the same.

R⁴ is the same as R⁴ in Formula (1), and preferable ranges are also the same. R⁴'s may also have a covalent bond or a coordinate bond with R²³.

The compound represented by Formula (1a) may further have a substituent, and the substituent is the same as the substituents of R² and R³, and preferable ranges are also the same.

A preferable combination in Formula (1a) is a case where Z^{1a} and Z^{1b} each independently form a benzene ring or a pyridine ring, R^{5a} and R^{5b} each independently represent an alkyl group, an alkoxy group, a halogen atom, or a cyano group, R²² and R²³ each independently represent a heteroaryl group, a cyano group, an acyl group, and an alkoxycarbonyl group, R²² and R²³ are bonded to each other to form a cyclic acid nucleus, and R⁴'s represent a hydrogen atom, —BR^{4A}R^{4B}, a metal atom, magnesium, aluminum, calcium, barium, zinc, or tin. A particularly preferable combination is a case where both of Z^{1a} and Z^{1b} form benzene rings, both of R^{5a} and R^{5b} are alkyl groups, halogen atoms, or cyano groups, R²² and R²³ each independently represent a combination of a nitrogen-containing heteroaryl group and a cyano group or an alkoxycarbonyl group, R²² and R²³ are bonded to each other to form a cyclic acid nucleus, and R⁴'s represent a hydrogen atom, —BR^{4A}R^{4B}, aluminum, zinc, vanadium, iron, copper, palladium, iridium, and platinum.

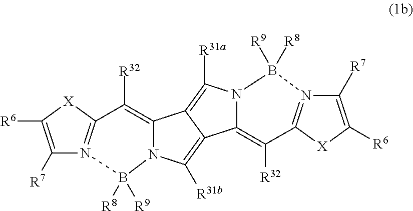

In Formula (1b), R^{31a} and R^{31b} each independently represent an alkyl group having 1 to 20 carbon atoms, an aryl group having 6 to 20 carbon atoms, or a heteroaryl group having 3 to 20 carbon atoms. R³² represents a cyano group, an acyl group having 1 to 6 carbon atoms, an alkoxycarbonyl group having 1 to 6 carbon atoms, an alkyl or arylsulfinyl group having 1 to 10 carbon atoms, or a nitrogen-containing heteroaryl group having 3 to 10 carbon atoms. R⁶ and R⁷ each independently represent a hydrogen atom, an alkyl group having 1 to 10 carbon atoms, an aryl group having 6 to 10 carbon atoms, or a heteroaryl group having 4 to 10 carbon atoms. R⁶ and R⁷ may be bonded to each other to form a fused ring. As the formed ring, a alicyclic ring having 5 to 10 carbon atoms, an aryl ring having 6 to 10 carbon atoms, or a heteroaryl ring having 3 to 10 carbon atoms is preferable. R⁸ and R⁹ each independently represent an alkyl group having 1 to 10 carbon atoms, an alkoxy group having 1 to 10 carbon atoms, an aryl group having 6 to 20 carbon atoms, or a heteroaryl group having 3 to 10 carbon atoms. X represents an oxygen atom, a sulfur atom, —NR—, and —CRR′—, R and R′ represents a hydrogen atom, an alkyl group having 1 to 10 carbon atoms, or an aryl group having 6 to 10 carbon atoms.

In Formula (1b), R^{31a} and R^{31b} are the same as those described in R^{1a} and R^{1b} in Formula (1), and preferable ranges thereof are also the same. R^{31a} and R^{31b} are preferably the same.

R³² is the same as examples of R² in Formula (1), and preferable ranges thereof are also the same.

R⁶ and R⁷ are the same as examples of substituent of R² and R³ in Formula (1), and preferable ranges thereof are also the same. R⁶ and R⁷ are bonded to each other to form a ring, examples of the formed ring include an alicyclic ring having 5 to 10 carbon atoms, an aryl ring having 6 to 10 carbon atoms, a heteroaryl ring having 3 to 10 carbon atoms, and preferable examples thereof include a benzene ring, a naphthalene ring, and a pyridine ring. If R⁶ and R⁷ are caused to be a boron complex by introducing substituted 5-membered nitrogen-containing heteroaryl, it is possible to realize an infrared absorption coloring agent in which high fastness and high invisibility are compatible with each other.

R⁸ and R⁹ are the same as the substituents of R² and R³ in Formula (1), and preferable ranges thereof are also the same.

X represents an oxygen atom, a sulfur atom, —NR—, or —CRR′—. R and R′ each independently represent a hydrogen atom, an alkyl group having 1 to 10 carbon atoms, or an aryl group having 6 to 10 carbon atoms, and preferably a hydrogen atom, an alkyl group having 1 to 6 carbon atoms, or a phenyl group.

A preferable combination in Formula (1b) is a case where R^{31a} and R^{31b} each independently represent an alkyl group having 1 to 10 carbon atoms, a benzene ring, or a pyridine ring, R³² is a cyano group or an alkoxycarbonyl group, R⁶ and R⁷ are bonded to each other to form a benzene ring, a pyridine ring, a pyrazine ring, or a pyrimidine ring, R⁸ and R⁹ each independently represent an alkyl group having 1 to 6 carbon atoms, a phenyl group, and a naphthyl group, X is an oxygen atom, a sulfur atom, —NR—, or —CRR′—, R and R′ each independently represent a hydrogen atom, an alkyl group having 1 to 6 carbon atoms, and a phenyl group. A particularly preferable combination is a case where both of R^{31a} and R^{31b} are an alkyl group having 1 to 10 carbon atoms or a benzene ring, R³² is a cyano group, R⁶ and R⁷ are bonded to each other to form a benzene ring or a pyridine ring, R⁸ and R⁹ each independently represent an alkyl group having 1 to 6 carbon atoms, a phenyl group, a naphthyl group, and X represents oxygen or sulfur.

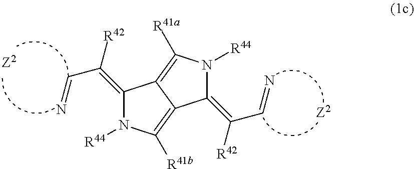

In Formula (1c), R^{41a} and R^{41b} represent groups which are different from each other, and represent an alkyl group having 1 to 20 carbon atoms, an aryl group having 6 to 20 carbon atoms, or a heteroaryl group having 3 to 20 carbon atoms. R⁴² represents a cyano group, an acyl group having 1 to 6 carbon atoms, an alkoxycarbonyl group having 1 to 6 carbon atoms, an alkyl or arylsulfinyl group having 1 to 10 carbon atoms, or a nitrogen-containing heteroaryl group having 3 to 10 carbon atoms. Z² represents an atomic group that forms a nitrogen-containing 5-membered or 6-membered heterocyclic ring together with —C═N—, and represents a pyrazole ring, a thiazole ring, an oxazole ring, an imidazole ring, an oxadiazole ring, a thiadiazole ring, a triazole ring, a pyridine ring, a pyridazine ring, a pyrimidine ring, or a pyrazine ring; a benzo fused ring or a naphtho fused ring thereof; or a complex of these fused rings, as nitrogen-containing heteroaryl. R⁴⁴ represents a hydrogen atom, an alkyl group having 1 to 20 carbon atoms, an aryl group having 6 to 20 carbon atoms, a heteroaryl group having 4 to 20 carbon atoms, a metal atom, a halogen atom as a substituent, an alkyl group having 1 to 10 carbon atoms, an aryl group having 6 to 20 carbon atoms, —BR^{44A}R^{44B}, or a metal atom, R⁴⁴ may have a covalent bond or a coordinate bond with nitrogen-containing heteroaryl formed by Z², and R^{44A} and R^{44B} each independently represent a hydrogen atom, a halogen atom, an alkyl group having 1 to 10 carbon atoms, an aryl group having 6 to 20 carbon atoms, or a heteroaryl group having 4 to 20 carbon atoms.

In Formula (1c), R^{41a} and R^{41b} are the same as those described in R^{1a} and R^{1b} in Formula (1), and preferable ranges thereof are also the same. Here, R^{41a} and R^{41b} represent groups different from each other.

R⁴² is the same as examples of R² in Formula (1), and preferable ranges thereof are also the same.

Z² represents an atomic group that forms a nitrogen-containing 5-membered or 6-membered heterocyclic ring with —C═N— and represents a pyrazole ring, a thiazole ring, an oxazole ring, an imidazole ring, an oxadiazole ring, a thiadiazole ring, a triazole ring, a pyridine ring, a pyridazine ring, a pyrimidine ring, or a pyrazine ring; a benzo fused ring or a naphtho fused ring thereof; or a complex of these fused rings, as nitrogen-containing heteroaryl.

R⁴⁴ represents a hydrogen atom, an alkyl group having 1 to 20 carbon atoms, an aryl group having 6 to 20 carbon atoms, a heteroaryl group having 4 to 20 carbon atoms, a metal atom, a halogen atom as a substituent, an alkyl group having 1 to 10 carbon atoms, an aryl group having 6 to 20 carbon atoms, —BR^{44A}R^{44B}, or a metal atom, R⁴⁴ may have a covalent bond or a coordinate bond with nitrogen-containing heteroaryl formed by Z², and R^{44A} and R^{44B} each independently represent a hydrogen atom, a halogen atom, an alkyl group having 1 to 10 carbon atoms, an aryl group having 6 to 20 carbon atoms, or a heteroaryl group having 4 to 20 carbon atoms.

If a nitrogen-containing 5-membered or 6-membered heterocyclic ring formed by Z² with —C═N— is introduced by introducing groups represented by R^{41a} and R^{41b} different from each other, it is possible to provide high fastness, high invisibility, excellent dispersibility, and high organic solvent solubility.

A preferable combination in Formula (1c) is a case where R^{41a} and R^{41b} each independently represent an alkyl group having 1 to 10 carbon atoms, a benzene ring, or a pyridine ring, R⁴² represents a cyano group, an alkyl or arylsulfinyl group having 1 to 10 carbon atoms, or an alkoxycarbonyl group, Z² forms a thiazole ring, an oxazole ring, an imidazole ring, a thiadiazole ring, a triazole ring, a pyridine ring, a pyrimidine ring, or a pyrazine ring; or a benzo fused ring or a naphtho fused ring thereof with —C═N—, R⁴⁴ represents a hydrogen atom, substituted boron, a transition metal atom, magnesium, aluminum, calcium, barium, zinc, or tin. A particularly preferable combination is a case where R^{41a} and R^{41b} each independently represent an alkyl group having 1 to 10 carbon atoms or a benzene ring, R⁴² represents a cyano group, and Z² forms a thiazole ring, an oxazole ring, an imidazole ring, a triazole ring, a pyridine ring, or a pyrimidine ring; or a benzo fused ring or a naphtho fused ring thereof, with —C═N—, and R⁴⁴ is a hydrogen atom, —BR^{44A}R^{44B} (an alkyl group having 1 to 10 carbon atoms as R^{44A}R^{44B}, a benzene ring, a pyridine ring, or a thiophene ring), aluminum, zinc, vanadium, iron, copper, palladium, iridium, or platinum.

The coloring agent represented by Formula (1) is more preferably a coloring agent represented by Formula (1A) below.

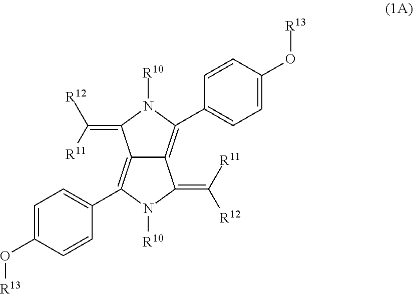

In the formula, R¹⁰'s each independently represent a hydrogen atom, an alkyl group, an aryl group, a heteroaryl group, —BR^{14A}R^{14B}, or a metal atom. R¹⁰ may form a covalent bond or a coordinate bond with R¹². R¹¹ and R¹² each independently represent a hydrogen atom or a substituent, and at least one of R¹¹ or R¹² is a cyano group, R¹¹ and R¹² may be bonded to each other to form a ring. R¹³'s each independently represent a hydrogen atom or a branched alkyl group having 3 to 30 carbon atoms.

R¹⁰ is the same as R⁴ described in Formula (1), and preferable ranges thereof are also the same. A hydrogen atom or a group represented by —BR^{14A}R^{14B} (particularly diphenylboron) is preferable, and a group represented by —BR^{14A}R^{14B} is particularly preferable.

R¹¹ and R¹² are the same as R² and R³ described in (1) above, and preferable ranges thereof are also the same. It is more preferable that any one of R¹¹ and R¹² is a cyano group, and the other is a heteroaryl group.

R^{14A} and R^{14B} are the same as R^{4A} and R^{4B} described in (1), and preferable ranges thereof are also the same.

R¹³'s each independently represent a hydrogen atom or a branched alkyl group having 3 to 30 carbon atoms, and the number of carbon atoms of the branched alkyl group is more preferably 3 to 20.

Specific examples of the compound represented by Formula (1) include compounds below. For example, paragraphs 0037 to 0052 of JP2011-68731A ([0070] of corresponding US2011/0070407A), and the contents thereof are incorporated to this specification. In a structural formula below, Me represents a methyl group, and Ph represents a phenyl group.

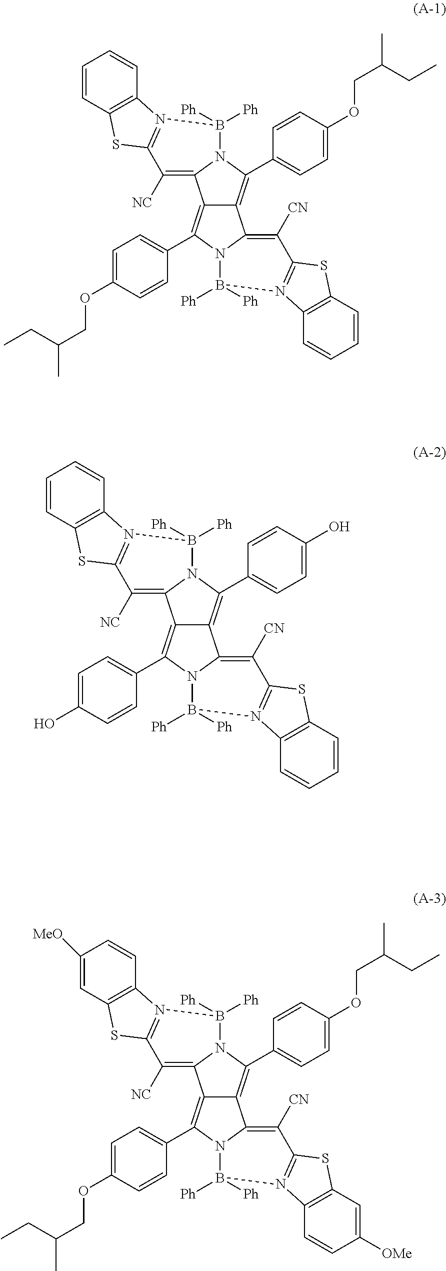

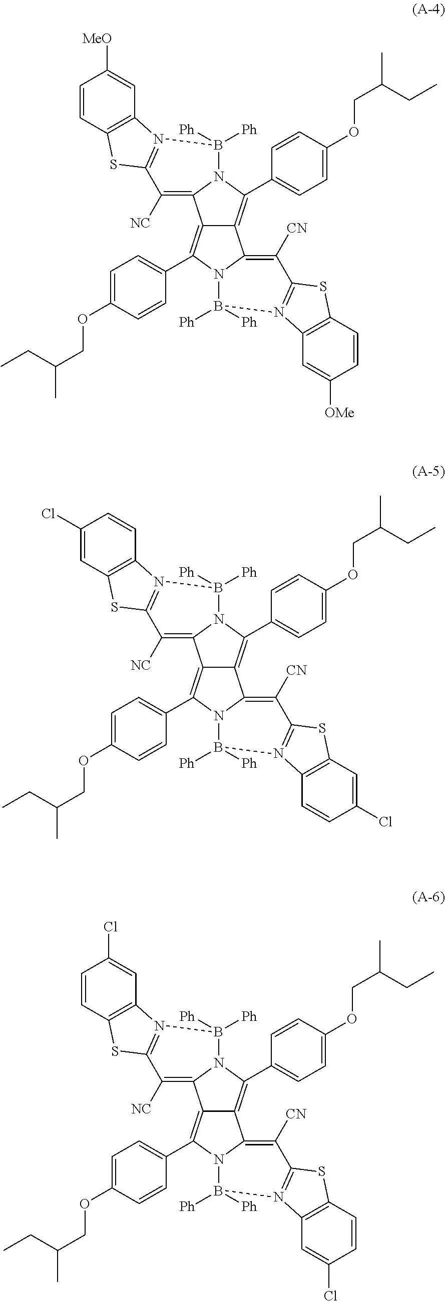

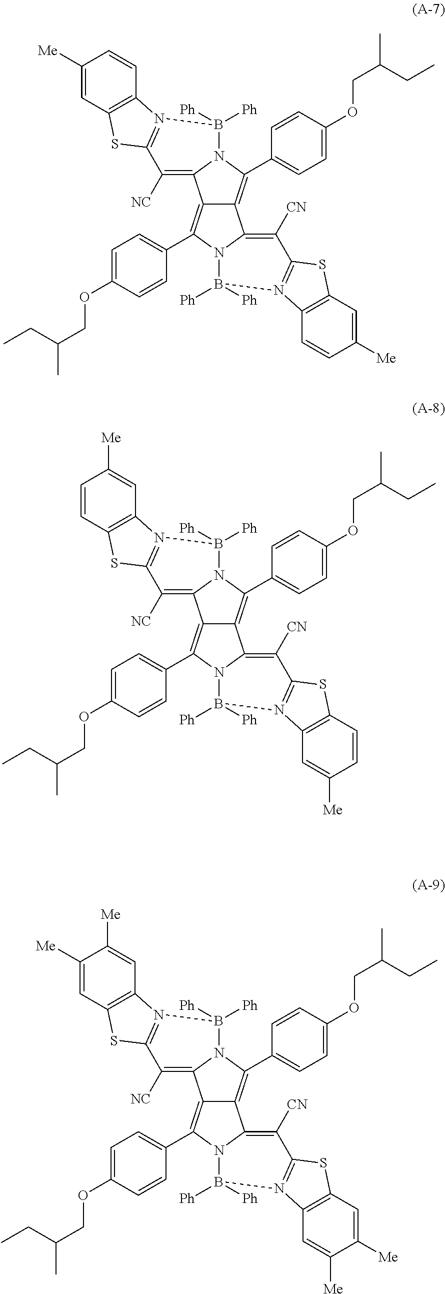

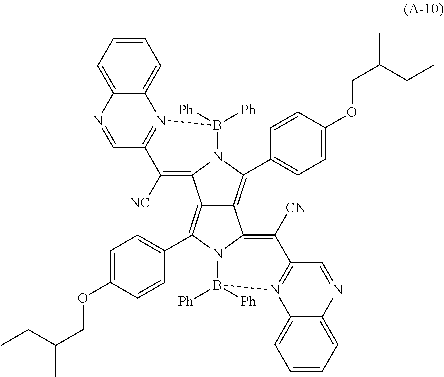

<<Other Coloring Agents>>

The composition according to the invention may further include coloring agents (hereinafter, also referred to as other coloring agents) other than the coloring agent represented by Formula (1).

Examples of the other coloring agents include a compound (hereinafter, also referred to as a “colorant”) having a maximum absorption wavelength in a wavelength range of 400 to 700 nm.

The colorant may be a pigment or may be a dye. A pigment is preferable. Examples of the pigment include various inorganic pigments or various organic pigments well-known in the art, an organic pigment is preferable. The organic pigment can increase dispersibility of the coloring agent represented by Formula (1), and further at least one selected from a red pigment or a blue pigment is preferable for the reason that thixotropy of the composition is suppressed to be low.

Examples of the organic pigment include below. However, the invention is not limited thereto.

Color index (C. I.) pigment yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and the like

C. I. pigment orange 2, 5, 13, 16, 17:1, 31, 34, 36, 38, 43, 46, 48, 49, 51, 52, 55, 59, 60, 61, 62, 64, 71, 73, and the like

C. I. pigment red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279

C. I. pigment green 7, 10, 36, 37, 58, and 59

C. I. pigment violet 1, 19, 23, 27, 32, 37, and 42

C. I. pigment blue 1, 2, 15, 15:1, 15:2, 15:3, 15:4, 15:6, 16, 22, 60, 64, 66, 79, and 80

Examples of the inorganic pigment include a metal compound represented by metal oxide, metal complex salt, or the like, and specific examples thereof include metal oxide such as iron, cobalt, aluminum, cadmium, lead, copper, titanium, magnesium, chromium, zinc, and antimony, and composite oxide of metal described above.

As the dye, for example, coloring agents disclosed in JP1989-90403A (JP-S64-90403A), JP1989-91102A (JP-S64-91102A), JP1989-94301A (JP-H01-94301A), JP1994-11614A (JP-H06-11614A), JP2592207B, U.S. Pat. No. 4,808,501A, U.S. Pat. No. 5,667,920A, US505950A, U.S. Pat. No. 5,667,920A, JP1993-333207A (JP-H05-333207A), JP1994-35183A (JP-H06-35183A), JP1994-51115A (JP-H06-51115A), JP1994-194828A (JP-H06-194828A), and the like can be used. If the dye is classified into chemical structure, a pyrazole azo compound, a pyrromethene compound, an anilinoazo compound, a triphenylmethane compound, an anthraquinone compound, a benzylidene compound, an oxonol compound, a pyrazolotriazole azo compound, a pyridone azo compound, a cyanine compound, a phenothiazine compound, a pyrrolopyrazole azomethine compound, and the like can be used. As the dye, coloring agent multimers may be used. Examples of the coloring agent multimer include compounds include JP2011-213925A and JP2013-041097A.

<<Coloring Agent Derivative>>

It is preferable that the composition according to the invention further includes a coloring agent derivative. If the composition includes a coloring agent derivative, dispersibility of particles including the coloring agent represented by Formula (1) increases, aggregation of the particles can be effectively suppressed. The coloring agent derivative is preferably a pigment derivative.

As the coloring agent derivative, the coloring agent derivative having a structure in which a portion of the coloring agent is substituted with an acidic group, a basic group, or a phthalimidomethyl group is preferable, the coloring agent derivative represented by Formula (2) is more preferable. Since a coloring agent structure P easily adsorbs on surfaces of coloring agent particles, the coloring agent derivative represented by Formula (2) can increase dispersibility of the coloring agent particles in the composition. In a case where the composition includes a resin, a terminal portion X of the coloring agent derivative adsorbs in the resin with an interaction with an adsorbing portion (polar group and the like) of the resin, and thus it is possible to further increase dispersibility of the coloring agent particles.

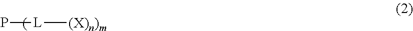

In Formula (2), P represents a coloring agent structure, L represents a single bond or a linking group, X represents an acidic group, a basic group, a group having a salt structure, or a phthalimide group, m represents an integer of 1 or greater, n represents an integer of 1 or greater, in a case where m is 2 or greater, plural L's and plural X's may be different from each other, and in a case where n is 2 or greater, plural X's may be different from each other.

In Formula (2), P is preferably at least one selected from a coloring agent structure, a pyrrolopyrrole coloring agent structure, a diketopyrrolopyrrole coloring agent structure, a quinacridone coloring agent structure, an anthraquinone coloring agent structure, a dianthraquinone coloring agent structure, a benzoisoindole coloring agent structure, a thiazine indigo coloring agent structure, an azo coloring agent structure, a quinophthalone coloring agent structure, a phthalocyanine coloring agent structure, a dioxazine coloring agent structure, a perylene coloring agent structure, a perinone coloring agent structure, or a benzimidazolinone coloring agent structure, more preferably at least one selected from a pyrrolopyrrole coloring agent structure, a diketopyrrolopyrrole coloring agent structure, a quinacridone coloring agent structure, or a benzimidazolinone coloring agent structure, and particularly preferably a pyrrolopyrrole coloring agent structure. If the coloring agent derivative has these coloring agent structures, dispersibility of the coloring agent represented by Formula (1) can be increased.

In Formula (2), L represents a single bond or a linking group.

As the linking group, groups obtained from 1 to 100 carbon atoms, 0 to 10 nitrogen atoms, 0 to 50 oxygen atoms, 1 to 200 hydrogen atoms, and 0 to 20 sulfur atoms are preferable, and the linking group may not be substituted or may have a substituent. The substituent includes the substituent T described in Formula (1) above, and is preferably an alkyl group, an aryl group, a hydroxyl group, or a halogen atom.

The linking group is preferably an alkylene group, an arylene group, a nitrogen-containing heterocyclic group, —NR′—, —SO₂—, —S—, —O—, or —CO—, or a group consisting of a combination thereof and more preferably an alkylene group, a nitrogen-containing heterocyclic group, —NR′—, or —SO₂—, or a group consisting of a combination thereof. R′ represents a hydrogen atom, an alkyl group (preferably having 1 to 30 carbon atoms) or an aryl group (preferably having 6 to 30 carbon atoms).

The number of carbon atoms of the alkylene group is preferably 1 to 30, more preferably 1 to 15, and even more preferably 1 to 10. The alkylene group may have a substituent. The alkylene group may have a linear shape, a branched shape, or a cyclic shape. The cyclic alkylene group may be any one of a single ring and a polycyclic ring.

The number of carbon atoms of the arylene group is preferably 6 to 18, more preferably 6 to 14, and even more preferably 6 to 10, and a phenylene group is particularly preferable.

The nitrogen-containing heterocyclic group is preferably a 5-membered ring or a 6-membered ring. The nitrogen-containing heterocyclic group is preferably a single ring or a fused ring, preferably a single ring or a fused ring having a fused number of 2 to 8, and more preferably a single ring or a fused ring having a fused number of 2 to 4. The number of nitrogen atoms included in the nitrogen-containing heterocyclic group is preferably 1 to 3 and more preferably 1 to 2. The nitrogen-containing heterocyclic group may include a heteroatom in addition to a nitrogen atom. Examples of the heteroatom in addition to the nitrogen atom include an oxygen atom and a sulfur atom. The number of heteroatoms in addition to the nitrogen atom is preferably 0 to 3 and more preferably 0 to 1.

Examples of the nitrogen-containing heterocyclic group include a piperazine ring group, a pyrrolidine ring group, a pyrrole ring group, a piperidine ring group, a pyridine ring group, an imidazole ring group, a pyrazole ring group, an oxazole ring group, a thiazole ring group, a pyrazine ring group, a morpholine ring group, a thiazine ring group, an indole ring group, an isoindole ring group, a benzimidazole ring group, a purine ring group, a quinoline ring group, an isoquinoline ring group, a quinoxaline ring group, a cinnoline ring group, a carbazole ring group, and groups represented by Formulae (L-1) to (L-7) below.

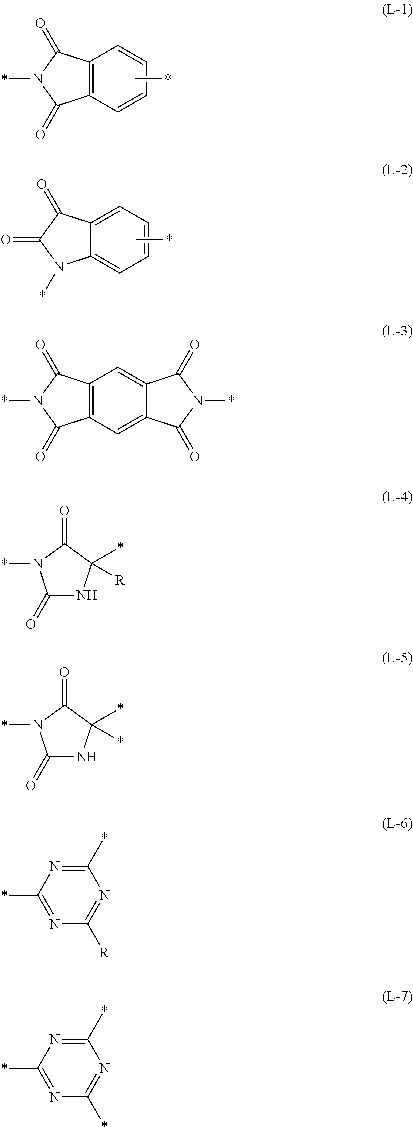

* in the formula represents a coupler hand to P, L, or X. R represents a hydrogen atom or a substituent. Examples of the substituent include the substituent T described in Formula (1) above.

Specific examples of the linking group include an alkylene group, an arylene group, —SO₂—, a group represented by (L-1) above, a group represented by (L-5), a group obtained by combining —O— and an alkylene group, a group consisting of a combination of —NR′— and an alkylene group, a group consisting of a combination of —NR′— and —CO—(—NR′—CO—, —NR′—CO—NR′—, and the like), a group consisting of a combination of —NR′—, —CO—, and an alkylene group, a group consisting of a combination of —NR′—, —CO—, an alkylene group, and an arylene group, a group consisting of a combination of —NR′—, —CO—, and an arylene group, a group consisting of a combination of —NR′—, —SO₂—, and an alkylene group, a group consisting of a combination of —NR′—, —SO₂—, an alkylene group, and an arylene group, a group consisting of a combination of a group represented by (L-1) and an alkylene group, a group consisting of a combination of a group represented by (L-1) and an arylene group, a group consisting of a combination of a group represented by (L-1), —SO₂—, and an alkylene group, a group consisting of a combination of a group represented by (L-1), —S—, and an alkylene group, a group consisting of a combination of a group represented by (L-1), —O—, and an arylene group, a group consisting of a combination of a group represented by (L-1), —NR′—, —CO—, and an arylene group, and a group consisting of a combination of a group represented by (L-3) and an arylene group.

In Formula (2), X represents an acidic group, a basic group, a group having a salt structure, and a phthalimide group.

Examples of the acidic group include a carboxyl group and a sulfo group.

Examples of the basic group include groups represented by Formulae (X-3) to (X-9) described below.

Examples of the group having a salt structure include salt of the acidic groups, and salt of the basic groups described above. Examples of the atom or the atomic group that configures salt include a metal atom or tetrabutylammonium. As the metal atom, an alkali metal atom or an alkali earth metal atom is more preferable. Examples of the alkali metal atom include lithium, sodium, and potassium. Examples of the alkali earth metal atom include calcium and magnesium.

The phthalimide group may not be substituted or may have a substituent. Examples of the substituent include an acidic group, a basic group, or a group having a salt structure described above. The substituent may be the substituent T described in Formula (1) above. The substituent T may further substituted with other substituents. Examples of the other substituents include a carboxyl group and a sulfo group.

X is preferably at least one selected from a carboxyl group, a sulfo group, a phthalimide group, or groups represented by Formulae (X-1) to (X-9).

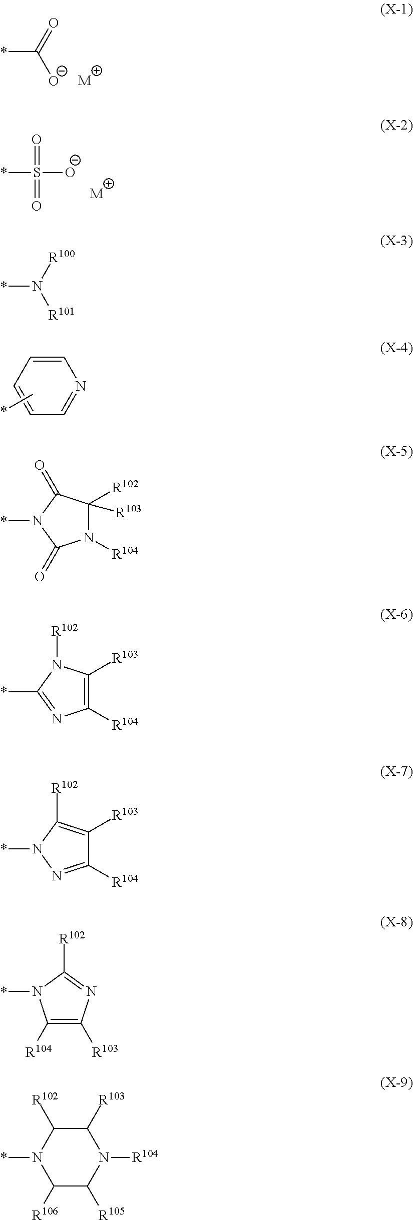

In Formulae (X-1) to (X-9), * represents a coupler hand to L of Formula (2), R¹⁰⁰ to R¹⁰⁶ each independently represent a hydrogen atom, an alkyl group, an alkenyl group, or an aryl group, R^{10°} and R¹⁰¹ may be linked to each other to form a ring, and M represents an atom or an atomic group that forms an anion and salt.

The alkyl group may have any one of a linear shape, a branched shape, and a cyclic shape. The number of carbon atoms of a linear alkyl group is preferably 1 to 20, more preferably 1 to 12, and even more preferably 1 to 8. The number of carbon atoms of the branched alkyl group is preferably 3 to 20, more preferably 3 to 12, and even more preferably 3 to 8. The cyclic alkyl group may be any one of a single ring and a polycyclic ring. The number of carbon atoms of the cyclic alkyl group is preferably 3 to 20, more preferably 4 to 10, and even more preferably 6 to 10.

The number of carbon atoms of the alkenyl group is preferably 2 to 10, more preferably 2 to 8, and even more preferably 2 to 4.

The number of carbon atoms of the aryl group is preferably 6 to 18, more preferably 6 to 14, and even more preferably 6 to 10.

R¹⁰⁰ and R¹⁰¹ are linked to each other to form a ring. The ring may be an alicyclic ring or may be an aromatic ring. The ring may be a single ring or a polycyclic ring. The linking group in a case where R¹⁰⁰ and R¹⁰¹ are bonded to each other to form a ring can be linked to —CO—, —O—, —NH—, a divalent aliphatic group, a divalent aromatic group, and a divalent linking group selected from a group consisting of a combination thereof. Specific examples thereof include a piperazine ring, a pyrrolidine ring, a pyrrole ring, a piperidine ring, a pyridine ring, an imidazole ring, a pyrazole ring, an oxazole ring, a thiazole ring, a pyrazine ring, a morpholine ring, a thiazine ring, an indole ring, an isoindole ring, a benzimiazole ring, a purine ring, a quinoline ring, an isoquinoline ring, a quinoxaline ring, a cinnoline ring, and a carbazole ring.

M represents an atom or an atomic group that configures an anion and salt. Examples thereof also include those described above, and preferable ranges thereof are also the same.

In Formula (2), m represents an integer of 1 or greater. The upper limit of m represents the number of substituents that the coloring agent structure P can take. For example, m is preferably 10 or less and more preferably 5 or less. In a case where m is 2 or greater, plural L's and plural X's may be different from each other.

n represents an integer of 1 or greater, is preferably 1 to 3 and more preferably 1 to 2. In a case where n is 2 or greater, plural X's may be different from each other.

According to the invention, the coloring agent derivative is preferably a compound represented by Formula (3). The compound represented by Formula (3) is a compound in which P in Formula (2) is represented by a pyrrolopyrrle coloring agent structure.

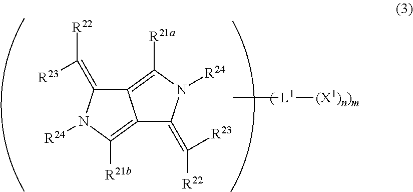

In Formula (3), R^{21a} and R^{21b} each independently represent an alkyl group, an aryl group, or a heteroaryl group, R²² and R²³ each independently represent a cyano group, an acyl group, an alkoxycarbonyl group, an alkyl group, an arylsulfinyl group, or a heteroaryl group, R²² and R²³ may be bonded to each other to form a ring, R²⁴ represents a hydrogen atom, an alkyl group, an aryl group, heteroaryl group, —BR^{24A}R^{24B}, or a metal atom, R²⁴ may form a covalent bond or a coordinate bond with at least one selected from R^{21a}, R^{21b}, and R²³, R^{24A} and R^{24B} each independently represent a hydrogen atom, a halogen atom, an alkyl group, an aryl group, or a heteroaryl group, L¹ represents a single bond or a linking group consisting of an alkylene group, a nitrogen-containing heterocyclic group, —NR′—, —CO—, —SO₂—, or a combination thereof, R′ represents a hydrogen atom, an alkyl group, or an aryl group, X¹ represents an acidic group, a basic group, a group having a salt structure, or a phthalimide group, m represents an integer of 1 or greater, n represents an integer of 1 or greater, in a case where m is 2 or greater, plural L¹'s and plural X¹'s may be different from each other, and in a case where n is 2 or greater, plural X's may be different from each other.

R^{21a} and R^{21b} in Formula (3) are the same as R^{1a} and R^{1b} in Formula (1). An aryl group having an alkoxy group having a branched alkyl group or an aryl group having a hydroxyl group is preferable. The number of carbon atoms of the branched alkyl group is preferably 3 to 30 and more preferably 3 to 20.

R²² and R²³ in Formula (3) each independently represent a cyano group, an acyl group, an alkoxycarbonyl group, an alkyl group, an arylsulfinyl group, or a heteroaryl group. It is preferable that any one of R²² and R²³ represents a cyano group and the other represents a heteroaryl group. The heteroaryl group is preferably a 5-membered ring or a 6-membered ring. The heteroaryl group is preferably a single ring or a fused ring, preferably a single ring or a fused ring having a fused number of 2 to 8, and more preferably a single ring or a fused ring having a fused number of 2 to 4. The number of heteroatoms included in the heteroaryl group is preferably 1 to 3 and more preferably 1 to 2. Examples of the heteroatom include a nitrogen atom, an oxygen atom, and a sulfur atom. As the heteroaryl group, a quinoline group, a benzothiazole group, or a naphthothiazole group is preferable, and a benzothiazole group is particularly preferable.

R²⁴ in Formula (3) represents a hydrogen atom, an alkyl group, an aryl group, a heteroaryl group, —BR^{24A}R^{24B}, or a metal atom and preferably represents a hydrogen atom or —BR^{24A}R^{24B}. R^{24A} and R^{24B} each independently represent a hydrogen atom, a halogen atom, an alkyl group, an aryl group, or a heteroaryl group, preferably represents an alkyl group, an aryl group, or a heteroaryl group, and more preferably represents an aryl group. The alkyl group, the aryl group, and the heteroaryl group are the same as those described in R^{1a} and R^{1b} of Formula (1), and preferable ranges thereof are also the same. Specific examples of the group represented by —BR^{4A}R^{4B} include difluoroboron, diphenylboron, dibutylboron, dinaphthylboron, and catechol boron. Among these, diphenylboron is particularly preferable.

R²⁴ may form a covalent bond or a coordinate bond with at least one of R^{21a}, R^{22b}, and R²³. Particularly, R²⁴ preferably forms a coordinate bond with R²³

L¹ in Formula (3) represents a single bond or a linking group consisting of an alkylene group, a nitrogen-containing heterocyclic group, —NR′—, —CO—, or —SO₂—, or a combination thereof. R′ represents a hydrogen atom, an alkyl group, or an aryl group. The alkyl group and the aryl group represented by R′ are the same as R′ of Formula (2), and preferable ranges thereof are also the same.

The linking group represented by L¹ is the same as those described in L of Formula (2), and preferable ranges thereof are also the same. Among these, an alkylene group, —SO₂—, —NR′—, a group consisting of a combination of —SO₂— and an alkylene group, or a group consisting of a combination of the group represented by (L-1) and an alkylene group is more preferable.

X¹ in Formula (3) represents an acidic group, a basic group, a group having a salt structure, or a phthalimide group. The phthalimide group may not be substituted or may have a substituent. These groups may be the same as those described in X of Formula (2), and preferable ranges thereof are also the same. Among these, a carboxyl group, a sulfo group, a phthalimide group, a group represented by (X-3), or a group represented by (X-9) is more preferable.

m in Formula (3) represents an integer of 1 or greater. For example, the upper limit is preferably 10 or less and more preferably 5 or less.

n in Formula (3) represents an integer of 1 or greater. n is preferably 1 to 3 and more preferably 1 to 2.

The coloring agent derivative is more preferably a compound represented by Formula (3A) below.

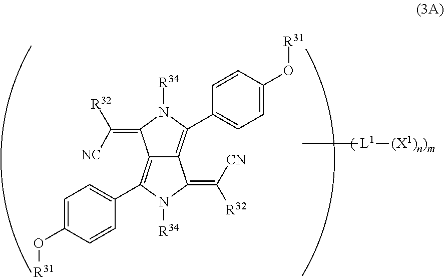

In Formula (3A), R³¹'s each independently represent a hydrogen atom or a branched alkyl group, R³²'s each independently represent a heteroaryl group, R³⁴ represents a hydrogen atom or —BR^{34A}R^{34B}, R³⁴ may form a covalent bond or a coordinate bond with R³², R^{34A} and R^{34B} each independently represent a hydrogen atom or an aryl group, L¹ represents a single bond or a linking group consisting of an alkylene group, a nitrogen-containing heterocyclic group, —NR′—, —CO—, or —SO₂—, or a combination thereof, R′ represents a hydrogen atom, an alkyl group, or an aryl group, X¹ represents an acidic group, a basic group, a group having a salt structure, or a phthalimide group, m represents an integer of 1 or greater, n represents an integer of 1 or greater, in a case where m is 2 or greater, plural L¹'s and plural X¹'s may be different from each other, and in a case where n is 2 or greater, plural X¹'s may be different from each other.

In Formula (3A), a branched alkyl group represented by R³¹ has the same meaning as those described in R²¹ of Formula (3), and preferable ranges thereof are also the same.

In Formula (3A), a heteroaryl group represented by R³² has the same meaning as those described in R²² and R²³ of Formula (3), and preferable ranges thereof are also the same.

In Formula (3A), —BR^{24A}R^{24B} represented by R³⁴ has the same meaning as those described in R²⁴ of Formula (3), and preferable ranges thereof are also the same.

In Formula (3A), L¹, X¹, m, and n have the same meaning as those described in Formula (3), and preferable ranges thereof are also the same.

Specific examples of the coloring agent derivative represented by Formula (2) include (B-1) to (B-62) below. Among the specific examples, (B-1) to (B-21), (B-61), and (B-62) are coloring agent derivatives represented by Formula (3). In formulae below, m, m1, m2, and m3 each independently represent an integer of 1 or greater.

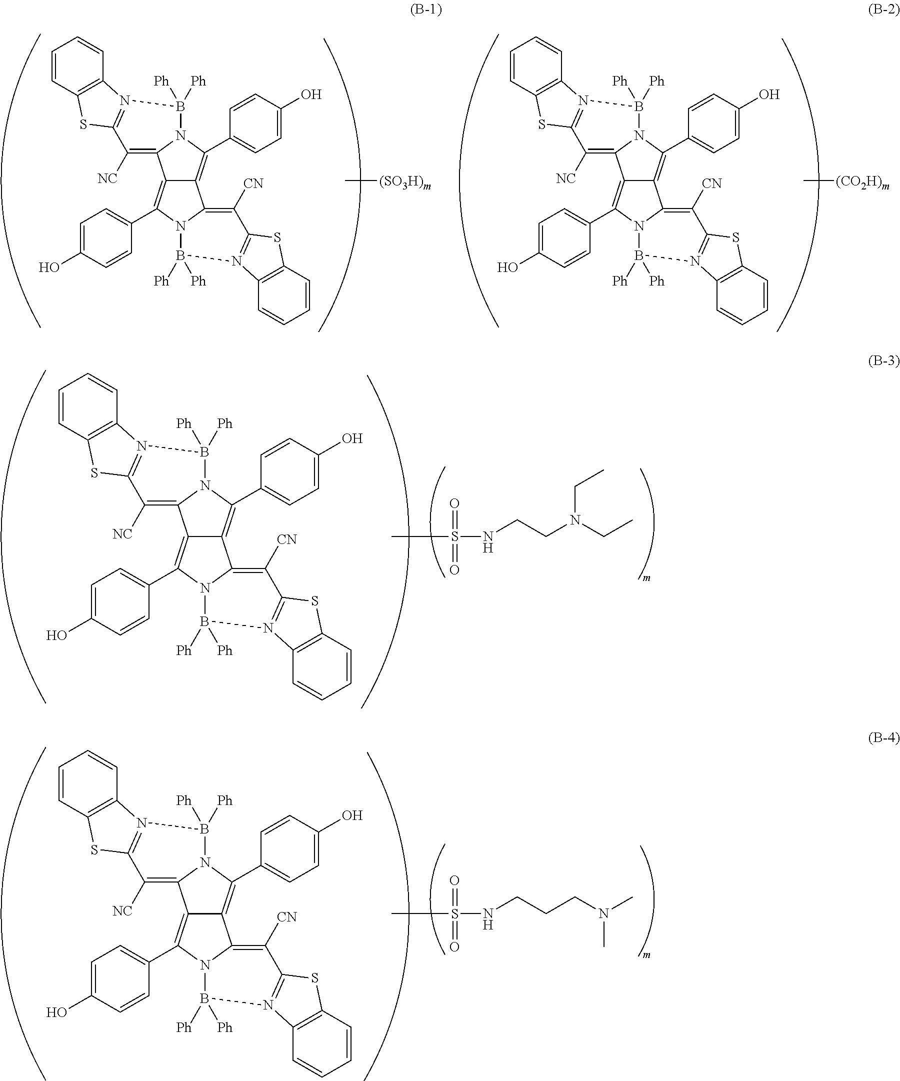

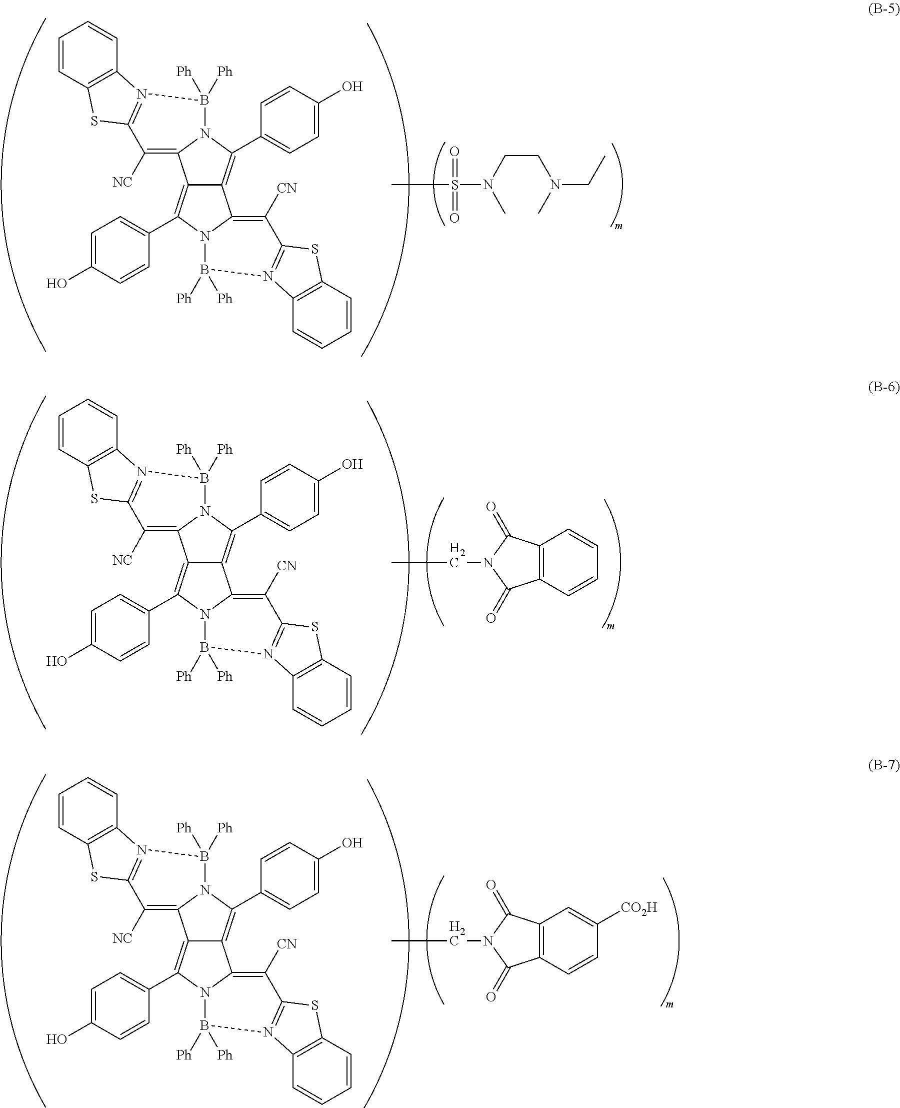

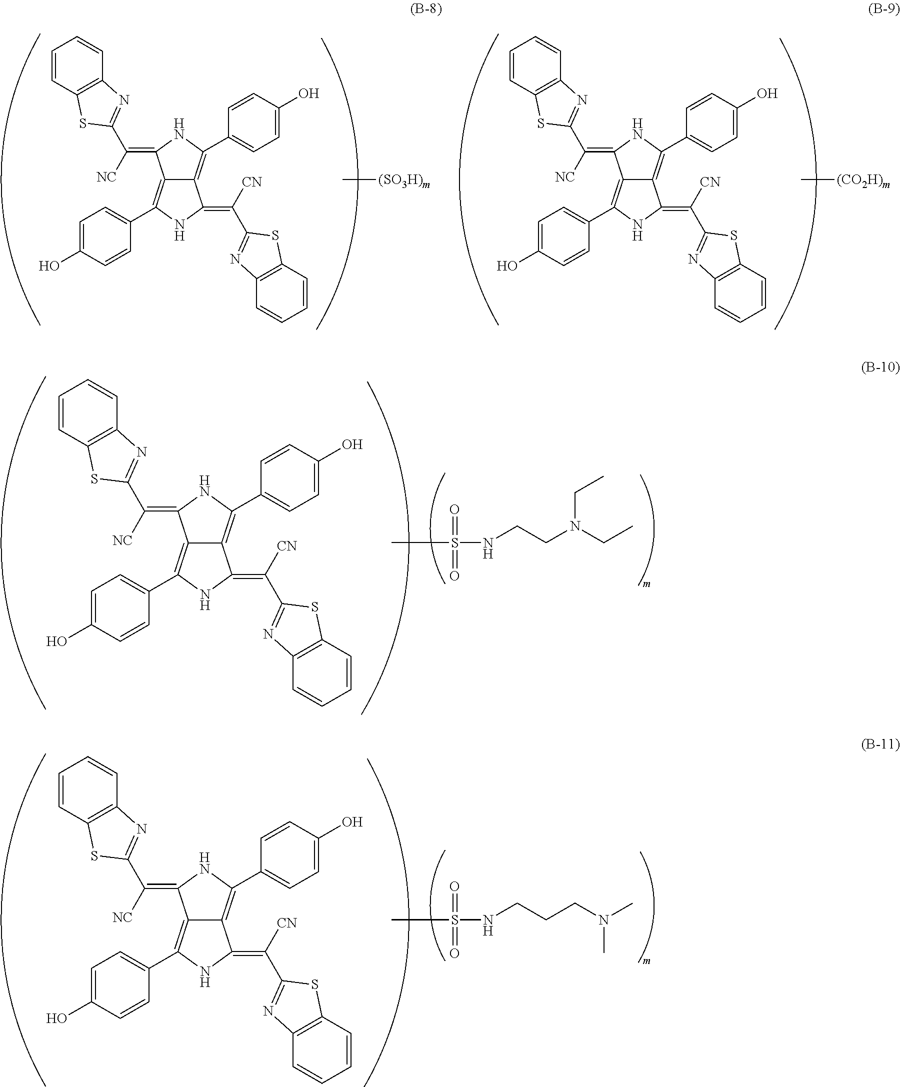

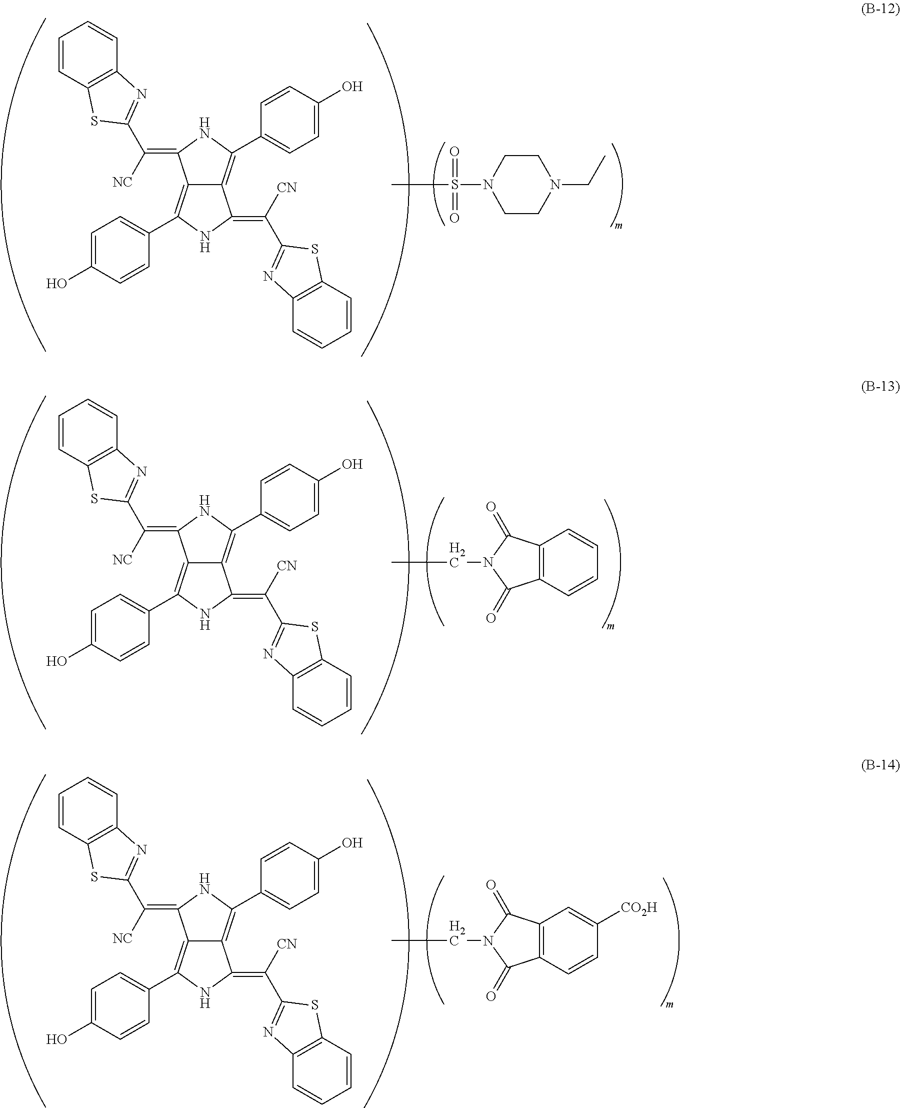

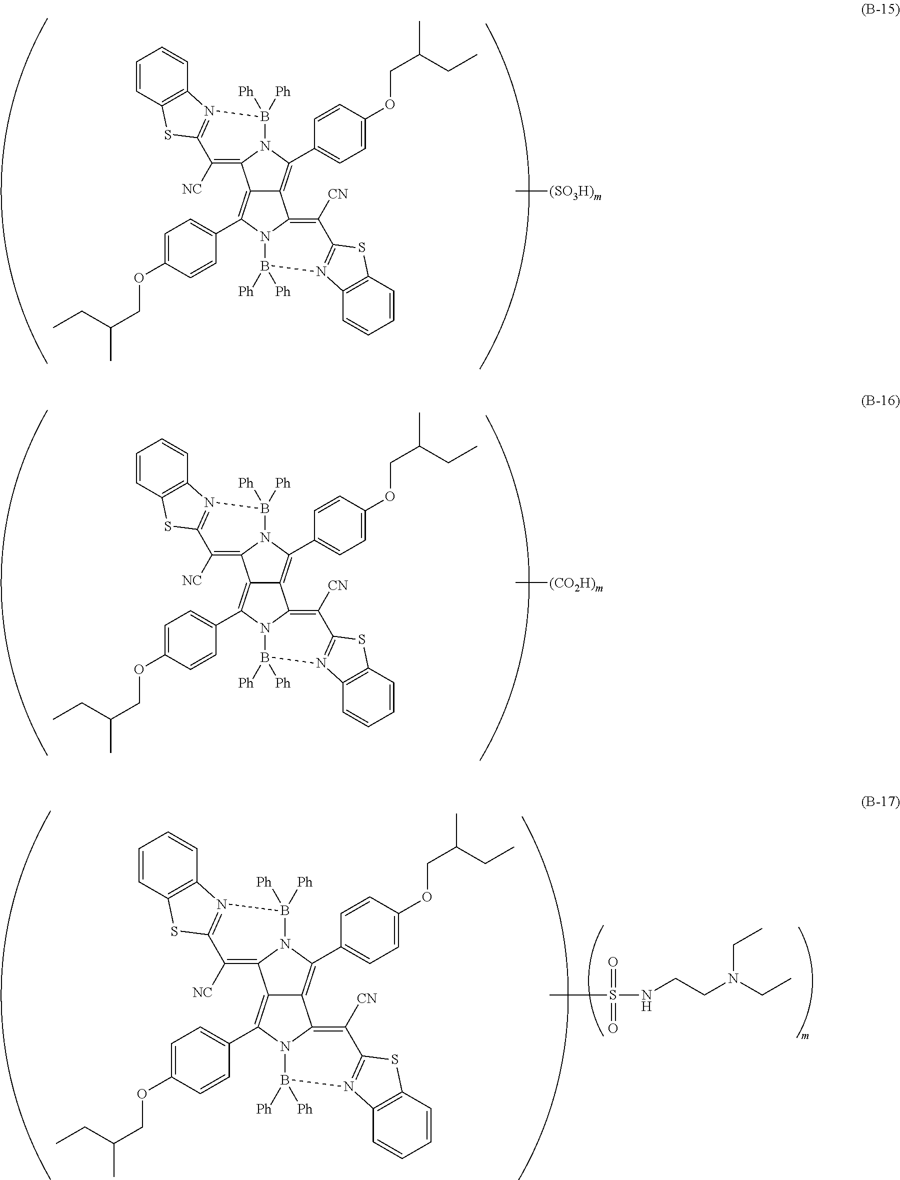

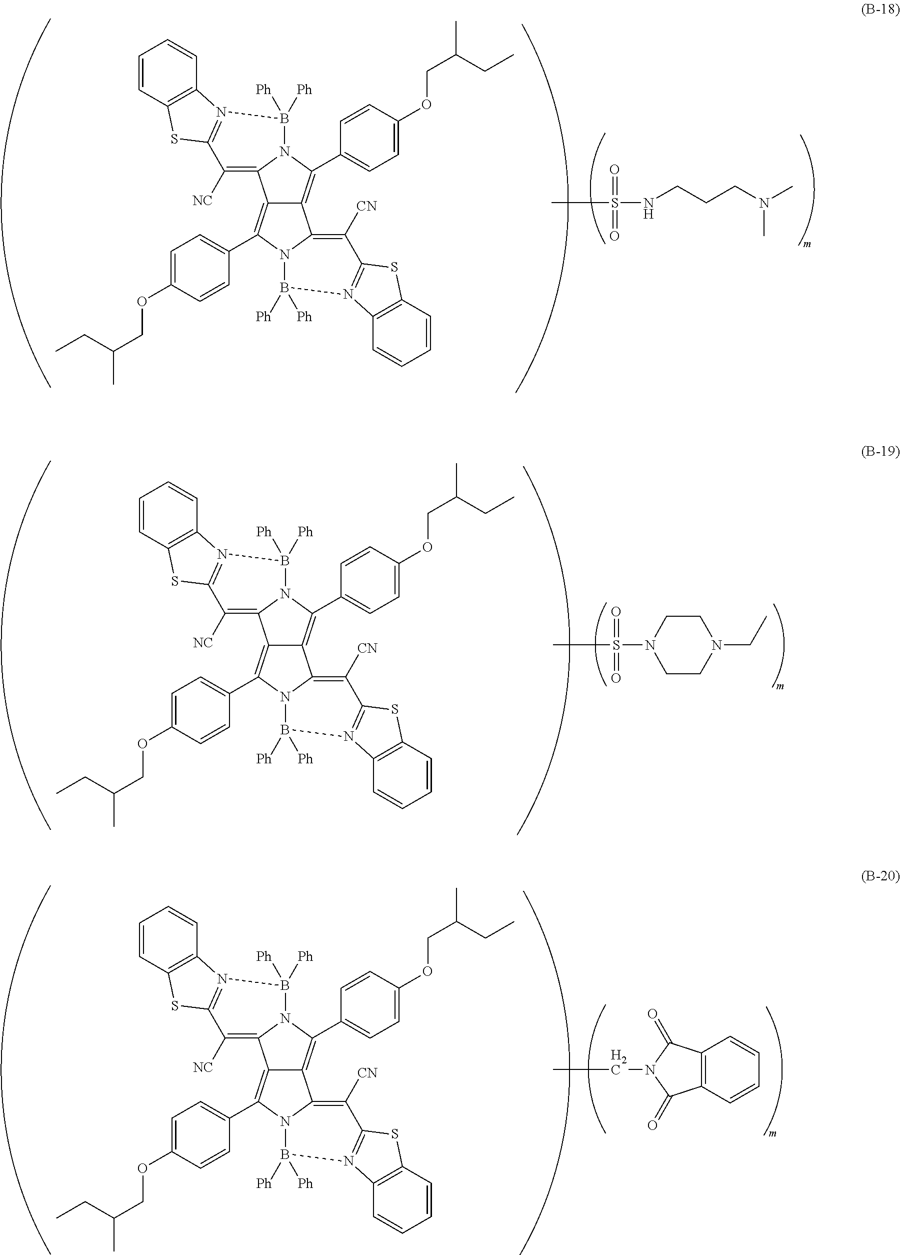

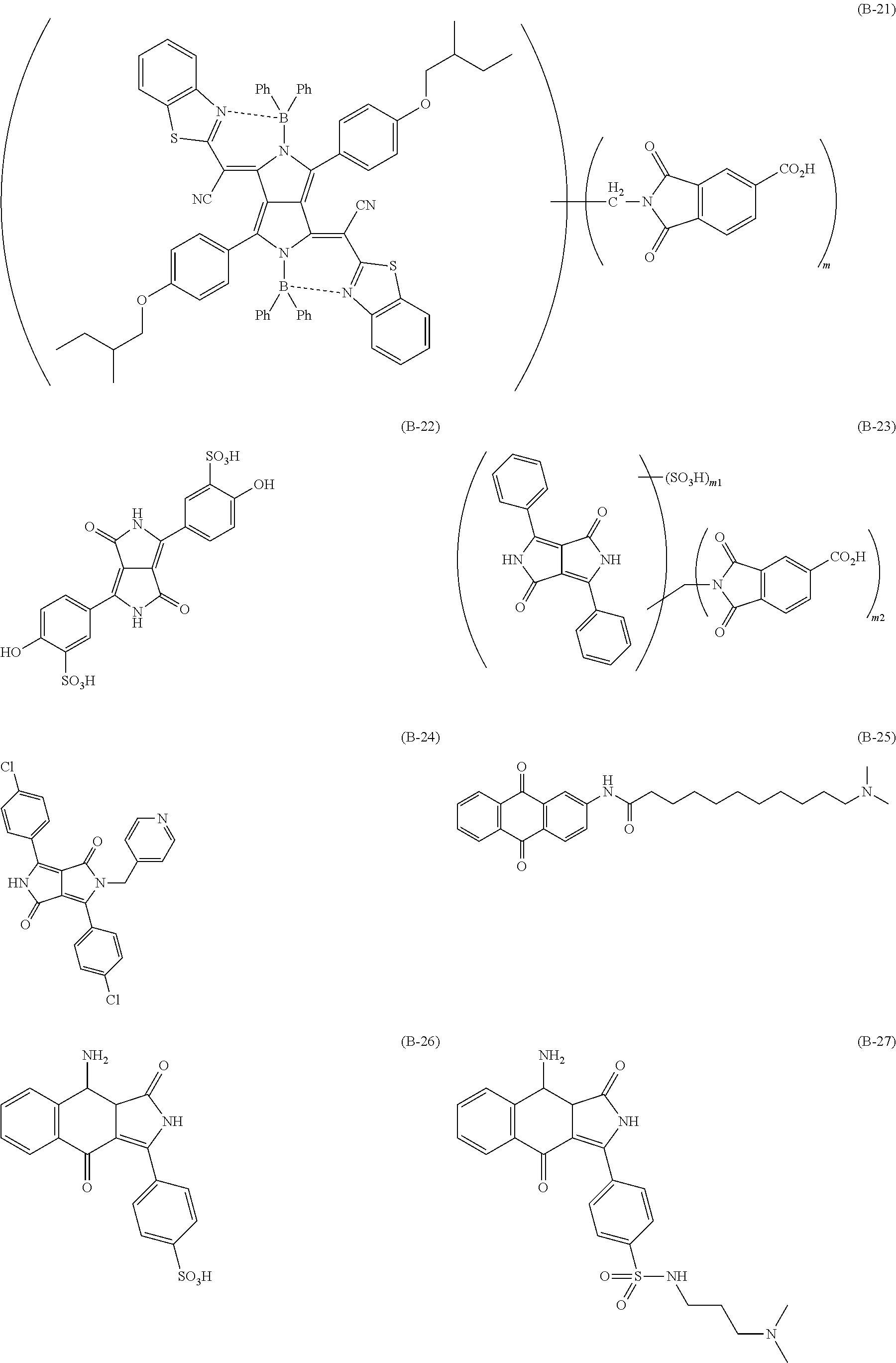

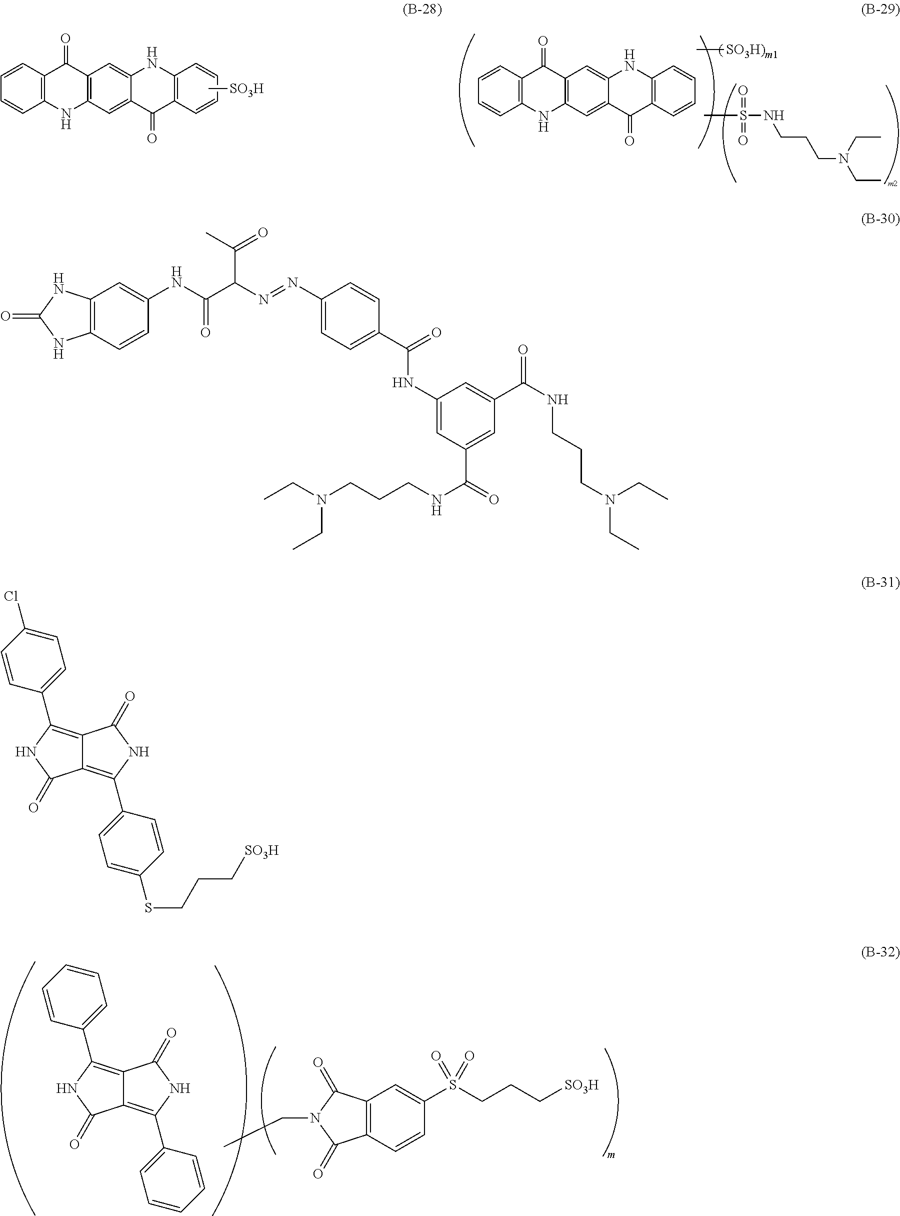

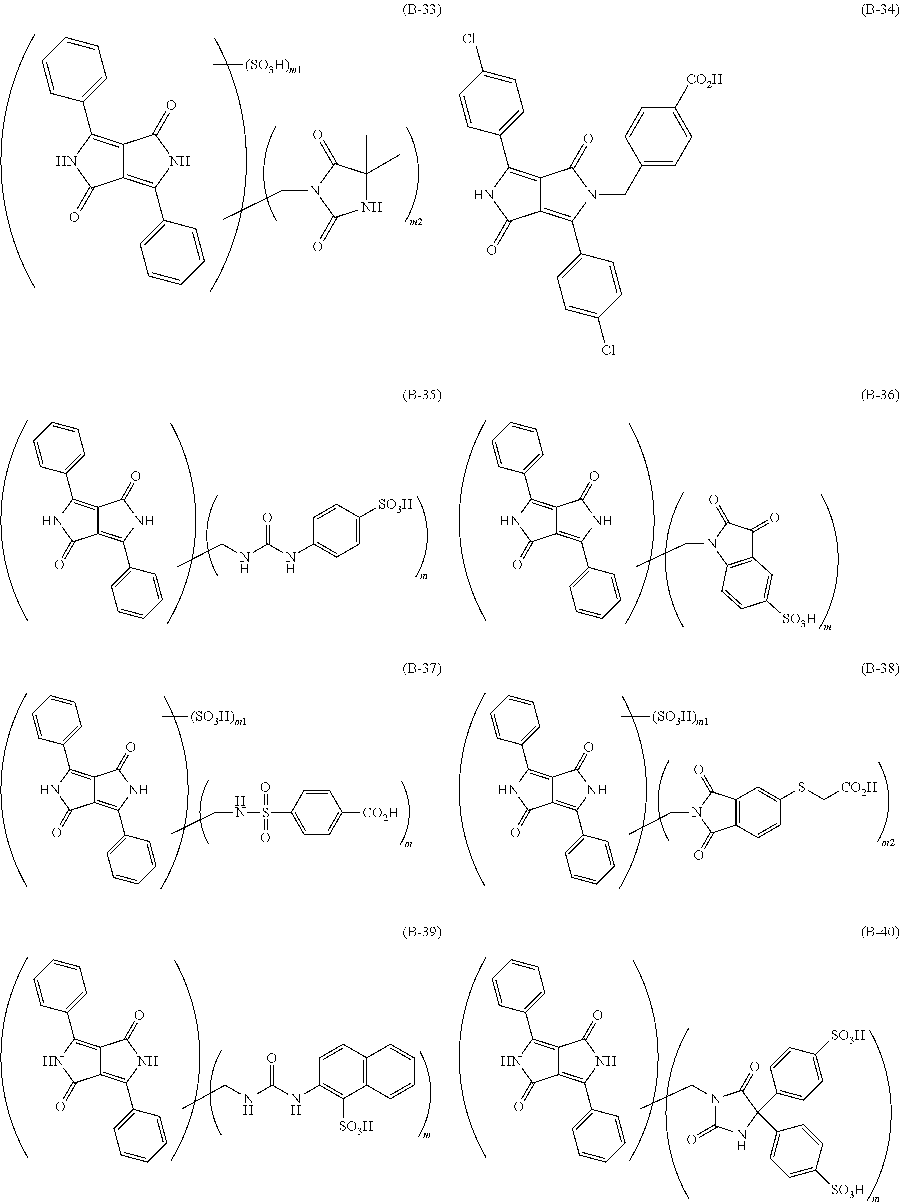

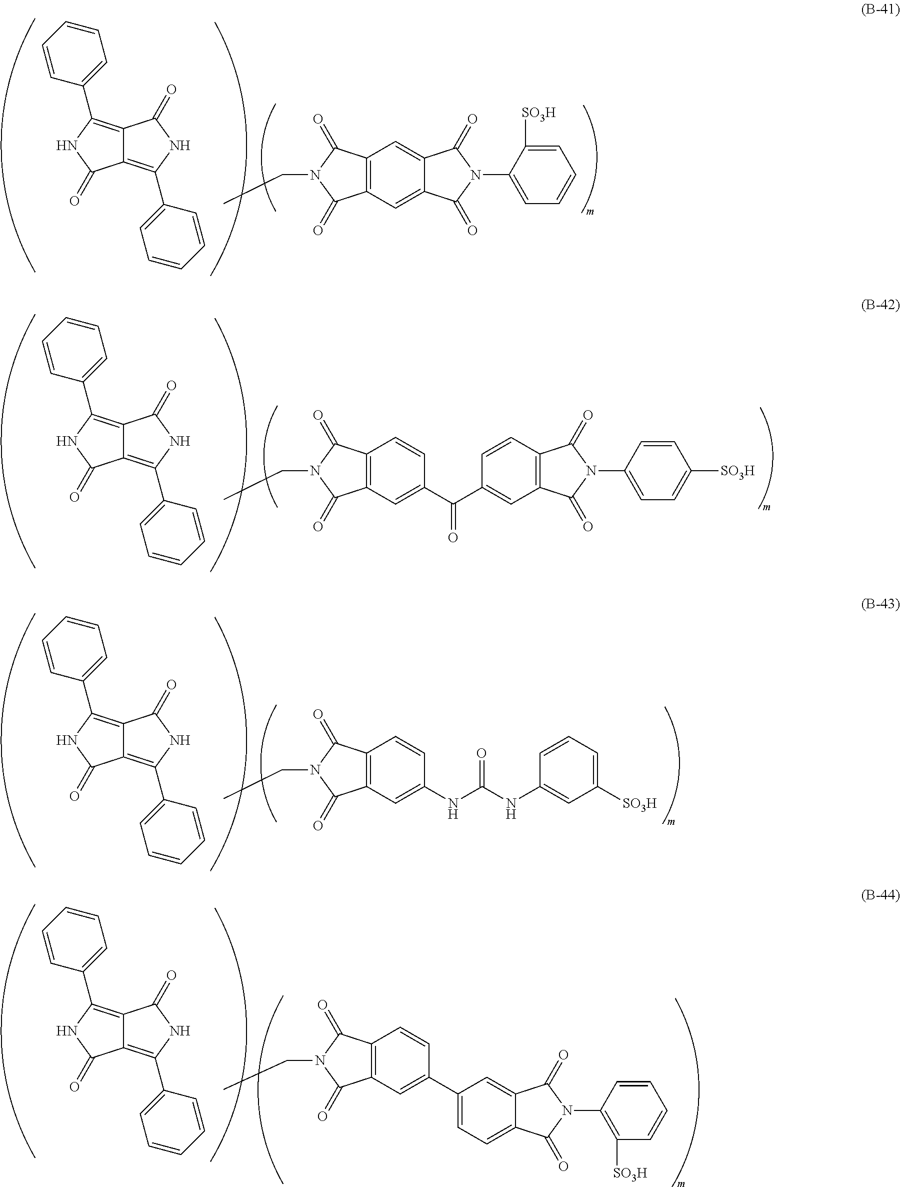

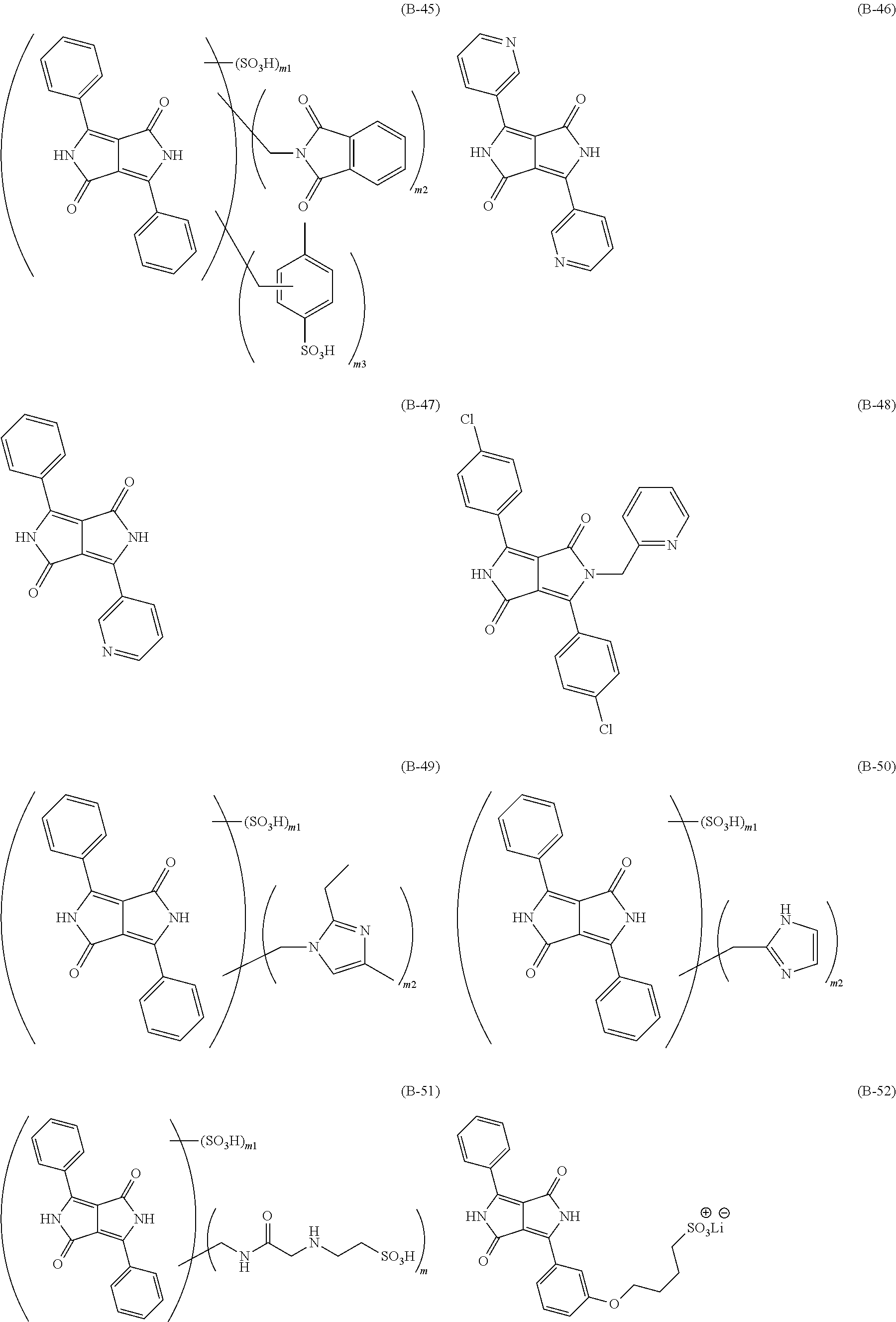

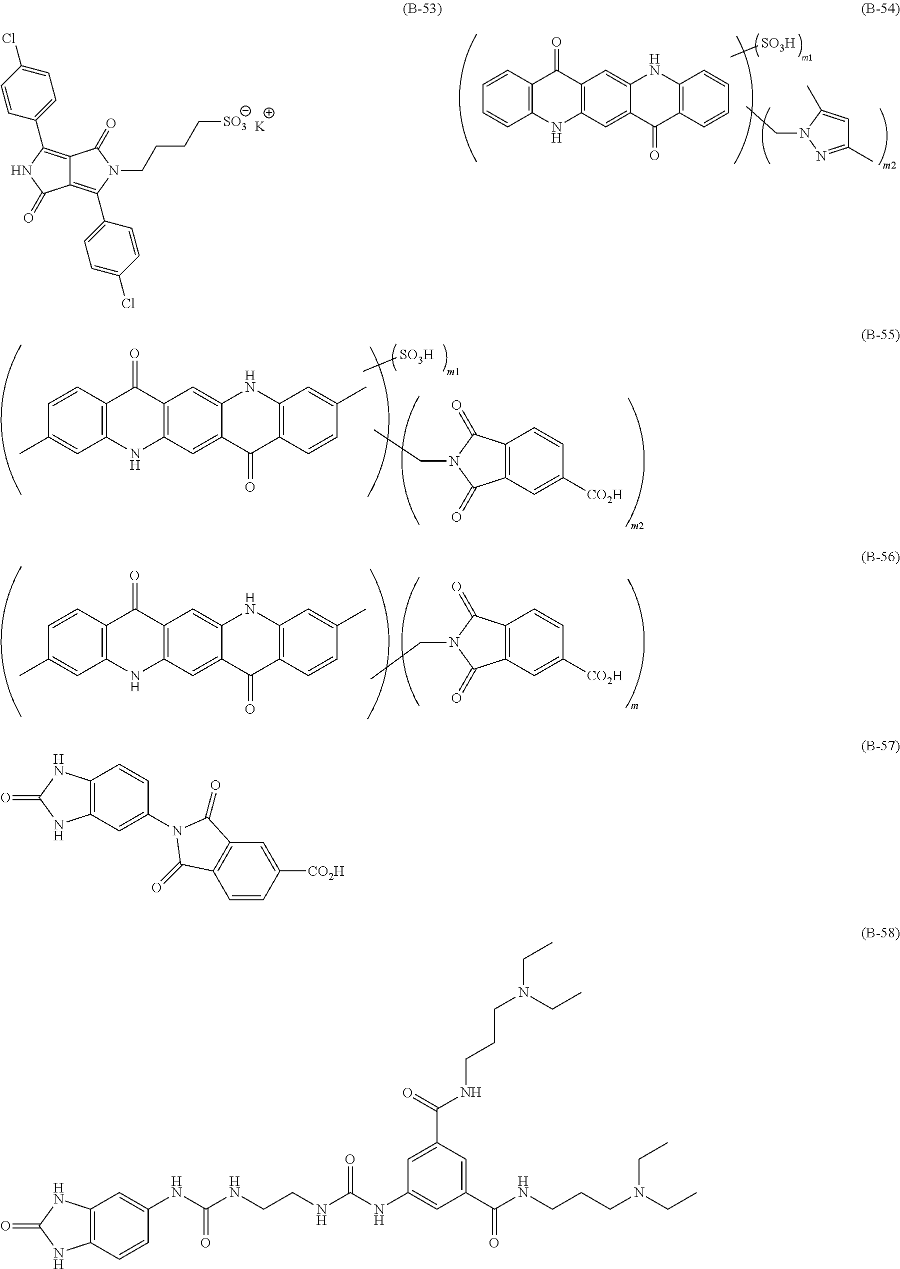

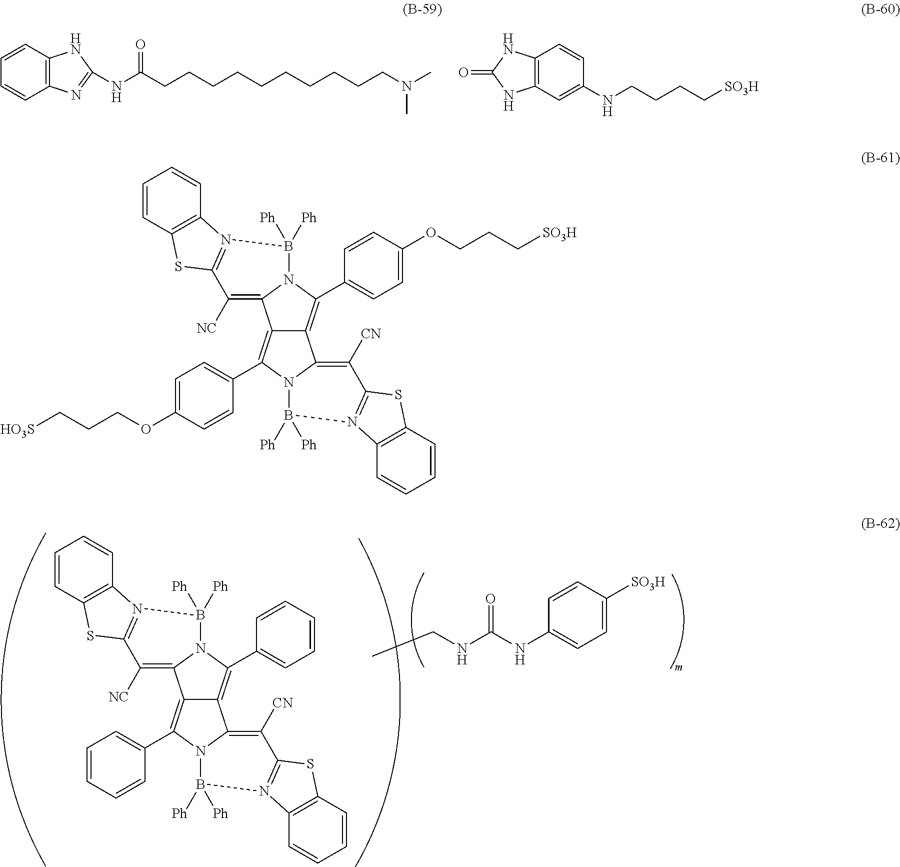

According to the invention, as the coloring agent derivative, those disclosed in JP1981-118462A (JP-S56-118462A), JP1988-264674A (JP-S63-264674A), JP1989-217077A (JP-H01-217077A), JP1991-9961A (JP-H03-9961A), JP1991-26767A (JP-H03-26767A), JP1991-153780A (JP-H03-153780A), JP1991-45662A (JP-H03-45662A), JP1992-285669A (JP-H04-285669A), JP1994-145546A (JP-H06-145546A), JP1994-212088A (JP-H06-212088A), JP1994-240158A (JP-H06-240158A), JP1998-30063A (JP-H10-30063A), JP1998-195326A (JP-H10-195326A), paragraph numbers 0086 to 0098 of WO2011/024896A, paragraph numbers 0063 to 0094 of WO2012/102399A, and the like can be preferably used, and the contents thereof are in corporate to this specification.

The composition according to the invention preferably contains 1 to 30 parts by mass of the coloring agent derivative with respect to 100 parts by mass of the coloring agent represented by Formula (1). The lower limit value is preferably 3 parts by mass or greater and more preferably 5 parts by mass or greater. The upper limit value is preferably 20 parts by mass or less and more preferably 15 parts by mass or less.

The composition according to the invention particularly preferably contains 1 to 30 parts by mass of the coloring agent derivative represented by Formula (2) with respect to 100 parts by mass of the coloring agent represented by Formula (1).

If the content of the coloring agent derivative is in the range described above, dispersibility of the particles including the coloring agent represented by Formula (1) increases, and aggregation of particles can be effectively suppressed.

The coloring agent derivative may be used singly or two or more types thereof can be used. In a case where two or more types the coloring agent derivative are used, the total amount is preferably in the range described above.

<<Organic Solvent>>

It is preferable that the composition according to the invention further includes an organic solvent.

The organic solvent is not particularly limited and can be appropriately selected depending on the purpose, as long as the organic solvent can be evenly dissolved and dispersed. Examples thereof suitably include alcohols, ketones, esters, aromatic hydrocarbons, halogenated hydrocarbons, dimethylformamide, dimethylacetamide, dimethyl sulfoxide, and sulfolane. These may be used singly or two or more types may be used in combination.

Specific examples of alcohols, aromatic hydrocarbons, and halogenated hydrocarbons include those disclosed in paragraph 0136 of JP2012-194534A and the like, and the contents thereof are incorporated to this specification.

Specific examples of esters, ketones, and ethers include paragraph 0497 of JP2012-208494A ([0609] of corresponding US2012/0235099A). Examples thereof include n-amyl acetate, ethyl propionate, dimethyl phthalate, ethyl benzoate, methyl sulfate, acetone, methyl isobutyl ketone, diethyl ether, and ethylene glycol monobutyl ether acetate.

As the organic solvent, at least one selected from cyclopentanone, cyclohexanone, propylene glycol monomethyl ether acetate, N-methyl-2-pyrrolidone, butyl acetate, ethanol, ethyl lactate, and propylene glycol monomethyl ether is preferable.

According to the invention, a solubility parameter (SP value) of the organic solvent is preferably 23 (cal/cm³)^{0.5} or less, more preferably 20 (cal/cm³)^{0.5} or less, even more preferably 18 (cal/cm³)^{0.5} or less, and still even more preferably 15 (cal/cm³)^{0.5} or less. For example, the lower limit value is preferably 1 (cal/cm³)^{0.5} or greater, more preferably 3 (cal/cm³)^{0.5} or greater, and even more preferably 5 (cal/cm³)^{0.5} or greater.

As the SP value, extremely great data such as measured values from evaporation latent heat, solubility, or the like and a calculation method by Small, Fedors, or Hansen is suggested. However, according to the invention, a value obtained by a well-known Holy method is used. Examples of documents of the Hoy method suitably include H. L. Hoy: J. Paint Tech., 42 (540), 76-118 (1970) and “SP value, base, application and calculation method” (Yamamoto, Johokiko Co., Ltd., 2005).

For example, an SP value of propylene glycol monomethyl ether acetate is 9.2 (cal/cm³)^{1/2}, and an SP value of cyclohexanone is 10.0 (cal/cm³)^{1/2}.

The content of the organic solvent is preferably a value in which a total solid content of the composition according to the invention becomes 5 to 60 mass %, and more preferably a value in which a total solid content of the composition according to the invention becomes 10 to 40 mass %.

The organic solvent may be used singly or two or more types thereof may be used in combination. In a case where two or more types of organic solvents are used, it is preferable that the total amount becomes the range described above.

<<Resin>>

It is preferable that the composition according to the invention further includes a resin. For example, the resin is formulated as a dispersing agent for dispersing particles including the coloring agent represented by Formula (1) in the composition.

The resin that works as a dispersing agent is preferably an acidic type resin or a basic type resin.

Here, an acidic type resin represents a resin in which an amount of acid groups is greater than an amount of basic groups. In the acidic type resin, it is preferable that an amount of acid groups is 70 mol % or greater when a total amount of a value of an acid and a value of a basic group in the resin is 100 mol %, and it is more preferable that the resin substantially consists of only with acid groups. The acid group included in the acidic type resin is preferably a carboxyl group. The acid value of the acidic type resin is preferably 40 to 105 mgKOH/g, more preferably 50 to 105 mgKOH/g, and even more preferably 60 to 105 mgKOH/g.

A basic type resin represents a resin in which an amount of basic groups is greater than an amount of acid groups. In the basic type resin, it is preferable that an amount of basic groups is 50 mol % or greater, when a total amount of an amount of acid groups and an amount of basic groups in the resin is 100 mol %, a basic group included in the basic type resin is preferably amine.

The resin can be further classified into a linear polymer, a terminal modification-type polymer, a graft-type polymer, and a block-type polymer.

Examples of the terminal modification-type polymer include polymers having phosphoric acid groups at terminals disclosed in JP1991-112992A (JP-H03-112992A) and JP2003-533455A, polymers having sulfonic acid groups at terminals disclosed in JP2002-273191A, and polymers having a partial skeleton and a heterocyclic ring of a partial skeleton and a heterocyclic rings disclosed in JP1997-77994A (JP-H09-77994A). Polymers obtained by introducing anchor parts (partial skeletons or heterocyclic rings of an acid group, a basic group, or an organic coloring agent, and the like) to two or more pigment surfaces to polymer terminals of JP2007-277514A have excellent dispersion stability and thus are preferable.

Examples of a graft-type polymer include reaction products of poly(lower alkylene imine) and polyester disclosed in JP1979-37082A (JP-S54-37082A), JP1996-507960A (JP-H08-507960A), and JP2009-258668A, reaction products of polyallylamine and polyester disclosed in JP1997-169821A (JP-H09-169821A), copolymers of macromonomers and nitrogen atom monomers disclosed in JP1998-339949A (JP-H10-339949A) and JP2004-37986A, graft-type polymers having heterocyclic rings and partial skeletons of organic coloring agents disclosed in JP2003-238837A and JP2008-9426A, and JP2008-81732A, and copolymers of macromonomers and acid group-containing monomers disclosed in JP2010-106268A. Examples of the macromonomers include macromonomers AA-6 (polymethyl methacrylate of which a terminal group is a methacryloyl group), AS-6 (polystyrene of which a terminal group is a methacryloyl group), AN-6S (a copolymer of styrene and acrylonitrile of which a terminal group is a methacryloyl group), and AB-6 (polybutyl acrylate of which a terminal group is end group is a methacryloyl group) manufactured by Toagosei Co., Ltd., PLACCEL FM5 manufactured by Daicel Corporation (a 5 molar equivalent ε-caprolactone adduct of 2-hydroxyethyl methacrylate), FA10L (a 10 molar equivalent ε-caprolactone adduct of 2-hydroxyethyl acrylate) manufactured by Daicel Corporation, and a polyester-based macromonomer disclosed in JP1990-272009A (JP-H02-272009A).

As the block-type polymer, block-type polymers disclosed in JP2003-49110A and JP2009-52010A are preferable.

The resin can use a graft copolymer including a structural unit represented by any one of Formulae (1) to (4).

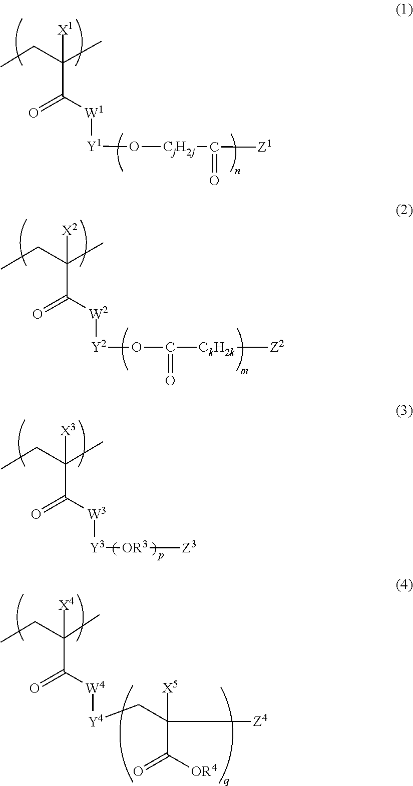

X¹, X², X³, X⁴, and X⁵ each independently represent a hydrogen atom or a monovalent organic group. A hydrogen atom or an alkyl group having 1 to 12 carbon atoms is preferable, a hydrogen atom or a methyl group is more preferable, and a methyl group is particularly preferable.

W¹, W², W³, and W⁴ each independently represent an oxygen atom or NH, and an oxygen atom is preferable.

R³ represents a branched or linear alkylene group (preferably having 1 to 10 carbon atoms or more preferably 2 or 3 carbon atoms). In view of dispersion stability, a group represented by —CH₂—CH(CH₃)— or a group represented by —CH(CH₃)—CH₂— is preferable.

Y¹, Y², Y³, and Y⁴ each independently represent a divalent linking group.

With respect to the graft copolymer, disclosure in paragraph numbers 0025 to 0069 of JP2012-255128A are referred to, and the contents above are incorporated to this specification.

Specific examples of the graft copolymer includes below. Resins disclosed in paragraph numbers 0072 to 0094 of JP2012-255128A can be used.

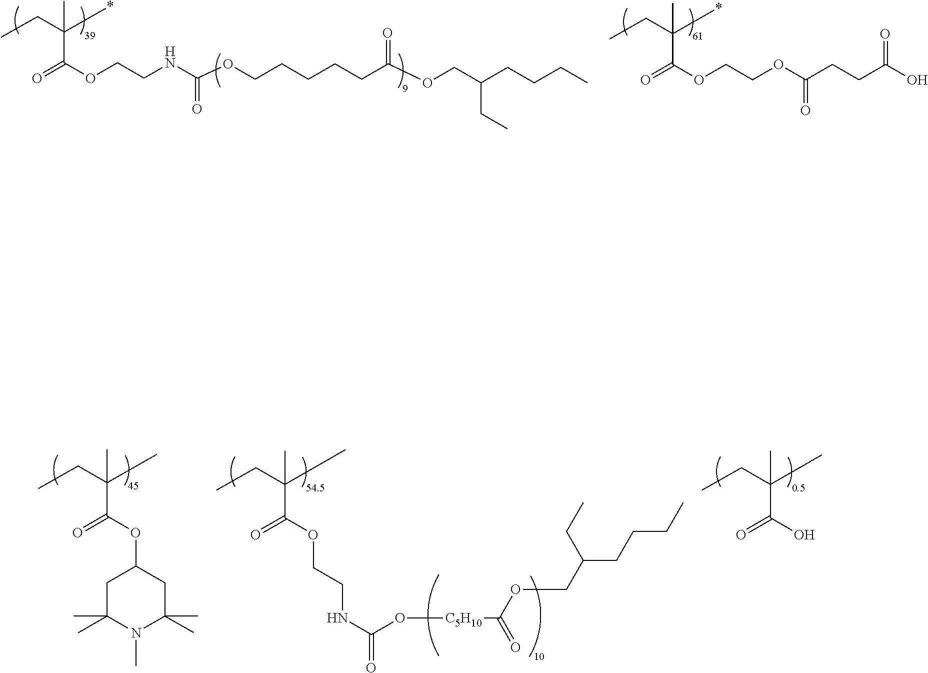

The resin can use an oligoimine-based resin including a nitrogen atom on at least one of a main chain or a side chain. As the oligoimine-based resin, a resin that has a repeating unit having a partial structure X having a functional group with pKa of 14 or less and a side chain including a side chain Y having 40 to 10,000 atoms and has a basic nitrogen atom at least one of main chain and a side chain is preferable. The basic nitrogen atom is not particularly limited, as long as the basic nitrogen atom is a nitrogen atom exhibiting basicity.

Examples of the oligoimine-based resin include a resin that includes a repeating unit represented by Formula (I-1), a repeating unit represented by Formula (I-2), and/or a repeating unit represented by Formula (I-2a).

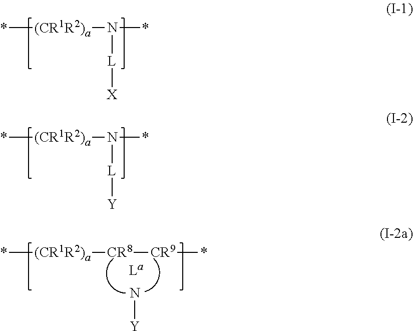

R¹ and R² each independently represent a hydrogen atom, a halogen atom, or an alkyl group (preferably having 1 to 6 carbon atoms). a each independently represent an integer of 1 to 5. * represents a linking portion between repeating units.

R⁸ and R⁹ are the same as R¹.

L is a single bond or a linking group relating to an alkylene group (preferably having 1 to 6 carbon atoms), an alkenylene group (preferably having 2 to 6 carbon atoms), an arylene group (preferably having 6 to 24 carbon atoms), a heteroarylene group (preferably having 1 to 6 carbon atoms), an imino group (preferably having 0 to 6 carbon atoms), an ether group, a thioether group, or a carbonyl group, or a combination thereof. Among these, a single bond or —CR⁵R⁶—NR⁷— (an imino group becomes X or Y) is preferable. Here, R⁵R⁶'s each independently represent a hydrogen atom, a halogen atom, and an alkyl group (preferably having 1 to 6 carbon atoms). R⁷ represents a hydrogen atom or an alkyl group having 1 to 6 carbon atoms.

L^{a} is a structural site that forms a ring structure together with CR⁸CR⁹ and N, and is preferably a structural site that is combined with a carbon atom of CR^{s}CR⁹ and that forms a nonaromatic heterocyclic ring having 3 to 7 carbon atoms. L^{a} is more preferably a structural site that is combined with a carbon atom and N (nitrogen atom) of CR⁸CR⁹ and forms a 5-membered to 7-membered nonaromatic heterocyclic ring, even more preferably a structural site that forms a 5-membered nonaromatic heterocyclic ring, and particularly preferably a structural site that forms pyrrolidine. This structural site may further have a substituent such as an alkyl group.

X represents a group having a functional group with pKa of 14 or less.

Y represents a side chain having 40 to 10,000 atoms.

The resin (oligoimine-based resin) may further contain at least one selected from repeating units represented by Formulae (I-3), (I-4), and (I-5), as copolymer components. If the resin includes these repeating units, dispersibility of the pigment can be further improved.

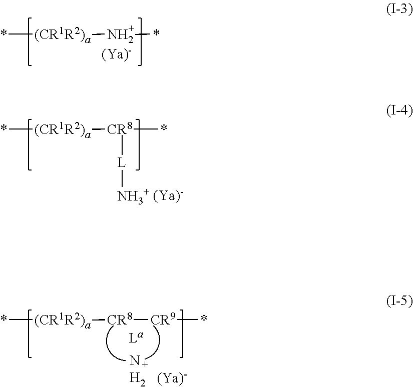

R¹, R², R⁸, R⁹, L, La, a, and * are the same as those regulated in Formulae (I-1), (I-2), and (I-2a).

Ya represents a side chain 40 to 10,000 atoms which has an anion group. The repeating unit represented by Formula (I-3) can be formed by adding an oligomer or a polymer that has a group that reacts with amine and forms salt to a resin that has a primary or secondary amino group in a main chain portion and causing reaction.

With respect to the oligoimine-based resin described above, disclosure of paragraph numbers 0102 to 0166 of JP2012-255128A can be referred to, and the contents thereof can be incorporated to this specification. Specific examples of the oligoimine-based resin include the following. Resins disclosed in paragraph numbers 0168 to 0174 of JP2012-255128A can be used.

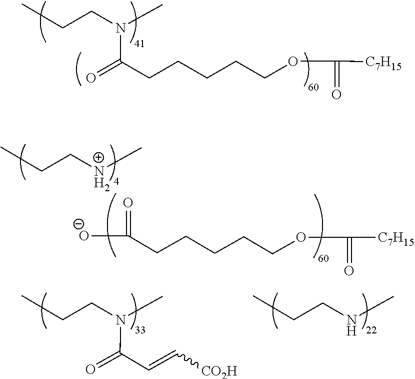

The resin can use a resin including a constitutional unit represented by Formula (P1). If a resin below is used, dispersibility of the coloring agent represented by Formula (1) can be further improved.

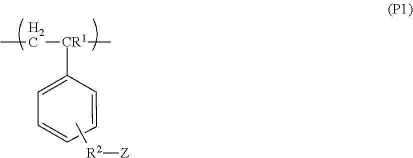

In Formula (P1), R¹ represents hydrogen or a methyl group, R² represents an alkylene group, and Z represents a nitrogen-containing heterocyclic structure.

The alkylene group represented by R² is not particularly limited. Examples thereof suitably include a methylene group, an ethylene group, a trimethylene group, a tetramethylene group, a hexamethylene group, a 2-hydroxypropylene group, a methyleneoxy group, an ethyleneoxy group, a methyleneoxycarbonyl group, and a methylenethio group. A methylene group, a methyleneoxy group, a methyleneoxycarbonyl group, and a methylenethio group are more preferable.

Examples of the nitrogen-containing heterocyclic structure represented by Z include structures having a pyridine ring, a pyrazine ring, a pyrimidine ring, a pyrrole ring, an imidazole ring, a triazole ring, a tetrazole ring, an indole ring, a quinoline ring, an acridine ring, a phenothiazine ring, a phenoxazine ring, an acridone ring, an anthraquinone ring, a benzimidazole structure, a benzotriazole structure, a benzthiazole structure, a cyclic amide structure, a cyclic urea structure, and a cyclic imide structure. Among these, as the nitrogen-containing heterocyclic structure represented by Z, a structure represented by Formula (P2) or (P3) is preferable.

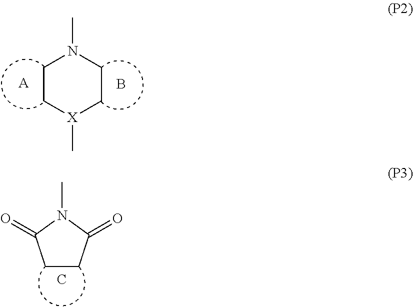

In Formula (P2), X is any one selected from a group consisting of a single bond, an alkylene group (for example, a methylene group, an ethylene group, a propylene group, a trimethylene group, and a tetramethylene group), —O—, —S—, —NR—, and —C(═O)—. Here, R represents a hydrogen atom or an alkyl group, and examples of the alkyl group in a case where R represents an alkyl group include a methyl group, an ethyl group, an n-propyl group, an i-propyl group, an n-butyl group, a t-butyl group, an n-hexyl group, an n-octyl group, a 2-ethylhexyl group, and an n-octadecyl group.

Among these, X is preferably a single bond, a methylene group, —O—, and —C(═O)—, and particularly preferably —C(═O)—.

In Formulae (P2) and (P3), a ring A, a ring B, and a ring C each independently represent an aromatic ring. Examples of the aromatic ring include a benzene ring, a naphthalene ring, an indene ring, an azulene ring, a fluorene ring, an anthracene ring, a pyridine ring, a pyrazine ring, a pyrimidine ring, a pyrrole ring, an imidazole ring, an indole ring, a quinoline ring, an acridine ring, a phenothiazine ring, a phenoxazine ring, an acridone ring, and an anthraquinone ring. Among these, a benzene ring, a naphthalene ring, an anthracene ring, a pyridine ring, a phenoxazine ring, an acridone ring, a phenothiazine ring, a phenoxazine ring, an acridine ring, and an anthraquinone ring are preferable, and a benzene ring, a naphthalene ring, and a pyridine ring are particularly preferable.

Specific examples of the structural unit represented by Formula (P1) include the following. Disclosure of paragraph number 0023 of JP2008-009426A can be also referred to, and the contents thereof are incorporated to this specification.

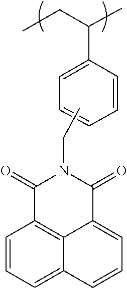

The resin including a structural unit represented by Formula (P1) further includes a structural unit represented by any one of Formulae (1) to (4) described above. A repeating unit represented by Formula (I-1) a repeating unit represented by Formula (I-2), and/or a repeating unit represented by Formula (I-2a) described above may be further included.

The resin can be obtained as commercially available products, and specific examples thereof include “Disperbyk-101 (polyamideamine phosphate salt), 107 (carboxylic acid ester), 110 and 111 (a copolymer containing an acid group), 130 (polyamide), 161, 162, 163, 164, 165, 166, and 170 (high molecular weight copolymer)” and “BYK-P104 and P105 (high molecular weight unsaturated polycarboxylic acid)” manufactured by BYK Chemie GmbH, “EFKA4047, 4050 to 4010 to 4165 (polyurethane-based), EFKA4330 to 4340 (block copolymer), 4400 to 4402 (modified polyacrylate), 5010 (polyesteramide), 5765 (high molecular weight polycarboxylate), 6220 (fatty acid polyester), 6745 (phthalocyanine derivative), and 6750 (azo pigment derivative)” manufactured by BASF SE, “AJISPER PB821, PB822, PB880, and PB881” manufactured by Ajinomoto Fine-Techno Co., Inc., “FLOWLEN TG-710 (urethane oligomer)” and “Polyflow No. 50E and No. 300 (acrylic copolymer)” manufactured by Kyoeisya Chemical Co., Ltd., “DISPARLON KS-860, 873SN, 874, and #2150 (aliphatic polyvalent carboxylic acid), #7004 (polyether ester), and DA-703-50, DA-705, and DA-725” manufactured by Kusumoto Chemicals Ltd., “DEMOL RN, and N (naphthalene sulfonic acid formalin polycondensate), MS, C, and SN-B (aromatic sulfonic acid formalin polycondensate)”, “HOMOGENOL L-18 (high molecular polycarboxylic acid)”, “EMULGEN 920, 930, 935, and 985 (polyoxyethylene nonylphenyl ether)”, and “ACETAMIN 86 (stearylamine acetate)” manufactured by Kao Corporation, “SOLSPERSE 5000 (phthalocyanine derivative), 22000 (azo pigment derivative), 13240 (polyesteramine), 3000, 17000, and 27000 (polymers having functional groups at terminals thereof), 24000, 28000, 32000, and 38500 (graft polymers)” manufactured by Lubrizol Japan Limited, “NIKKOLE T106 (polyoxyethylene sorbitan monooleate) and MYS-IEX (polyoxyethylene monostearate)” manufactured by Nikko Chemicals Co., Ltd., “HINOACT T-8000E” manufactured by Kawaken Fine Chemicals Co., Ltd., “an organosiloxane polymer KP-341” manufactured by Shin-Etsu Chemical Co., Ltd., “W001: cationic surfactant”, nonionic surfactants such as polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid ester, and anionic surfactants such as “W004, W005, and W017” manufactured by Yusho Co., Ltd., “EFKA-46, EFKA-47, EFKA-47EA, EFKA polymer 100, EFKA polymer 400, EFKA polymer 401, and EFKA polymer 450” manufactured by Morishita & Co., Ltd., polymer dispersants such as “DISPERSE AID 6, DISPERSE AID 8, DISPERSE AID 15, and DISPERSE AID 9100” manufactured by San Nopco Limited, ADEKA PLURONIC L31, F38, L42, L44, L61, L64, F68, L72, P95, F77, P84, F87, P94, L101, P103, F108, L121, and P-123 manufactured by ADEKA Corporation), and “IONET S-20” manufactured by Sanyo Chemical Industries.

These resins may be used singly or two or more types thereof may be used in combination. The resin may use an alkali soluble resin.

The alkali soluble resin can be appropriately selected from alkali soluble resins which are linear organic high molecular polymers and have at least one group that promotes alkali solubility in a molecule (preferably, a molecule using an acrylic copolymer or a styrene-based copolymer as a main chain). In view of heat resistance, a polyhydroxystyrene-based resin, a polysiloxane-based resin, an acrylic resin, an acrylamide-based resin, and acryl/acrylamide copolymer resins are preferable. In view of developability control, an acrylic resin, an acrylamide-based resin, and an acryl/acrylamide copolymer resins are preferable.

Examples of a group promoting alkali solubility (hereinafter, also referred to as an acid group) include a carboxyl group, a phosphoric acid group, a sulfonic acid group, and a phenolic hydroxyl group. However, groups that are soluble to an organic solvent and can be developed by a weak alkali aqueous solution are preferable, and (meth)acrylic acid is particularly preferable. These acid groups may be used singly or two or more types thereof may be used in combination. As the alkali soluble resin, disclosure of paragraphs 0558 to 0571 ([0685] to [0700] of corresponding US2012/0235099A) or following paragraphs of JP2012-208494A is referred to, and the contents thereof are incorporated to this specification.

As the alkali soluble resin, a resin including a compound represented by Formula (ED) below as a copolymer component is also preferable.

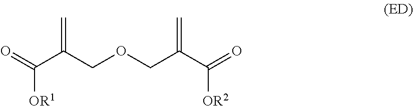

In Formula (ED), R¹ and R² each independently represent a hydrocarbon group having 1 to 25 carbon atoms that may have a hydrogen atom or a substituent.

The hydrocarbon group having 1 to 25 carbon atoms which is represented by R¹ and R² is not particularly limited. Examples thereof include a linear or branched alkyl group such as methyl, ethyl, n-propyl, isopropyl, n-butyl, isobutyl, t-butyl, t-amyl, stearyl, lauryl, and 2-ethylhexyl; an aryl group such as phenyl; an alicyclic ring-type group such as cyclohexyl, t-butylcyclohexyl, dicyclopentadienyl, tricyclodecanyl, isobornyl, adamantyl, and 2-methyl-2-adamantyl; an alkyl group substituted with alkoxy such as 1-methoxyethyl and 1-ethoxyethyl, and an alkyl group substituted with an aryl group such as benzyl. Among these, particularly, a primary or secondary hydrocarbon group that hardly separates due to acid or heat, such as methyl, ethyl, cyclohexyl, and benzyl is preferable in view of heat resistance.

R¹ and R² may be the same substituents or may be different substituents.

Examples of the compound represented by Formula (ED) include dimethyl-2,2′-[oxybis(methylene)]bis-2-propenoate, diethyl-2,2′-[oxybis(methylene)]bis-2-propenoate, di(n-propyl)-2,2′-[oxybis(methylene)]bis-2-propenoate, di(n-butyl)-2,2′-[oxybis(methylene)]bis-2-propenoate, di(t-butyl)-2,2′-[oxybis(methylene)]bis-2-propenoate, and di(isobutyl)-2,2′-[oxybis(methylene)]bis-2-propenoate. Among these, diethyl-2,2′-[oxybis(methylene)]bis-2-propenoate is preferable.

The copolymer components in addition to the compound represented by Formula (ED) are not particularly limited.

For example, in view of easy handleability such as solubility to a solvent, aryl (meth)acrylate, alkyl (meth)acrylate, and polyethyleneoxy (meth)acrylate are preferably included as a copolymer component, and aryl (meth)acrylate and alkyl (meth)acrylate are more preferable.

In view of alkali developability, a monomer having a carboxyl group such as (meth)acrylic acid and itaconic acid containing an acidic group, a monomer having a phenolic hydroxyl group such as N-hydroxyphenyl maleimide, and a monomer having a carboxylic acid anhydride group such as maleic anhydride and itaconic anhydride are preferably included as copolymer components, and (meth)acrylic acid is more preferable.

Examples of a preferable combination of copolymer components include a combination of the compound represented by Formula (ED), benzyl methacrylate, and methyl methacrylate, and/or methacrylic acid.

With respect to the resin including the compound represented by Formula (ED) as the copolymer component, disclosure of paragraph numbers 0079 to 0099 of JP2012-198408A can be referred to, and the contents thereof are incorporated to this specification.

The acid value of the alkali soluble resin is preferably 30 to 200 mgKOH/g. The lower limit is preferably 50 mgKOH/g or greater and more preferably 70 mgKOH/g or greater. The upper limit is preferably 150 mgKOH/g or less and more preferably 120 mgKOH/g or less.

The weight-average molecular weight (Mw) of the alkali soluble resin is preferably 2,000 to 50,000. The lower limit is preferably 5,000 or greater and more preferably 7,000 or greater. The upper limit is preferably 30,000 or less and more preferably 20,000 or less.

The content of the resin in the composition according to the invention is preferably 0.1 to 100 parts by mass with respect to 100 parts by mass of the coloring agent represented by Formula (1). The upper limit is preferably 80 parts by mass or less, more preferably 60 parts by mass or less, and even more preferably 40 parts by mass or less. The lower limit is preferably 0.5 parts by mass or greater and more preferably 1 part by mass or greater. If the content of the resin is in the range described above, the dispersibility of the coloring agent particles is satisfactory.

<Preparation of Composition>

The composition according to the invention can be prepared by mixing the respective components described above. At the time of the preparation of the composition, respective components that form the composition are collectively formulated, or the respective components may be sequentially formulated after being dissolved or dispersed in an organic solvent. An input order or a work condition at the time of formulation is not particularly limited.

The method of manufacturing the composition according to the invention preferably includes a step (dispersion step) of dispersing the coloring agent represented by Formula (1) in presence of at least one selected from a resin or an organic solvent. It is preferable that the dispersion step is further performed in presence of the coloring agent derivative represented by Formula (2) described above.

In a case where the composition according to the invention includes the coloring agent represented by Formula (1) and a coloring agent other than the coloring agent represented by Formula (1), the composition can be manufactured by dispersing (codispersing) the coloring agent represented by Formula (1) and coloring agents (other coloring agents) other than the coloring agent represented by Formula (1) coloring agent in presence of at least one selected from a resin or an organic solvent. It is preferable to further perform codispersion in presence of the coloring agent derivative represented by Formula (2) described above. The composition according to the invention can be manufactured by performing a dispersion step for each coloring agent and mixing compositions (dispersion liquids) obtained by dispersing respective coloring agents. In view of dispersion stability of the coloring agent represented by Formula (1), it is preferable to manufacture the composition according to the invention by codispersion.

For the purpose of removing foreign substances, reducing defects, or the like, the composition according to the invention is preferably filtrated with a filter. The filter can be used without limitation, as long as the filter is used for the filtration use in the related art.

Examples thereof include filters made of a fluorine resin such as polytetrafluoroethylene (PTFE), a polyamide resin such as nylon-6 and nylon-6,6, and polyolefin resin (including high density, ultrahigh molecular weight) such as polyethylene and polypropylene (PP). Among these materials, polypropylene (including high density polypropylene) and nylon are preferable.

A diameter of the filter is suitably about 0.1 to 7.0 μm, preferably about 0.2 to 2.5 μm, more preferably about 0.1 to 1.5 μm, and even more preferably about 0.3 to 0.7 μm. If the diameter is caused to be in this range, it is possible to securely remove fine foreign substances such as impurities or aggregates included in the composition, while the filter clogging is suppressed.

When the filter is used, other filters may be combined. At this point, the filtering in a first filter may be performed once or may be performed twice or more times. In a case where filtering is performed twice or more times by combining other filters, it is preferable that hole diameters of a second filter or thereafter are equal to or greater than a hole diameter of the first filter. A first filter having a different diameter may be combined. As the hole diameter herein, a nominal value of a filter manufacturer can be referred to. A commercially available can be selected from, for example, various filters provided by Nihon Pall Ltd., Toyo Roshi Kaisha, Ltd., Entegris Japan Co., Ltd. (formerly, Mykrolis Corporation), or Kitz Micro Filter Corporation.

As a second filter, a filter formed with the same material as the first filter described above can be used. A hole diameter of the second filter is suitably about 0.2 to 10.0 μm, preferably about 0.2 to 7.0 μm, and more preferably about 0.3 to 6.0 μm. If the hole diameter is in the range described above, foreign substances can be removed while component particles contained in the composition remain.

<Curable Composition>

The curable composition according to the invention includes the composition described above and a curable compound.

In the curable composition according to the invention, the content of the coloring agent can be adjusted, if necessary. For example, the content thereof is preferably 0.01 to 50 mass % with respect to the total solid content of the curable composition. The lower limit is preferably 0.1 mass % or greater and more preferably 0.5 mass % or greater. The upper limit is preferably 30 mass % or less and more preferably 15 mass % or less. In a case where the curable composition according to the invention includes two or more types of coloring agents, the total content thereof is preferably in the range described above.

<<Curable Compound>>

The curable composition according to the invention may contain a curable compound. The curable compound may be a compound having a polymerizable group (hereinafter, referred to as a “polymerizable compound”) or may be a non-polymerizable compound such as a binder. The curable compound may have any chemical form such as a monomer, an oligomer, a prepolymer, or a polymer. With respect to the curable compound, paragraphs 0070 to 0191 of JP2014-41318A (paragraphs 0071 to 0192 of corresponding WO2014/017669A), and paragraphs 0045 to 0216 of JP2014-32380A can be referred to, and the contents thereof are incorporated to this specification.

As the curable compound, a polymerizable compound is preferable. Examples of the polymerizable compound include a compound including an ethylenically unsaturated bond and a polymerizable group such as cyclic ether (epoxy and oxetane). Examples of the ethylenically unsaturated bond preferably include a vinyl group, a styryl group, a (meth)acryloyl group, and a (meth)allyl group. The polymerizable compound may be a monofunctional compound having one polymerizable group or may be a polyfunctional compound having two or more polymerizable groups. However, a polyfunctional compound is preferable. If the curable composition contains a polyfunctional compound, heat resistance can be further increased.

Examples of the curable compound include monofunctional (meth)acrylate, polyfunctional (meth)acrylate (preferably trifunctional to hexafunctional (meth)acrylate), a polybasic acid-modified acrylic oligomer, and a polyfunctional epoxy resin such as an epoxy resin.

The content of the curable compound is preferably 1 to 90 mass % with respect to the total solid content of the curable composition. The lower limit is preferably 5 mass % or greater, more preferably 10 mass % or greater, and even more preferably 20 mass % or greater. The upper limit is preferably 80 mass % or less and more preferably 75 mass % or less. In a case where a polymer including a repeating unit having a polymerizable group is used as a curable compound, the content of the curable compound is preferably 10 to 75 mass % with respect to a total solid content of the curable composition. The lower limit is preferably 20 mass % or greater. The upper limit is preferably 65 mass % or less and more preferably 60 mass % or less.

The curable compound may be used singly or two or more types thereof may be used in combination. In a case where two or more types are used, the total content is preferably in the range described above.

<<<Compound Including Ethylenically Unsaturated Bond>>>

According to the invention, as the curable compound, a compound including an ethylenically unsaturated bond can be used. As examples of the compound including an ethylenically unsaturated bond, paragraphs 0033 and 0034 of JP2013-253224A can be referred to, and the contents thereof are incorporated to this specification.

As a compound including an ethylenically unsaturated bond, ethyleneoxy-modified pentaerythritol tetraacrylate (as a commercially available product, NK ESTER ATM-35E; manufactured by Shin-Nakamura Chemical Co., Ltd.), dipentaerythritol triacrylate (as a commercially available product, KAYARAD D-330; manufactured by Nippon Kayaku Co., Ltd.), dipentaerythritol tetraacrylate (as a commercially available product, KAYARAD D-320; manufactured by Nippon Kayaku Co., Ltd.), dipentaerythritol penta(meth)acrylate (as a commercially available product, KAYARAD D-310; manufactured by Nippon Kayaku Co., Ltd.), dipentaerythritol hexa(meth)acrylate (as commercially available products, KAYARAD DPHA; manufactured by Nippon Kayaku Co., Ltd., A-DPH-12E; manufactured by Shin-Nakamura Chemical Co., Ltd.), and a structure in which ethylene glycol, propylene glycol residues are interposed between these (meth)acryloyl groups are preferable. An oligomer type of these can be used.

Polymerizable compounds of paragraphs 0034 to 0038 disclosed in JP2013-253224A can be referred to, and the contents thereof are incorporated to this specification.

Examples thereof include polymerizable monomers disclosed in paragraphs 0477 of JP2012-208494A (“0585” of corresponding US2012/0235099A), and the contents thereof are incorporated to this specification.

Diglycerine ethyleneoxide (EO)-modified (meth)acrylate (as a commercially available product, M-460; manufactured by Toagosei Co., Ltd.) is preferable. Pentaerythritol tetraacrylate (manufactured by Shin-Nakamura Chemical Co., Ltd., A-TMMT), 1,6-hexanediol diacrylate (manufactured by Nippon Kayaku Co., Ltd., KAYARAD HDDA) is also preferable. An oligomer type of these can be used. Examples thereof include RP-1040 (manufactured by Nippon Kayaku Co., Ltd.).

A compound including an ethylenically unsaturated bond may have an acid group such as a carboxyl group, a sulfonic acid group, and a phosphoric acid group.

Examples of a compound including an ethylenically unsaturated bond having an acid group include ester between an aliphatic polyhydroxy compound and an unsaturated carboxylic acid. A compound caused to have an acid group by being reacted with a non-aromatic carboxylic anhydride is preferable in an unreacted hydroxyl group of an aliphatic polyhydroxy compound. Particularly preferably, in this ester, an aliphatic polyhydroxy compound is pentaerythritol and/or dipentaerythritol. Examples of a commercially available product include M-305, M-510, and M-520 of ARONIX series, as a polybasic acid-modified acrylic oligomer manufactured by Toagosei Co., Ltd.

An acid value of the compound including an acid group and an ethylenically unsaturated bond is preferably 0.1 to 40 mgKOH/g. The lower limit is preferably 5 mgKOH/g or greater. The upper limit is preferably 30 mgKOH/g or less.

<<<Compound Having Epoxy Group or Oxetanyl Group>>>

According to the invention, a compound having an epoxy group or an oxetanyl group can be used as a curable compound. Examples of the compound having an epoxy group or an oxetanyl group include a polymer having an epoxy group on a side chain, and a monomer or a oligomer that has two or more epoxy groups in a molecule. Examples thereof include a bisphenol A-type epoxy resin, a bisphenol F-type epoxy resin, a phenol novolac-type epoxy resin, a cresol novolac-type epoxy resin, and an aliphatic epoxy resin. Examples thereof include a monofunctional or polyfunctional glycidyl ether compound, and a polyfunctional aliphatic glycidyl ether compound is preferable.

The weight-average molecular weight is preferably 500 to 5,000,000 and more preferably 1,000 to 500,000.

As these compounds, commercially available products may be used, or these compounds obtained by introducing an epoxy group to a side chain of a polymer can be used.

As a commercially available product, for example, disclosure of paragraph 0191 of JP2012-155288A can be referred to, and the contents thereof are incorporated to this specification.

Examples of a commercially available product include a polyfunctional aliphatic glycidyl ether compound such as DENACOL EX-212L, EX-214L, EX-216L, EX-321L, and EX-850L (above, manufactured by Nagase ChemteX Corporation). These are low chlorine products, but EX-212, EX-214, EX-216, EX-321, EX-850, and the like which are not low chlorine products can be used in the same manner.

Examples thereof also include ADEKA RESIN EP-4000S, ADEKA RESIN EP-4003S, ADEKA RESIN EP-4010S, and ADEKA RESIN EP-4011S (above, manufactured by ADEKA Corporation), NC-2000, NC-3000, NC-7300, XD-1000, EPPN-501, and EPPN-502 (above, manufactured by ADEKA Corporation), JER1031S, CELLOXIDE 2021P, CELLOXIDE 2081, CELLOXIDE 2083, CELLOXIDE 2085, EHPE3150, EPOLEAD PB 3600, EPOLEAD PB 4700 (above, manufactured by Daicel Corporation), CYCLOMER P ACA 200M, CYCLOMER P ACA 230AA, CYCLOMER P ACA Z250, CYCLOMER P ACA Z251, CYCLOMER P ACA Z300, and CYCLOMER P ACA Z320 (above, manufactured by Daicel Corporation).

Examples of a commercially available product of the phenol novolac-type epoxy resin include JER-157S65, JER-152, JER-154, and JER-157S70 (above are manufactured by Mitsubishi Chemical Corporation).

As specific examples of a polymer having an oxetanyl group on a side chain and a polymerizable monomer or a polymerizable oligomer that have two or more oxetanyl groups in a molecule, ARON OXETANE OXT-121, OXT-221, OX-SQ, and PNOX (above, manufactured by Toagosei Co., Ltd.) can be used.

As a compound having an epoxy group, a compound having a glycidyl group as a epoxy group such as glycidyl (meth)acrylate or allyl glycidyl ether can be used, but a preferable compound is an unsaturated compound having an alicyclic epoxy group. As this compound, disclosure of paragraph 0045 or the like of JP2009-265518A can be referred to, and the contents thereof are incorporated to this specification.

The compound including an epoxy group or an oxetanyl group may include a polymer having an epoxy group or an oxetanyl group as a repeating unit.

<<<Other Curable Compounds>>>

According to the invention, a polymerizable compound having a caprolactone-modified structure as a curable compound can be used.

As a polymerizable compound having a caprolactone-modified structure, disclosure of paragraphs 0042 to 0045 of JP2013-253224A can be referred to, and the contents thereof are incorporated to this specification.

Examples of the polymerizable compound having a caprolactone-modified structure include DPCA-20, DPCA-30, DPCA-60, and DPCA-120 which are commercially available as a KAYARAD DPCA series from Nippon Kayaku Co., Ltd., SR-494 which is tetrafunctional acrylate having four ethyleneoxy chains manufactured by Sartomer, and TPA-330 which is a trifunctional acrylate having three isobutyleneoxy chains.

<<Polymerization Initiator>>

The curable composition may include a polymerization initiator. The polymerization initiator is not particularly limited, as long as the polymerization initiator has performance of initiating polymerization of a polymerizable compound due to light, heat, or the both. The polymerization initiator can be appropriately selected according to the purpose.

In a case where the polymerization of the polymerizable compound is initiated with light, a photopolymerization initiator is preferable. The photopolymerization initiator preferably has photosensitivity to a range from an ultraviolet range to visible light.

In a case where a polymerizable compound is polymerized with heat, a thermal polymerization initiator is preferable. The thermal polymerization initiator is preferably decomposed at 150° C. to 250° C.

The polymerization initiator is preferably a compound having at least an aromatic group, and examples thereof include an acylphosphine compound, an acetophenone-based compound, an α-aminoketone compound, a benzophenone-based compound, a benzoin ether-based compound, a ketal derivative compound, a thioxanthone compound, an oxime compound, a hexaarylbiimidazole compound, a trihalomethyl compound, an azo compound, an organic peroxide, an onium salt compound such as a diazonium compound, an iodonium compound, a sulfonium compound, an azinium compound, and a metallocene compound, an organic boron salt compound, a disulfone compound, and a thiol compound.

As the polymerization initiator, paragraphs 0218 to 0251 of JP2014-41318A (paragraphs 0220 to 0253 of corresponding WO2014/017669A), and the contents thereof are incorporated to this specification.

The polymerization initiator is preferably an oxime compound, an acetophenone compound, or an acylphosphine compound.

Examples of the commercially available oxime compound include IRGACURE-OXE01 (manufactured by BASF SE), IRGACURE-OXE02 (manufactured by BASF SE), TR-PBG-304 (manufactured by Changzhou Tronly New Electronic Material Co., LTD.), ADEKA ARKLS NCI-831 (manufactured by ADEKA Corporation), and ADEKA ARKLS NCI-930 (manufactured by ADEKA Corporation).

An oxime initiator having a fluorine atom can be used. Specific examples of this initiator include compounds disclosed in JP2010-262028A, compounds 24 and 36 to 40 disclosed in paragraph 0345 of JP2014-500852A, and compound (C-3) disclosed in paragraph 0101 of JP2013-164471A. Oxime multimers disclosed in JP2010-527339A and WO2015/004565A can be used.

Commercially available products of the acetophenone compound include IRGACURE-907, IRGACURE-369, and IRGACURE-379 (product name: all manufactured by BASF SE).

Commercially available products of the acylphosphine compound include IRGACURE-819 and DAROCUR-TPO (product name: all are manufactured by BASF SE).

In the a case where the curable composition according to the invention contains a polymerization initiator, the content of the polymerization initiator is preferably 0.01 to 30 mass % with respect to the total solid content of the curable composition. The lower limit is preferably 0.1 mass % or greater. The upper limit is preferably 20 mass % or less and more preferably 15 mass % or less. The polymerization initiator may be used singly or two or more types thereof may be used in combination. In a case where two or more types are used, a total content is preferably in the range described above.

<<Alkali Soluble Resin>>

The curable composition according to the invention may contain an alkali soluble resin. If the alkali soluble resin is contained, desired patterns can be formed by alkali development. Examples of the alkali soluble resin include those described in the composition, and preferable ranges thereof are also the same.

In a case where the curable composition according to the invention contains an alkali soluble resin, the content of the alkali soluble resin is preferably 1 mass % or greater, may be 2 mass % or greater, may be 5 mass % or greater, and may be 10 mass % or greater with respect to a total solid content of the curable composition according to the invention. The content of the alkali soluble resin may be 80 mass % or less, may be 65 mass % or less, may be 60 mass % or less, and may be 15 mass % or less with respect to the total solid content of the curable composition according to the invention.

In a case where a pattern is not formed by an alkali development by using the curable composition according to the invention, it is obvious that an alkali soluble resin may not be contained.

<<Surfactant>>

The curable composition according to the invention may include a surfactant. The surfactant may be used singly or two or more types thereof may be used in combination. The content of the surfactant is preferably 0.0001 to 2 mass % with respect to the solid content of the curable composition according to the invention. The lower limit is preferably 0.005 mass % or greater and more preferably 0.01 mass % or greater. The upper limit is preferably 1.0 mass % or less and more preferably 0.1 mass % or less.

As the surfactant, various surfactants such as a fluorine-based surfactant, a nonionic surfactant, a cation-based surfactant, an anion-based surfactant, and a silicone-based surfactant can be used. The curable composition according to the invention preferably contains at least one of a fluorine-based surfactant or a silicone-based surfactant. Accordingly, interfacial tension between a coated surface and a coating liquid decreases, and wettability to the coated surface improves. Therefore, liquid characteristics (particularly, fluidity) of the curable composition increases, and evenness after coating and liquid saving properties further improve. As a result, even in a case where a thin film having about several μm is formed with a small amount of a liquid, a film with homogeneous thickness that has small unevenness can be suitably formed.

A fluorine content of the fluorine-based surfactant is preferably 3 to 40 mass %. The lower limit is preferably 5 mass % or greater and more preferably 7 mass % or greater. The upper limit is preferably 30 mass % or less and even more preferably 25 mass % or less. A case where the fluorine content is in the range described above is effective in view of evenness of the thickness of the coated film and liquid saving properties, and solubility is also satisfactory.

Specific examples of the fluorine-based surfactant include surfactants disclosed in paragraphs 0060 to 0064 of JP2014-41318A (paragraphs 0060 to 0064 of corresponding WO2014/17669A) and the contents thereof are incorporated to this specification. Examples of the commercially available product of the fluorine-based surfactant include MEGAFACE F-171, MEGAFACE F-172, MEGAFACE F-173, MEGAFACE F-176, MEGAFACE F-177, MEGAFACE F-141, MEGAFACE F-142, MEGAFACE F-143, MEGAFACE F-144, MEGAFACE R30, MEGAFACE F-437, MEGAFACE F-475, MEGAFACE F-479, MEGAFACE F-482, MEGAFACE F-554, MEGAFACE F-780, MEGAFACE F-781F (above, manufactured by DIC Corporation), FLUORAD FC430, FLUORAD FC431, FLUORAD FC171 (above, manufactured by Sumimoto 3M Limited.), SURFLON S-382, SURFLON SC-101, SURFLON SC-103, SURFLON SC-104, SURFLON SC-105, SURFLON SC-1068, SURFLON SC-381, SURFLON SC-383, SURFLON S-393, and SURFLON KH-40 (above, Asahi Glass Co., Ltd.).

Compounds below are exemplified as fluorine-based surfactants used in the invention.

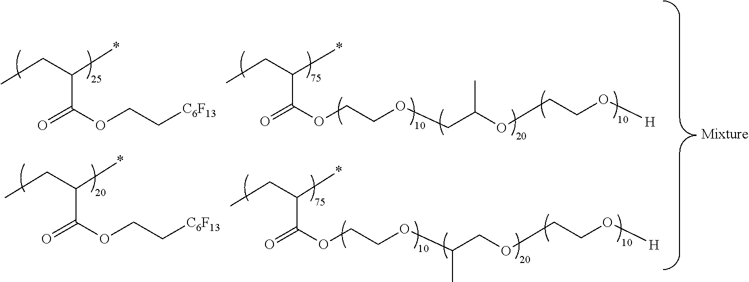

A weight-average molecular weight of the compound is, for example, 14,000.

Specific examples of the nonionic surfactant further include nonionic surfactants disclosed in paragraph 0553 of JP2012-208494A ([0679] of corresponding US2012/0235099A), and the contents thereof are incorporated to this specification.

Specific examples of the cation-based surfactant include cation-based surfactants disclosed in paragraph 0554 of JP2012-208494A ([0680] of corresponding US2012/0235099A), and the contents thereof are incorporated to this specification.

Examples of the silicone-based surfactant include silicone-based surfactants disclosed in paragraph 0556 of JP2012-208494A ([0682] of corresponding US2012/0235099A), and the contents thereof are incorporated to this specification.

<<Polymerization Inhibitor>>

In the manufacturing or preservation, the curable composition according to the invention may contain a small amount of polymerization inhibitor, in order to preventing unnecessary reaction of the curable compound.

Examples of the polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and N-nitrosophenylhydroxylamine cerous salt, and p-methoxyphenol is preferable.

In a case where the curable composition according to the invention contains a polymerization inhibitor, the content of the polymerization inhibitor is preferably 0.01 to 5 mass % with respect to the total solid content of the curable composition of the invention.

<<Organic Solvent>>

The curable composition according to the invention may contain an organic solvent. Examples of the organic solvent include those described in the composition above, and preferable ranges thereof are also the same.

With respect to the content of the solvent in the curable composition according to the invention, a total solid content of the curable composition according to the invention is preferably an amount of 5 to 90 mass %, more preferably an amount of 10 to 80 mass %, and even more preferably an amount of 20 to 75 mass %.

<<Other Coloring Agents>>

The curable composition according to the invention may include coloring agents (other coloring agents) other than the coloring agent represented by Formula (1). Examples of the other coloring agents include colorants described in the composition described above, and the like. The other coloring agents can be appropriately selected by the use of the curable composition.

For example, in a case where an infrared transmission filter that can only transmit near-infrared rays at a specific wavelength or greater is formed by using the curable composition according to the invention, an infrared transmission filter in which the colorant described above is preferably used. For example, two or more types of colorants selected from a red colorant, a yellow colorant, a blue colorant, and a violet colorant (preferably, a red colorant, a yellow colorant, a blue colorant, and a violet colorant) are used together, so as to transmit near-infrared rays, and which blocks light at a wavelength of 400 to 900 nm and transmits near-infrared rays having a wavelength of 900 nm or greater can be formed.

Specifically, it is preferable to contain C. I. pigment red 254 as a red pigment, C. I. pigment yellow 139 as a yellow pigment, C. I. pigment blue 15:6 as a blue pigment, and C. I. pigment violet 23 as a violet pigment. In a case where the colorant is obtained by combining a red colorant, a yellow colorant, a blue colorant, and a violet colorant, it is preferable that a mass ratio of a red colorant is 0.1 to 0.4 with respect to the total amount of the colorant, a mass ratio of a yellow colorant is 0.1 to 0.4 with respect to the total amount of the colorant, a mass ratio of the blue colorant is 0.2 to 0.6 with respect to the total amount of the colorant, and a mass ratio of the violet colorant is 0.01 to 0.30 with respect to the total amount of the colorant. It is more preferable that a mass ratio of the red colorant is 0.2 to 0.4 with respect to the total amount of the colorant, a mass ratio of a yellow colorant is 0.2 to 0.4 with respect to the total amount of the colorant, a mass ratio of the blue colorant is 0.2 to 0.5 with respect to the total amount of the colorant, and a mass ratio of the violet colorant is 0.05 to 0.25 with respect to the total amount of the colorant. With respect to a ratio between the coloring agent represented by Formula (1) and the colorant, the colorant is preferably contained in a ratio of 50 to 500 parts by mass and is more preferably contained in a ratio of 100 to 300 parts by mass with respect to 100 parts by mass of the coloring agent represented by Formula (1).

<<Other Components>>

In the curable composition according to the invention, other components are appropriately selected and used depending on the purpose, without deteriorating the effect of the invention.

Examples of other components that can be used together include a dispersing agent, a sensitizing agent, a crosslinking agent (crosslinking agent aqueous solution), acetic anhydride, a silane compound, a hardening accelerator, a filler, a plasticizer, an adhesion promoter, and other auxiliary agents (for example, conductive particles, a filler, an antifoaming agent, a flame retardant, a leveling agent, a peeling promoter, an antioxidant, a fragrance material, a surface tension adjuster, and a chain transfer agent) may be used together.

As these components, for example, disclosure in paragraph numbers 0183 to 0228 of JP2012-003225A (“0237” to “0309” of corresponding US2013/0034812A), paragraph numbers 0101 and 0102 of JP2008-250074A, paragraph numbers 0103 to 0104 of JP2008-250074A, paragraph numbers 0107 and 0109 of JP2008-250074A, and paragraph numbers 0159 to 0184 of JP2013-195480A can be referred to, and the contents thereof are incorporated to this specification.

If these components are appropriately contained, desired properties such as stability of the near-infrared cut filter and film characteristics can be adjusted.

<Preparation of Curable Composition>

The curable composition according to the invention can be prepared by mixing respective components described above. For the purpose of removing foreign substances or reducing defects, it is preferable that filtration is performed with a filter. Examples of the types of filter and the filtration method include those described in the composition, and preferable ranges thereof are also the same.

<Use of Curable Composition>

The curable composition according to the invention can be caused to be liquid, and thus a cured film such as the near-infrared cut filter can be easily manufactured by applying the curable composition according to the invention to a base material or the like and drying the curable composition.

In a case where a cured film is formed by coating, the viscosity of the curable composition according to the invention is preferably 1 to 3,000 mPa·s. The lower limit is preferably 10 mPa·s or greater and more preferably 100 mPa·s or greater. The upper limit is preferably 2,000 mPa·s or less and more preferably 1,500 mPa·s or less.

The total solid content of the curable composition according to the invention is changed depending on the coating method. However, for example, the total solid content is preferably 1 to 50 mass %. The lower limit is more preferably 10 mass % or greater. The upper limit is more preferably 30 mass % or less.

The use of the curable composition according to the invention is not particularly limited. However, for example, the curable composition according to the invention can be preferably used for a near-infrared cut filter (for example, for a near-infrared cut filter to a wafer leveling lens) of a solid-state imaging device on a light receiving side or a near-infrared cut filter of a solid-state imaging device on a back surface side (an opposite side of a light receiving side). The curable composition according to the invention can be particularly preferably used as a near-infrared cut filter of a solid-state imaging device on a light receiving side. The curable composition according to the invention can be used as a near-infrared cut filter in an infrared sensor of an infrared sensor that detects an object by detecting light at a wavelength of 700 to 1,000 nm.

In addition to the colorant represented by Formula (1) described above, a curable composition that further contains a coloring agent described above can form a filter that have both functions of a near-infrared cut filter and a color filter.

The curable composition can be used for forming an infrared transmission filter that can transmit near-infrared rays having a specific wavelength or greater. For example, an infrared transmission filter that blocks light at a wavelength of 400 to 900 nm and that transmits near-infrared rays at a wavelength of 900 nm or greater can be formed. In this case, it is preferable to use both of a combination of chromatic pigments that block visible light and the coloring agent represented by Formula (1) according to the invention. With respect to the infrared transmission filter, a maximum value of the transmittance of the light in a thickness direction of the film in a wavelength range of 400 to 830 nm is preferably 20% or less and more preferably 10% or less. A minimum value of a transmittance of light in a thickness direction of the film in a wavelength range of 1,000 to 1,300 nm is preferably 65% or greater and more preferably 70% or greater. A/B which is a ratio between a minimum value A of absorbance in the wavelength range of 400 to 830 nm and a maximum value B of absorbance in the wavelength range of 1,000 to 1,300 nm is preferably 4.5 or greater and more preferably 8 or greater.

<Cured Film and Near-Infrared Cut Filter>

Subsequently, the cured film and the near-infrared cut filter according to the invention are described.

The cured film and the near-infrared cut filter according to the invention are obtained by hardening the curable composition according to the invention described above.

Film thicknesses of the cured film and the near-infrared cut filter can be appropriately adjusted depending on purposes. The film thicknesses are preferably 20 μm or less, more preferably 10 Lm or less, and even more preferably 5 μm or less. For example, the lower limit of the film thicknesses is preferably 0.1 μm or greater, more preferably 0.2 μm or greater, and even more preferably 0.3 μm or greater.

The near-infrared cut filter and the cured film according to the invention can be used for a lens (a lens for a camera such as a digital camera, a cellular phone, or a vehicle camera, or an optical lens such as a f-0 lens or a pickup lens) having a function of absorbing and cutting infrared rays, an optical filter for a semiconductor light-receiving element, a near-infrared absorption film or a near-infrared absorption plate that cuts off heat rays for energy saving, an agricultural coating agent for the purpose of selective use of sunlight, a recording medium that uses absorption heat of near-infrared rays, a near-infrared filter for electronic equipment and photos, safety glasses, sunglasses, a heat ray cut film, recording for optical character reading, the use of the confidential document copy prevention, an electrophotographic photoreceptor, laser welding, and the like. The near-infrared cut filter and the cured film according to the invention can also used for a noise cut filter for a CCD camera, a filter for a CMOS infrared sensor, or an infrared transmission filter.

<Method of Manufacturing Cured Film and Near-Infrared Cut Filter>

The cured film and the near-infrared cut filter can be manufactured by a step of applying the curable composition according to the invention. Specifically, the cured film and the near-infrared cut filter can be manufactured by a step of forming a film by applying the curable composition according to the invention to a support and a step of drying the film. Film thicknesses and laminate structures can be appropriately selected depending on purposes. A step of forming patterns may be further performed.

A step of forming a film can be performed, by using the curable composition according to the invention on a support by a dropwise addition method (drop cast), a spin coater, a slit spin coater, a slit coater, screen printing, applicator coating, and the like. In a case of a dropwise addition method (drop cast), it is preferable to form a dropwise addition area of a curable composition having a photoresist as a partition wall on a support such that an even film in a predetermined film thickness can be obtained. The thickness of the film after drying is not particularly limited, and can be appropriately selected depending on the purpose.

The support is applied may be a transparent substrate consisting of glass or the like. The support may be a solid-state imaging device, may be another substrate provided on a light receiving side of the solid-state imaging device, and may be a layer such as a planarizing layer or the like provided on a light receiving side of the solid-state imaging device.

In a step of drying a film, the dry condition is different depending on respective components, types of solvents, use ratio, and the like. For example, the dry condition is preferably in a temperature of 60° C. to 150° C. for about 30 seconds to 15 minutes.

Examples of the step of forming a pattern include methods including a step of forming a film-shaped composition layer obtained by applying the curable composition according to the invention on the support, a step of exposing the composition layer in a pattern shape, and a step of forming a pattern by developing and removing unexposed portions, and the like. As a step of forming a pattern, photolithography or a dry etching method may be used for forming a pattern.

In the method of manufacturing the cured film and the near-infrared cut filter, other steps may be included. The other steps are not particularly limited, and can be appropriately selected depending on purposes. Examples thereof include a step of treating a surface of a substrate, a preheating step (prebaking step), a hardening treatment step, and a post heating step (post baking step).

<<Preheating Step and Post Heating Step>>

The heating temperature in the preheating step and post heating step is generally 80° C. to 200° C. The upper limit is preferably 150° C. or less. The lower limit is preferably 90° C. or greater.

The heating time in the preheating step and the post heating step is preferably 30 to 240 seconds. The upper limit is preferably 180 seconds or less. The lower limit is preferably 60 seconds or greater.

<<Hardening Treatment Step>>

A hardening treatment step is a step of performing a hardening treatment on a formed film, if necessary. If this treatment is performed, mechanical strength of the cured film and the near-infrared cut filter is improved.

The hardening treatment step is not particularly limited, and can be appropriately selected depending on purposes. Examples thereof suitably include an exposure treatment and an entire surface heating treatment. Here, the expression “exposure” according to the invention is used as a meaning of including not only light in various wavelengths but also radioactive ray irradiation such as electron rays or X rays.

The exposure is preferably performed by irradiation of radioactive rays. As the radioactive that can be used at the time of exposure, particularly, electron rays, KrF, ArF, ultraviolet rays such as g rays, h rays, and i rays, or visible light are preferably used.

Examples of an exposure technique include stepper exposure or exposure by a high pressure mercury vapor lamp.

An exposure amount is preferably 5 to 3,000 mJ/cm². The upper limit is preferably 2,000 mJ/cm² or less and more preferably 1,000 mJ/cm² or less. The lower limit is preferably 10 mJ/cm² or greater and more preferably 50 mJ/cm² or greater.

Oxygen concentration at the time of exposure can be appropriately selected. In addition to exposure the atmosphere, the exposure may be performed in a low oxygen atmosphere (for example, 15 volume %, 5 volume %, and substantially oxygen free) in which oxygen concentration is, for example, 19 volume % or less, and exposure may be performed in a high oxygen atmosphere (for example, 22 volume %, 30 volume %, and 50 volume %) in which oxygen concentration is greater than 21 volume %. The exposure illuminance can be appropriately set, the exposure illuminance can be generally selected from the range 1,000 W/m² to 100,000 W/m² (for example, 5,000 W/m², 15,000 W/m², 35,000 W/m²). Appropriate conditions of the oxygen concentration and the exposure illuminance may be combined, and the oxygen concentration and the exposure illuminance may be, for example, oxygen concentration of 10 volume % and illuminance of 10,000 W/m² or may be oxygen concentration of 35 volume % and illuminance of 20,000 W/m².

Examples of the entire surface exposure treatment include a method of exposing an entire surface of the formed film. In a case where the curable composition according to the invention contains a polymerizable compound, hardening of the polymerizable compounds is promoted by the entire surface exposure, such that hardening of the film further proceeds, and mechanical strength and durability further improve.

A device for performing the entire surface exposure is not particularly limited, and can be appropriately selected depending on purposes, and examples thereof suitably include a ultraviolet exposure machine such as a high pressure mercury vapor lamp.

Examples of the entire surface heating treatment method include a method of heating the entire surface of the formed film. With the heating of the entire surface, the film hardness of the pattern can be increased.

The heating temperature of the heating of the entire surface is preferably 100° C. to 260° C. The lower limit is preferably 120° C. or greater and more preferably 160° C. or greater. The upper limit is preferably 240° C. or less and more preferably 220° C. or less. If the heating temperature is in the range described above, a film having excellent strength can be easily obtained.

The heating time when the entire surface is heated is preferably 1 to 180 minutes. The lower limit is preferably 3 minutes or longer. The upper limit is preferably 120 minutes or less.

A device for heating the entire surface is not particularly limited, and can be appropriately selected among well-known devices, depending on purposes. Examples thereof include a dry oven, a hot plate, and an IR heater.

<Solid-State Imaging Device, Camera Module, and Infrared Sensor>

The solid-state imaging device according to the invention is obtained by using the curable composition according to the invention or includes the cured film according to the invention.

The camera module according to the invention has a solid-state imaging device and the near-infrared cut filter according to the invention.

The infrared sensor according to the invention is obtained by using the curable composition according to the invention or includes the cured film according to the invention.

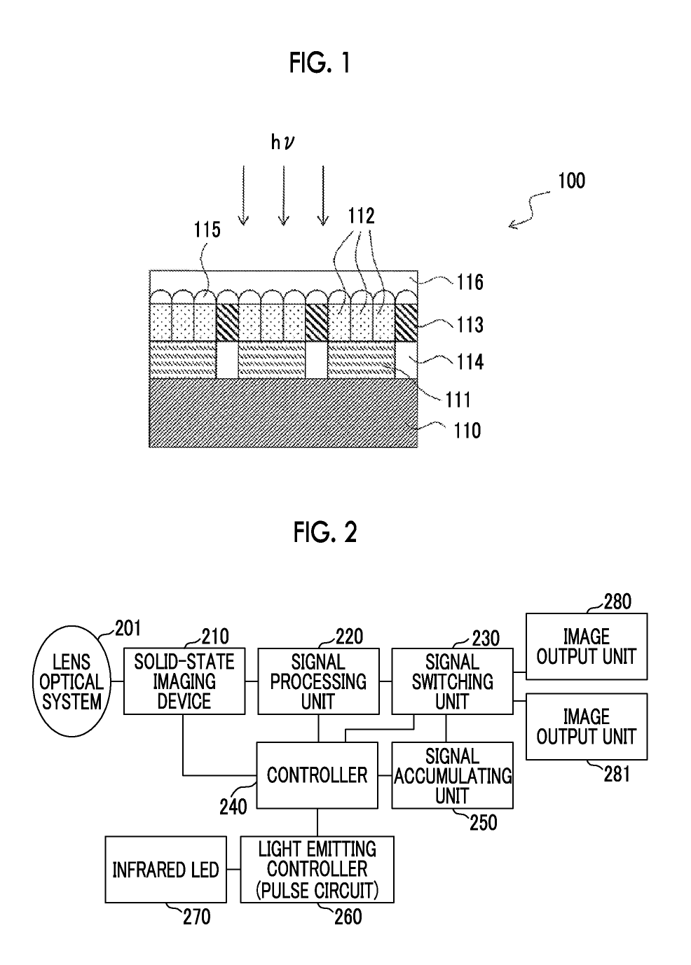

Hereinafter, one embodiment of the infrared sensor according to the invention is described by using FIG. 1.

In an infrared sensor 100 illustrated in FIG. 1, a reference numeral 110 is a solid-state imaging device.

An image pick-up area provided on the solid-state imaging device 110 has infrared cut filter 111 and a color filter 112. The near-infrared cut filter 111 can be formed, for example, by using the curable composition according to the invention.

Areas 114 are provided between infrared transmission filters 113 and the solid-state imaging device 110. Resin layers (for example, transparent resin layers) that light in a wavelength that transmits the infrared transmission filters 113 transmits are provided on the areas 114. In the embodiment illustrated in FIG. 1, a resin layer is provided on the areas 114, but the infrared transmission filters 113 may be formed on the areas 114. That is, the infrared transmission filters 113 may be formed on the solid-state imaging device 110.

Microlenses 115 are provided on incidence rays ho side of the color filters 112 and the infrared transmission filters 113. A planarizing layer 116 is formed so as to cover the microlenses 115.

According to the embodiment illustrated in FIG. 1, film thicknesses of the color filters 112 and film thicknesses of the infrared transmission filters 113 are the same, but film thicknesses of the both may be different from each other.

According to the embodiment illustrated in FIG. 1, the color filters 112 are provided on the incidence rays ho side of the near-infrared cut filters 111, but the near-infrared cut filters 111 may be provided on the incidence rays ho side of the color filters 112 by changing an order of the near-infrared cut filters 111 and the color filters 112.

According to the embodiment illustrated in FIG. 1, the near-infrared cut filters 111 and the color filters 112 are laminate to be adjacent to each other, but both of the filters do not have to be adjacent to each other and other layers may be interposed therebetween.

According to the embodiment illustrated in FIG. 1, the near-infrared cut filters 111 and the color filters 112 are provided as separate members. However, the color filters 112 may be caused to have functions as near-infrared cut filters by causing the color filters 112 to contain the composition according to the invention. In this case, the near-infrared cut filter 111 may be omitted.

<<Near-Infrared Cut Filter 111>>

Characteristics of the near-infrared cut filter 111 are selected by a light emitting wavelength of an infrared light emitting diode (LED) described below. For example, the near-infrared cut filter 111 can be formed by using the curable composition according to the invention described above.

<<Color Filter 112>>

The color filters 112 are not particularly limited, and color filters for forming pixels in the related art can be used. For example, disclosure in paragraphs 0214 to 0263 of JP2014-043556A can be referred to, and the contents thereof are incorporated to this specification.

<<Infrared Transmission Filter 113>>

Characteristics of the infrared transmission filters 113 are selected depending on a light emitting wavelength of an infrared LED described below. For example, description below are provided in an assumption that a light emitting wavelength of an infrared LED is 830 nm.

With respect to the infrared transmission filters 113, a maximum value of the light transmittance in the thickness direction of the film in a wavelength range of 400 to 650 nm are preferably 30% or less, more preferably 20% or less, even more preferably 10% or less, and particularly preferably 0.1% or less. The transmittance thereof preferably satisfies the condition above in the entire wavelength range of 400 to 650 nm. A maximum value in the wavelength range of 400 to 650 nm is generally 0.1% or greater.

With respect to the infrared transmission filter 113, a minimum value of the light transmittance in a thickness direction of the film at a wavelength range of 800 nm or greater (preferably 800 to 1,300 nm) is preferably 70% or greater, more preferably 80% or greater, even more preferably 90% or greater, and particularly preferably 99.9% or greater. The transmittance thereof preferably satisfies the conditions described above at a portion of a wavelength range of 800 nm or greater and preferably satisfies the conditions described above at a wavelength of the light emitting wavelength of the infrared LED. The minimum value of the light transmittance in the wavelength range of 900 to 1,300 nm is generally 99.9% or less.

The film thickness of the infrared transmission filter 113 is preferably 100 μm or less, more preferably 15 μm or less, even more preferably 5 μm or less, and particularly preferably 1 μm or less. The lower limit value is preferably 0.1 μm. If the film thickness in the range described above, it is possible to cause the film to satisfy spectroscopic properties described above.

The spectroscopic properties of the infrared transmission filter 113, a method of measuring a film thickness, and the like are provided below.

The film thickness is measured by using a substrate after drying that has a film and a stylus type surface profile measuring device (DEKTAK150 manufactured by ULVAC Technologies, Inc.).

The spectral characteristics of the film are values obtained by measuring transmittance in a wavelength range of 300 to 1,300 nm by using a spectrophotometer (ref. glass substrate) of a ultraviolet-visible-near-infrared spectrophotometer (U-4100 manufactured by Hitachi High-Technologies Corporation).

Conditions of the light transmittance may be achieved by any means. However, for example, conditions of the light transmittance can be achieved by causing the composition to contain two or more types of pigments and adjusting types and contents and of respective pigments.

For example, the infrared transmission filter 113 can be manufactured by using the colorant described above (preferably, a composition (infrared transmissive composition) including a colorant containing two or more colorants selected from a red colorant, a yellow colorant, a blue colorant, and a violet colorant.

The content of the pigment in the colorant is preferably 95 mass % or greater, more preferably 97 mass % or greater, and even more preferably 99 mass % or greater with respect to a total amount of the colorant. The upper limit of the content of the pigment in the colorant is 100 mass % or less with respect to the total amount of the colorant.

As the preferable embodiment of the colorant, two or more colorant s selected from a red colorant, a yellow colorant, a blue colorant, and a purple colorant are preferably contained, and a red colorant, a yellow colorant, a blue colorant, and a purple colorant are more preferably contained. As preferable specific examples, it is preferable to contain C. I. pigment red 254 as a red pigment, C. I. pigment yellow 139 as a yellow pigment, C. I. pigment blue 15:6 as a blue pigment, and C. I. pigment violet 23 as a violet pigment.

In a case where the colorant contained in the infrared transmissive composition is obtained by combining a red colorant, a yellow colorant, a blue colorant, and a violet colorant, it is preferable that a mass ratio of the red colorant is 0.2 to 0.5, a mass ratio of the yellow colorant is 0.1 to 0.2, a mass ratio of the blue colorant is 0.25 to 0.55, and a mass ratio of the violet colorant is 0.05 to 0.15 with respect to the total amount of the colorant. It is more preferable that a mass ratio of the red colorant is 0.3 to 0.4, a mass ratio of the yellow colorant is 0.1 to 0.2, a mass ratio of the blue colorant is 0.3 to 0.4, and a mass ratio of the violet colorant is 0.05 to 0.15 with respect to the total amount of the colorant.

The infrared transmission filter 113 can be formed by using the curable composition according to the invention. That is, it is possible to form an infrared transmission filter that can block light at a wavelength of 400 to 900 nm and transmit near infrared rays at a wavelength of 900 nm or greater by using two or more colorants selected from the coloring agent represented by Formula (1), a red colorant, a yellow colorant, a blue colorant, and a violet colorant (preferably, a red colorant, a yellow colorant, a blue colorant, and a violet colorant). With respect to this infrared transmission filter, a maximum value of the transmittance of the light in a thickness direction of the film in the wavelength range of 400 to 830 nm is preferably 20% or less and more preferably 10% or less. A minimum value of the transmittance of the light in a thickness direction of the film in the wavelength range of 1,000 to 1,300 nm is preferably 65% or greater and more preferably 70% or greater. A/B which is a ratio of the minimum value A of the absorbance at a wavelength range of 400 to 830 nm and the maximum value B of the absorbance at a wavelength of 1,000 to 1,300 nm is preferably 4.5 or greater and more preferably 8 or greater. In this case, the light emitting wavelength of the infrared LED is 930 to 950 nm.

Subsequently, an image pick-up device as an example in which the infrared sensor according to the invention is applied is described. As the infrared sensor, a motion sensor, a proximity sensor, a gesture sensor, and the like exist.

FIG. 2 is a functional block diagram of an image pick-up device. The image pick-up device comprises a lens optical system 201, a solid-state imaging device 210, a signal processing unit 220, a signal switching unit 230, a controller 240, a signal accumulating unit 250, a light emitting controller 260, an infrared LED 270 of a light emitting element that emitting infrared light, and image output units 280 and 281. As the solid-state imaging device 210, the infrared sensor 100 described above can be used. All or a portion of the configurations except for those of the solid-state imaging device 210 and the lens optical system 201 may be formed on the same semiconductor substrate. With respect to the respect configurations of the image pick-up device, paragraphs 0032 to 0036 of JP2011-233983A are referred to, and the contents thereof are incorporated to this specification.

A camera module having a solid-state imaging device and the near-infrared ray absorption filter described above is incorporated to the image pick-up device.

<Compound>

Subsequently, the compound according to the invention is described.

The compound according to the invention is the compound represented by Formula (3) described in the coloring agent derivative of the composition according to the invention, and suitable ranges thereof are also the same as those described above.

For example, the compound according to the invention can be used for a use of an infrared cut filter for a plasma display panel (PDP) or CCD or an optical filter as a heat ray shielding film, a use of a photothermal conversion material as a recordable optical disc (CD-R) or a flash melting fixing material, and an information display material as security ink or invisible bar code ink.

### EXAMPLES

Hereinafter, the invention is described in detail with reference to examples. Materials, use amounts, ratios, process details, process orders, and the like provided in the examples below can be appropriately changed without departing from the gist of the invention. Accordingly, ranges of the invention are not limited to the specific examples described below. Unless described otherwise, “%” and “parts” are based on a mass.

<Synthesis of Compound (A-1)>

An exemplary compound (A-1) was synthesized by schemes below.

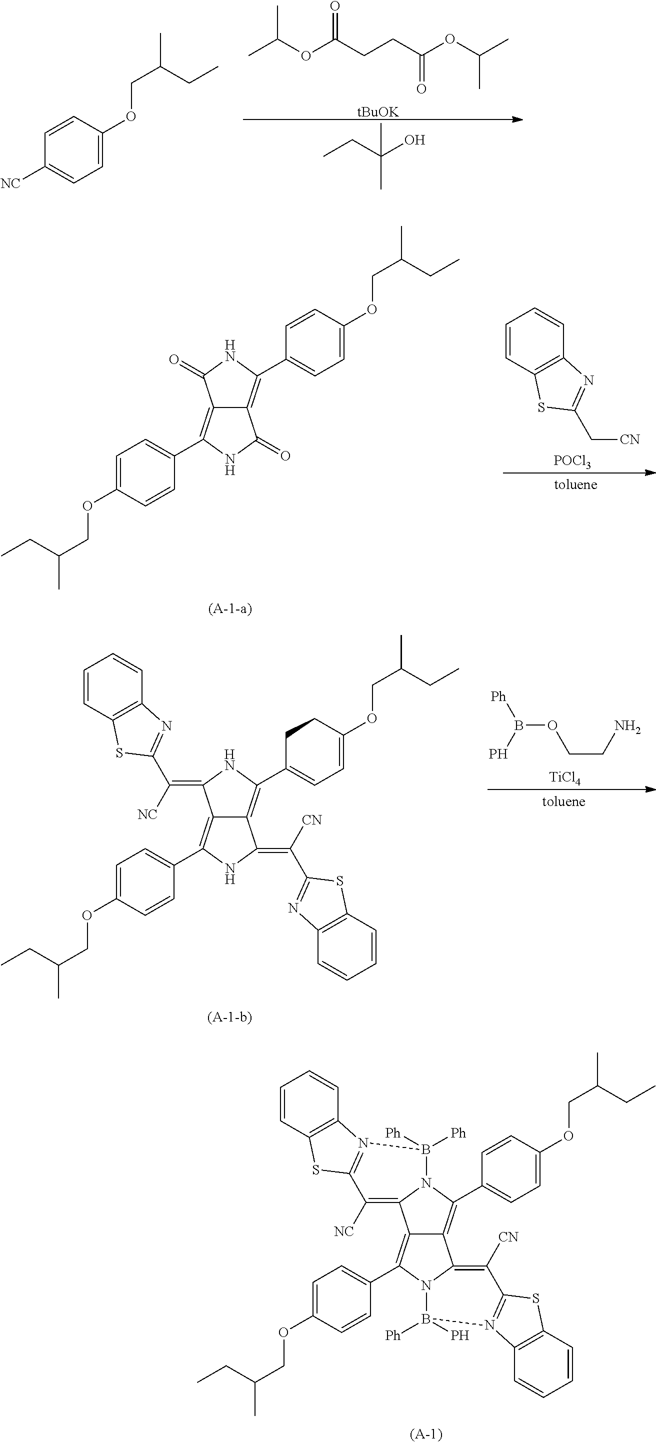

(A-1-a) was synthesized using 4-(2-methylbutoxy) benzonitrile as a raw material by a method disclosed in U.S. Pat. No. 5,969,154A.

¹H-NMR (DMSO/THF mixture): 60.95 (t, 3H), 1.02 (d, 3H), 1.58 (m, 1H), 1.87 (m, 1H), 3.92 (m, 2H), 7.66 (d, 2H), and 8.54 (d, 2H)

179 parts by mass of (A-1-a) and 162.5 parts by mass of 2-(2-benzothiazolyl) acetonitrile were stirred in 1,840 parts by mass of toluene, and 476.74 parts by mass of phosphorus oxychloride was added dropwise, and heating reflux is performed for 3.5 hours. After the reaction was completed, cooling was performed to an internal temperature of 25° C., and 1,800 parts by mass of methanol was added dropwise over 90 minutes while an internal temperature of 30° C. or less was maintained. After the dropwise addition was completed, stirring was performed for 30 minutes in room temperature. The precipitated crystal was filtrated, 450 parts by mass of methanol was washed. 2,300 parts by mass of methanol was added to obtained crystals, heating reflux was performed for 30 minutes, cooling was performed to 30° C., and the crystals were filtrated. The obtained crystals were dried with air at 40° C. for 12 hours, and blast drying was performed, so as to obtain 240 parts by mass of (A-1-b).

¹H-NMR (CDCl₃): δ0.99 (t, 3H), 1.07 (d, 3H), 1.58 (m, 1H), 1.93 (m, 1H), 3.93 (m, 2H), 7.15 (d, 2H), 7.66 (d, 2H), and 8.54 (d, 2H)

119 parts by mass of diphenylborinic acid 2-aminoethyl ester and 170 parts by mass of (A-1-b) was stirred in 2,840 parts by mass of toluene, 167 parts by mass of titanium tetrachloride was added dropwise over 30 minutes at an outside temperature of 40° C., and stirring was performed for 30 minutes. The temperature was increased to an outside temperature of 130° C. and heating reflux was performed for three hours. Cooling was performed to an internal temperature of 30° C., and 1,620 parts by mass of methanol was added dropwise, while the temperature was maintained to an internal temperature of 30° C. or less. The stirring was performed for 30 minutes after dropwise addition, precipitated crystal was filtrated, and washing was performed with 150 parts by mass of methanol. 1,500 parts by mass of methanol was added to obtained crystals, stirring was performed in room temperature for 10 minutes, and an operation of filtering the crystals was performed twice. 2,000 parts by mass of THF was added to the obtained crystals, heating reflux was performed for 30 minutes, cooling was performed to 30° C. or less, and the crystals were filtrated. The obtained crystals were subjected to blast drying at 40° C. for 12 minutes, so as to obtain 234 parts by mass of the compound (A-1). A peak having a molecular weight of 1,100.5 was observed by MALDI-MS, and thus the resultant was identified as the compound (A-1). λmax of (A-1) was 780 nm in chloroform.

<Synthesis of Compound (A-2)>

An exemplary compound (A-2) was synthesized by schemes below.

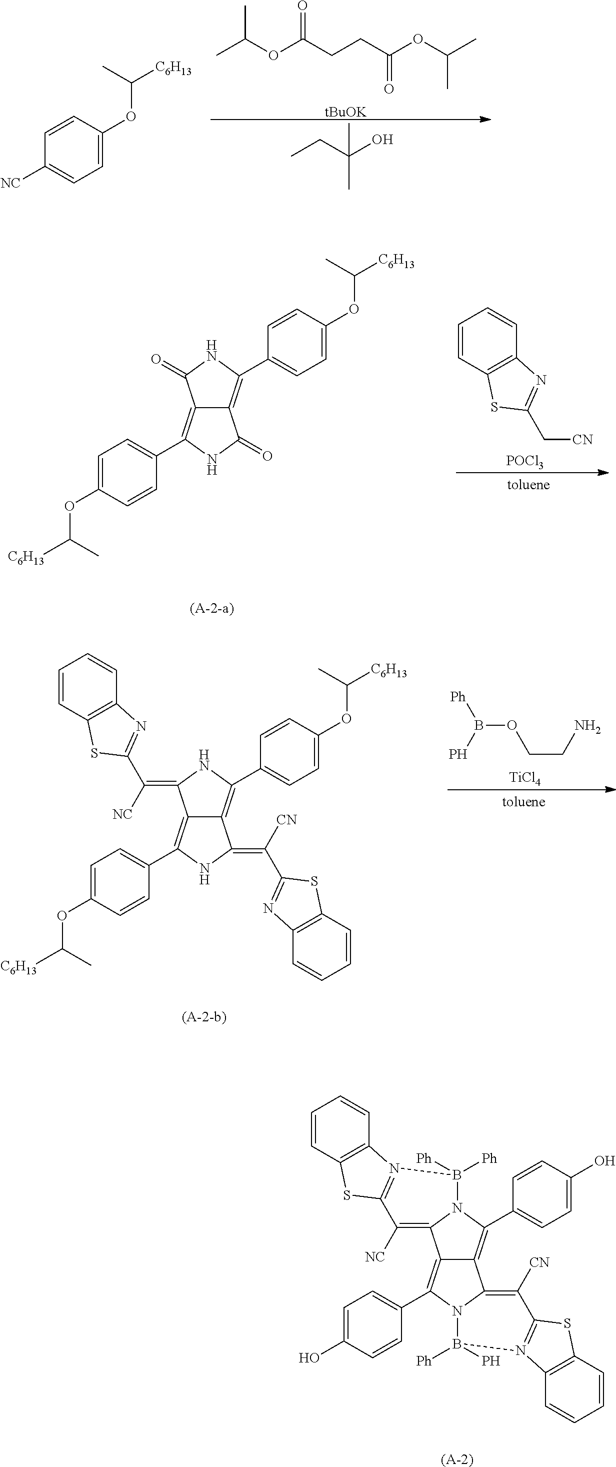

(A-2-a) was synthesized using 4-(1-methylheptoxy) benzonitrile as a raw material by a method disclosed in U.S. Pat. No. 5,969,154A.

¹H-NMR (a mixture liquid of d-DMSO (dimethylsulfoxide):28 mass % methanol solution of sodium methoxide=95:5 (mass ratio)); 60.82 (t, 6H), 1.15-1.70 (m, 26H), 4.40 (m, 2H), 6.78 (d, 4H), and 8.48 (d, 2H)

20.0 parts by mass of (A-2-a) and 15.4 parts by mass of 2-(2-benzothiazolyl) acetonitrile were stirred in 230 parts by mass of toluene, 45.0 parts by mass of phosphorus oxychloride was added dropwise, and heating reflux was performed for 3.5 hours. After the reaction was completed, cooling was performed to an internal temperature of 25° C., and 200 parts by mass of methanol was added dropwise over 60 minutes while an internal temperature of 30° C. or less was maintained. After the dropwise addition was completed, stirring was performed in room temperature for 30 minutes. Precipitated crystals were filtrated and were washed with 100 parts by mass of methanol. Heating reflux was performed for 30 minutes by adding 200 parts by mass of methanol to the obtained crystal, cooling was performed to 30° C., and the crystals were filtrated. The obtained crystals were subjected to blast drying at 40° C. for 12 hours, so as to obtain 8.8 parts by mass of (A-2-b).

¹H-NMR (CDCl₃): δ0.90-1.90 (m, 32H), 4.54 (m, 2H), 7.12 (d, 4H), 7.20-7.40 (m, 2H), 7.43 (t, 2H), 7.75 (d, 4H), and 7.81 (t, 4H)

3.9 parts by mass of diphenylborinic acid 2-aminoethyl ester and 6.0 parts by mass of (A-2-b) were stirred in 60 parts by mass of toluene at an outside temperature of 40° C., 10.6 parts by mass of titanium tetrachloride was added dropwise over 10 minutes, and stirring was performed for 30 minutes. The temperature was increased to an outside temperature of 130° C. and heating reflux was performed for three hours. Cooling was performed to an internal temperature of 30° C., and 40 parts by mass of methanol was added dropwise while an internal temperature of 30° C. or less was maintained. After the dropwise addition was completed, stirring was performed for 30 minutes, and precipitated crystals were filtrated and were washed with 35 parts by mass of methanol. Heating reflux was performed for 30 minutes by adding 50 parts by mass of methanol to the obtained crystal, cooling was performed to 30° C., and an operation of filtrating the crystals was performed twice. The obtained crystals were subjected to blast drying at 40° C. for 12 hours, so as to obtain 4.6 parts by mass of the compound (A-2). A peak having a molecular weight of 1,090.9 was observed by MALDI (Matrix Assisted Laser Desorption/Ionization)-MS (Mass Spectrometry), and thus the resultant was identified as the compound (A-2). λmax of (A-2) was 782 nm in dimethylsulfoxide (DMSO).

<Synthesis of Compound (A-3)>

An exemplary compound (A-3) was synthesized by schemes below.

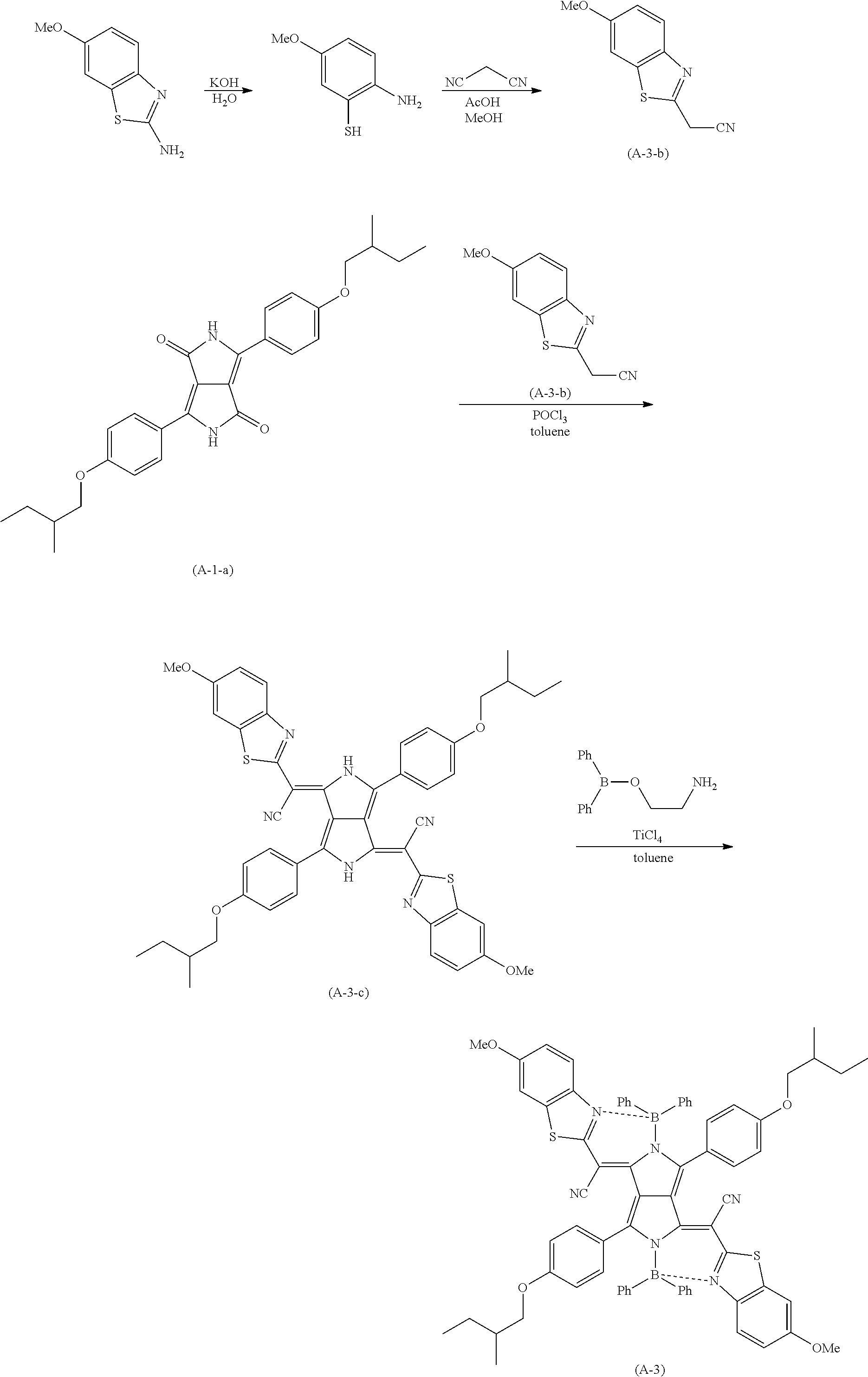

50.0 parts by mass of 2-amino-6-methoxybenzothiazole and 93.4 parts by mass of potassium hydroxide were subjected to heating reflux in 200 parts by mass of water for 24 hours, and cooling was performed to 10° C. or less. While the temperature was remained to 10° C. or less such that pH of the reaction solution became 6, 6 N hydrochloric acid and acetic acid were added. Precipitated crystals were filtrated and were washed with 200 parts by mass of water. A total amount of the obtained crystals, 18.3 parts by mass of malononitrile and 19.3 parts by mass of acetic acid were stirred in 172 parts by mass of methanol for one hour at 60° C., and cooling was performed to 10° C. or less. The precipitated crystals were filtrated and were washed with 200 parts by mass of cold methanol. The obtained crystals were subjected to blast drying at 40° C. for 12 hours, so as to obtain 38.7 parts by mass of (A-3-b).

¹H-NMR (CDCl₃): δ3.85 (s, 3H), 4.22 (s, 2H), 7.16 (d, 1H), 7.38 (s, 1H), and 7.97 (d, 1H)

(A-3-c) was synthesized using (A-1-a) and (A-3-b) as raw materials in the same method as the synthesis of (A-1-b).

¹H-NMR (a mixture liquid of d-DMSO (dimethylsulfoxide):28 mass % methanol solution of sodium methoxide=95:5 (mass ratio)); 60.98 (t, 6H), 1.12 (d, 6H), 1.30 (m, 2H), 1.63 (m, 2H), 1.95 (m, 2H), 3.89 (m, 4H), 6.88 (d, 2H), 6.98 (d, 4H), 7.42 (m, 4H), 7.67 (s, 2H), and 7.85 (d, 4H)

(A-3) was synthesized using (A-3-c) as a raw material in the same method as in the synthesis of (A-1). A peak having a molecular weight of 1,161.1 was observed by MALDI-MS, and thus the resultant was identified as the compound (A-3). λmax of (A-3) was 802 nm in chloroform.

¹H-NMR (CDCl₃): δ1.00 (t, 6H), 1.05 (d, 6H), 1.33 (m, 2H), 1.63 (m, 2H), 1.95 (m, 2H), 3.74 (m, 4H), 6.46 (s, 8H), 6.57 (d, 2H), 6.85 (d, 2H), 6.98 (s, 2H), 7.20 (m, 12H), and 7.25 (m, 8H)

<Synthesis of Compounds (A-4) to (A-9)>

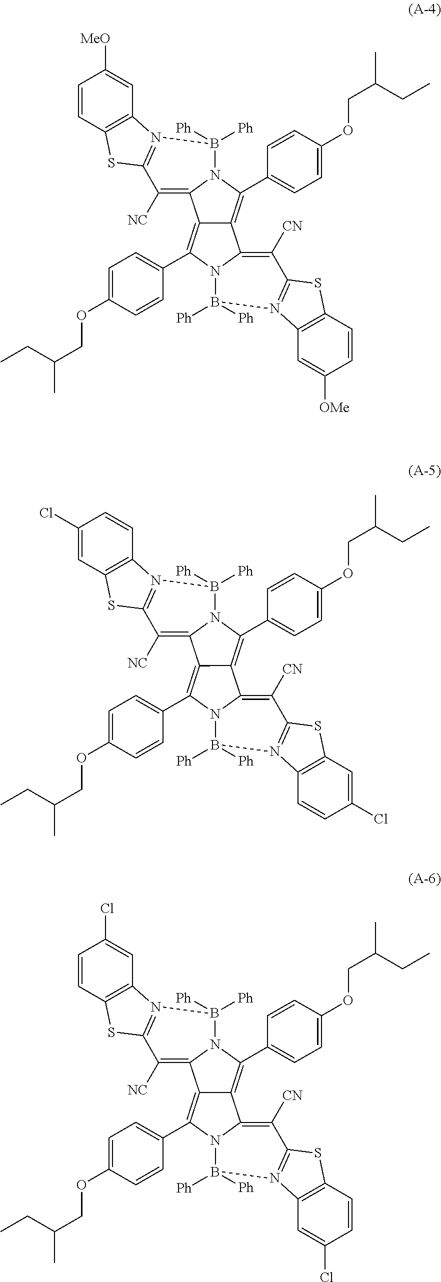

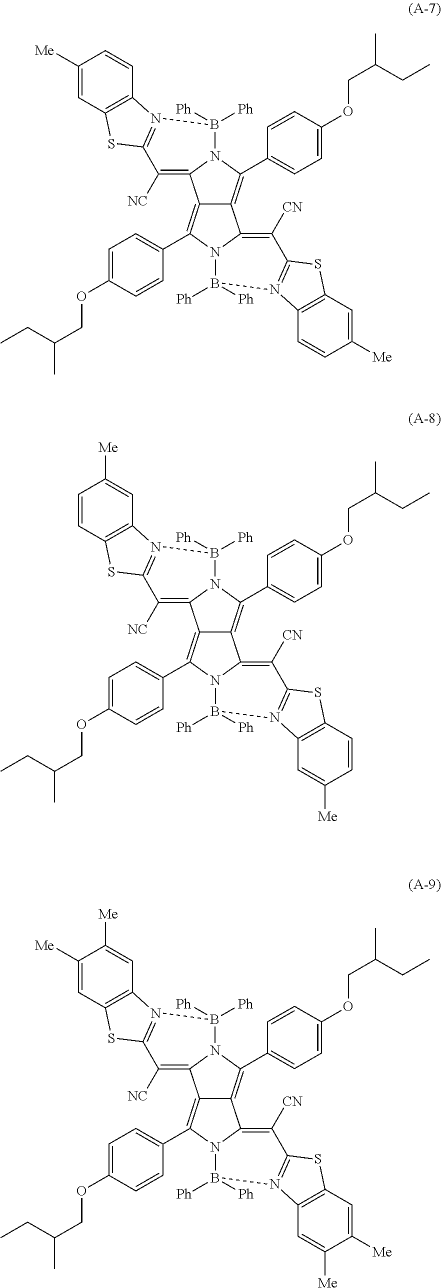

Compounds (A-4) to (A-9) were synthesized in the same manner as the synthesis of the compound (A-3). Molecular weights of all the compounds by MALDI-MS were the same as theoretical values, and thus the resultants were identified as the desired compounds. λmax of (A-4) was 794 nm, λmax of (A-5) was 786 nm, λmax of (A-6) was 782 nm, λmax of (A-7) was 788 nm, λmax of (A-8) was 785 nm, and λmax of (A-9) was 794 nm in chloroform.

<Synthesis of Compound (A-10)>

An exemplary compound (A-10) was synthesized by schemes below.

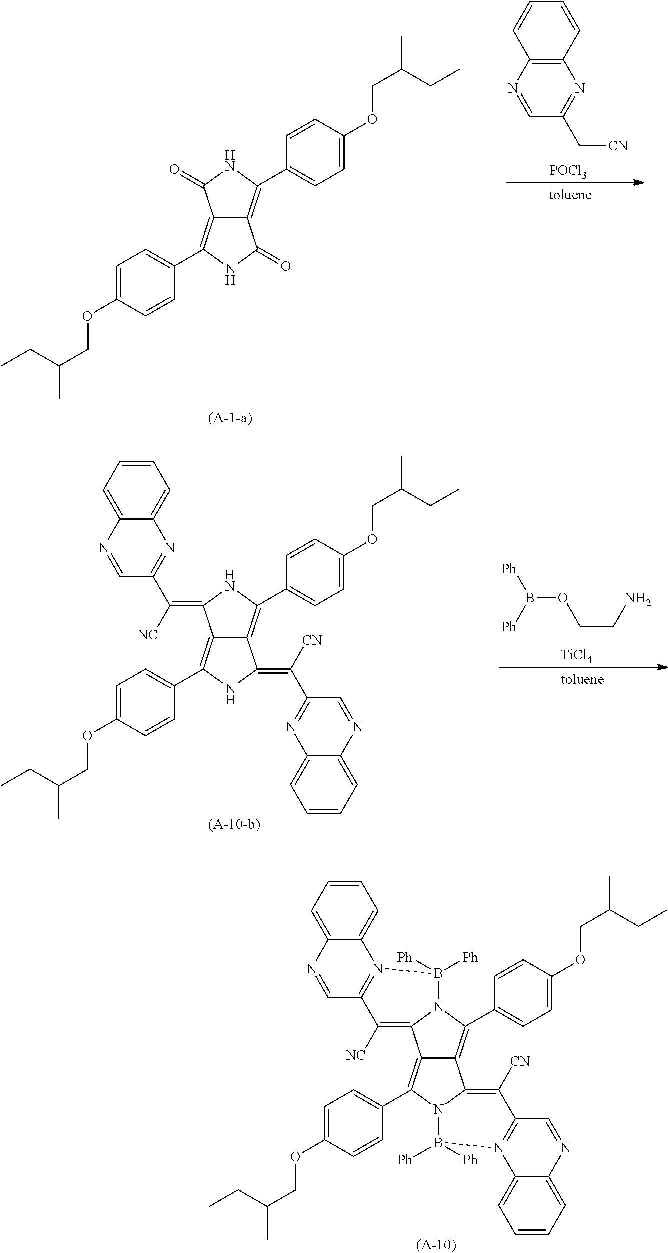

179 parts by mass of (A-1-a) and 7.1 parts by mass of 2-(2-quinoxalinyl) acetonitrile were stirred in 90.5 parts by mass of toluene, 21.3 parts by mass of phosphorus oxychloride was added dropwise, and heating reflux was performed for 3.5 hours. After the reaction was completed, cooling was performed to an internal temperature of 25° C., 80 parts by mass of methanol was added dropwise over 60 minutes while the temperature was maintained to an internal temperature of 30° C. or less. After the dropwise addition was completed, stirring was performed in room temperature for 30 minutes. Precipitated crystals were filtrated and were washed with 80 parts by mass of methanol. Heating reflux was performed for 30 minutes by adding 100 parts by mass of methanol to the obtained crystal, cooling was performed to 30° C., and the crystals were filtrated. The obtained crystals were subjected to blast drying at 40° C. for 12 hours, so as to obtain 3.6 parts by mass of (A-10-b).

¹H-NMR (CDCl₃): δ0.87 (t, 6H), 0.99 (d, 6H), 1.30-2.00 (m, 6H), 3.99 (m, 4H), 7.20 (d, 4H), 7.60-7.80 (m, 10H), 8.03 (d, 2H), 9.10 (s, 2H), and 14.07 (s, 2H)

5.6 parts by mass of diphenylborinic acid 2-aminoethyl ester and 2.0 parts by mass of (A-10-b) were stirred in 40 parts by mass of toluene, 7.8 parts by mass of titanium tetrachloride was added dropwise over 10 minutes at an outside temperature of 40° C., and stirring was performed for 30 minutes. The temperature was increased to an outside temperature of 130° C. and heating reflux was performed for 1.5 hours. Cooling was performed to an internal temperature of 30° C., and 40 parts by mass of methanol was added dropwise while an internal temperature of 30° C. or less was maintained. After the dropwise addition was completed, stirring was performed for 30 minutes, and precipitated crystals were filtrated and were washed with 80 parts by mass of methanol. Heating reflux was performed for 30 minutes by adding 60 parts by mass of methanol to the obtained crystal, cooling was performed to 30° C., and an operation of filtrating the crystals was performed twice. The obtained crystals were subjected to blast drying at 40° C. for 12 hours, so as to obtain 1.9 parts by mass of the compound (A-10). A peak having a molecular weight of 1,090.9 was observed by MALDI-MS, and thus the resultant was identified as the compound (A-10). λmax of (A-10) was 862 nm in chloroform.

¹H-NMR (CDCl₃): δ1.02 (t, 6H), 1.10 (d, 6H), 1.34 (m, 2H), 1.57 (m, 2H), 2.00 (m, 2H), 3.85 (m, 4H), 6.19 (d, 4H), 6.59 (d, 4H), 7.10-7.32 (m, 24H), 7.72 (d, 2H), 8.00 (d, 2H), and 9.06 (s, 2H)

<Synthesis of Compound (B-1)>

3 parts by mass of the compound (A-1) was added to 20.7 parts by mass of 30% fuming sulfuric acid and stirred at 25° C. for two hours, while an internal temperature of 5° C. or less was maintained. The reaction solution was added while being stirred in diisopropyl ether, and precipitated crystals were filtrated. Suspension washing was performed twice on the obtained crystals with diisopropyl ether, and the obtained crystals were dried at 40° C. for 12 hours, so as to obtain a compound (B-1). The resultant was identified as (B-1) from ¹H-NMR (CDCl₃). As a result of acid value measurement (THF/aqueous solution, titration liquid: 0.1 N NaOH aqueous solution), an acid value thereof was 186 mgKOH/g, and the number of sulfonic acid groups (the number of m's) was 1.8.

### Test Example 1

<Preparation of Composition (Dispersion Liquid)>

10 parts by mass of a near-infrared absorbing coloring agent subjected to a soft milling treatment which is presented in Table 1, 3.0 parts by mass of a coloring agent derivative which is presented in Table 1, 7.8 parts by mass of a dispersed resin which is presented in Table 1, 109 parts by mass of a solvent which is presented in Table 1, and 520 parts by mass of zirconia beads having a diameter of 0.5 mm were subjected to a distributed processing for 30 minutes, with a paint shaker, filtration was performed by using DFA4201NXEY (0.45 μm nylon filter) manufactured by Nihon Pall Ltd., and beads were separated with filtration, so as to manufacture a composition (dispersion liquid).

<Preparation of Curable Composition>

After components below were mixed, filtration was performed by using DFA4201NXEY (0.45 μm nylon filter) manufactured by Nihon Pall Ltd., so as to manufacture the curable composition.
Dispersion liquid described above: 13.5 parts by mass
polymerizable compound: CYCLOMER P (ACA) 230AA (manufactured by Daicel Corporation): 25 parts by mass
Polymerizable compound: KAYARAD DPHA (manufactured by Nippon Kayaku Co., Ltd.): 3.2 parts by mass
Photopolymerization initiator: IRGACURE OXE01 (manufactured by BASF SE):2 parts by mass
Polymerization inhibitor: p-Methoxyphenol: 0.001 parts by mass
   Surfactant: MEGAFACE F-781F (manufactured by DIC Corporation, fluorine-containing polymer-type surfactant): 0.004 parts by mass
Organic solvent: Propylene glycol monomethyl ether acetate: 56 parts by mass

<Method of Manufacturing Cured Film>

A substrate was coated with a curable composition by a spin coating method, and heating is thereafter performed for two minutes at 100° C. on a hot plate, so as to obtain a curable composition coated layer. The obtained curable composition coated layer was exposed by an exposure amount of 100 mJ/cm² by using an i-line stepper or an aligner. The coated layer after exposure was subjected to a hardening treatment on a hot plate at 230° C. for 5 minutes, so as to obtain a cured film of about 1.5 μm.

<Viscosity of Dispersion Liquid>

Viscosity of a dispersion liquid at 25° C. in 1,000 rpm was measured by using an E-type viscometer and was evaluated in the following standards.

A: 20 mPa·s or less

B: greater than 20 mPa·s and 100 mPa·s or less

C: greater than 100 mPa·s

<Average Particle Diameter>

An average primary particle diameter and an average secondary particle diameter of the coloring agent particles included in the dispersion liquid right after the manufacturing were measured by respective methods described below and were evaluated by the following standards.

Method of measuring average primary particle diameter: A dispersion liquid was diluted with propylene glycol monomethyl ether acetate, was added dropwise to a mesh for an electron microscopy, and was dried. Thereafter, TEM observation (TEM: 1200EX manufactured by JEOL Ltd., Acceleration voltage: 80 kV, and Observation magnification: ×100 K) was performed and 100 particles were extracted and measured.

—Evaluation Standard of Average Primary Particle Diameter—

A: 100 nm or less

B: greater than 100 nm and 200 nm or less

C: greater than 200 nm

A method of measuring an average secondary particle diameter: An average secondary particle diameter was measured by using MICROTRACUPA 150 manufactured by Nikkiso Co., Ltd. in a volume basis.

—Evaluation Standard of Average Secondary Particle Diameter—

A: 300 nm or less

B: greater than 300 nm and 500 nm or less

C: greater than 500 nm

<Light Fastness>

A cured film was set to a Fading tester provided with a super xenon lamp (100,000 lux), and light irradiation was performed for 50 hours under the condition in which an infrared cut filter was not used. Subsequently, a transmission spectrum of the cured film after irradiation was measured, and a residual ratio thereof with respect to the absorbance of the maximum absorption wavelength was calculated from an equation below and was evaluated in the following standards.

Residual ratio (%)=(absorbance after irradiation)/(absorbance before irradiation)×100

A: residual ratio of 95% to 100%

B: residual ratio of greater than 80% and less than 95%

C: residual ratio of 80% or less

TABLE 1

| | | | | | | | Average | Average |
|---|---|---|---|---|---|---|---|---|
| | Near-infrared | Coloring | | | Viscosity of | Light | primary | secondary |
| | absorption | agent | Dispersed | | dispersion | fastness of | particle | particle |
| | coloring agent | derivative | resin | Solvent | liquid | cured film | diameter | diameter |
| Example 1 | A-1 | B-1 | C-3 | PGMEA | A | A | A | A |
| Example 2 | A-1 | B-22 | C-3 | PGMEA | A | A | A | A |
| Example 3 | A-1 | B-23 | C-3 | PGMEA | A | A | A | A |
| Example 4 | A-1 | B-24 | C-5 | PGMEA | A | A | A | A |
| Example 5 | A-1 | B-25 | C-5 | PGMEA | A | A | A | A |
| Example 6 | A-1 | B-26 | C-3 | PGMEA | A | A | A | A |
| Example 7 | A-1 | B-27 | C-5 | PGMEA | A | A | A | A |
| Example 8 | A-1 | B-28 | C-3 | PGMEA | A | A | A | A |
| Example 9 | A-1 | B-29 | C-3 | PGMEA | A | A | A | A |
| Example 10 | A-1 | B-30 | C-5 | PGMEA | A | A | A | A |
| Example 11 | A-1 | B-30 | C-1 | Cyclohexanone | A | A | A | A |
| Example 12 | A-1 | B-30 | C-2 | Cyclohexanone | A | A | A | A |
| Example 13 | A-1 | B-30 | C-3 | Cyclohexanone | A | A | A | A |
| Example 14 | A-1 | B-30 | C-4 | Cyclohexanone | A | A | A | A |
| Example 15 | A-1 | B-57 | C-3 | Cyclohexanone | A | A | A | A |
| Example 16 | A-1 | B-47 | C-1 | Cyclohexanone | A | A | A | A |
| Example 17 | A-1 | B-48 | C-1 | Cyclohexanone | A | A | A | A |
| Example 18 | A-1 | B-30 | C-1 | Cyclopentanone | A | A | A | A |
| Comparative | A-1 | — | C-5 | PGMEA | C | A | A | C |
| Example 1 | | | | | | | | |
| Comparative | D-1 | B-30 | C-5 | PGMEA | B | C | B | B |
| Example 2 | | | | | | | | |

As clearly presented in Table 1, the composition (dispersion liquid) according to the invention had low viscosity and dispersibility of the coloring agent particles was satisfactory. The cured film obtained by using the curable composition according to the invention had excellent light fastness.

In contrast, in Comparative Examples 1 and 2, viscosity and light fastness were not compatible with each other.

Even if the pigment derivative was changed to B-2 to 21, 31 to 46, 49 to 56, and 58 to 60 in Example 1, the same effects in Example 1 was able to be obtained.

The reference numerals in the table above represent the following compounds.
Near-infrared absorption coloring agent

A-1: Structure below

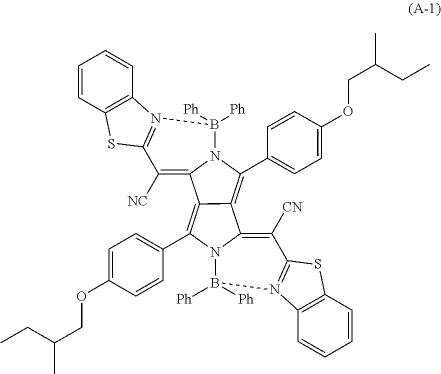

D-1: Structure below

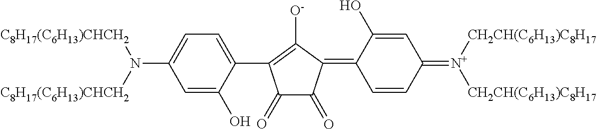

Coloring agent derivative

B-1, B-22 to B-30, 47, 48, and 57: Compounds (B-1), (B-22) to (B-30), (B-47), (B-48), and (B-57) described above
Dispersed resin

C-1 to C-5: Structure below

C-1 was a resin manufactured by using a macro monomer AA-6 manufactured by Toagosei Co., Ltd., and x/y/z=10/78/12 (mass %) and Mw: 19,700 were satisfied.

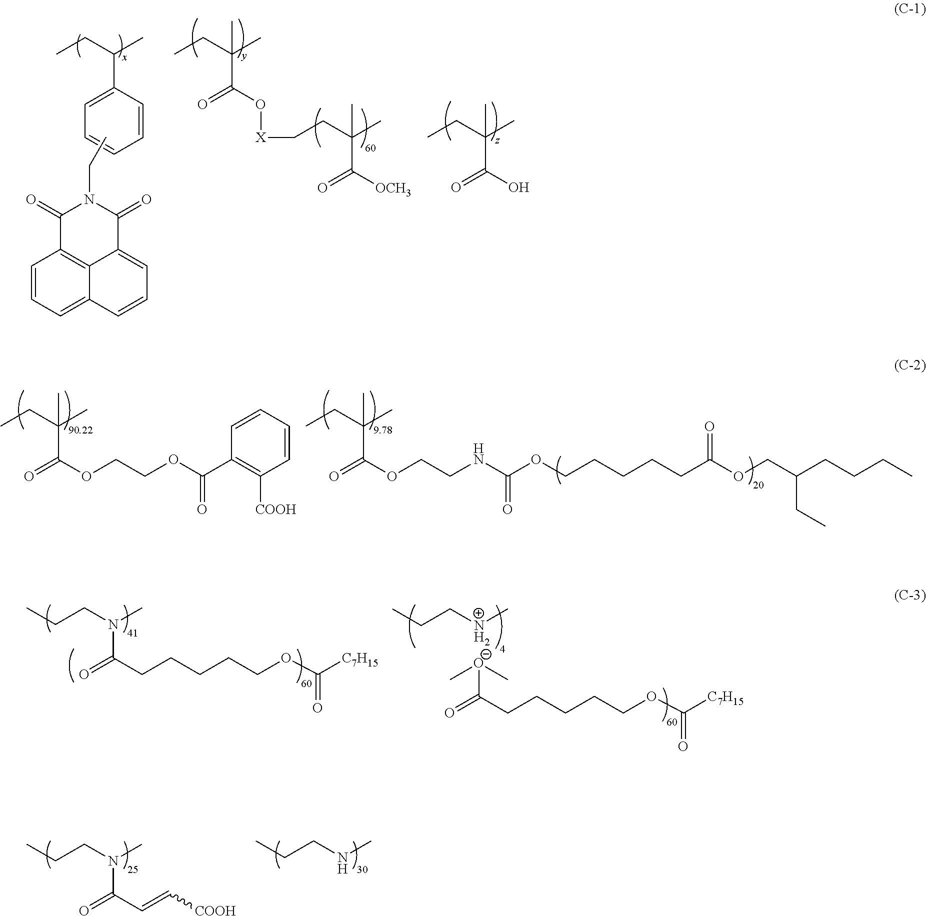

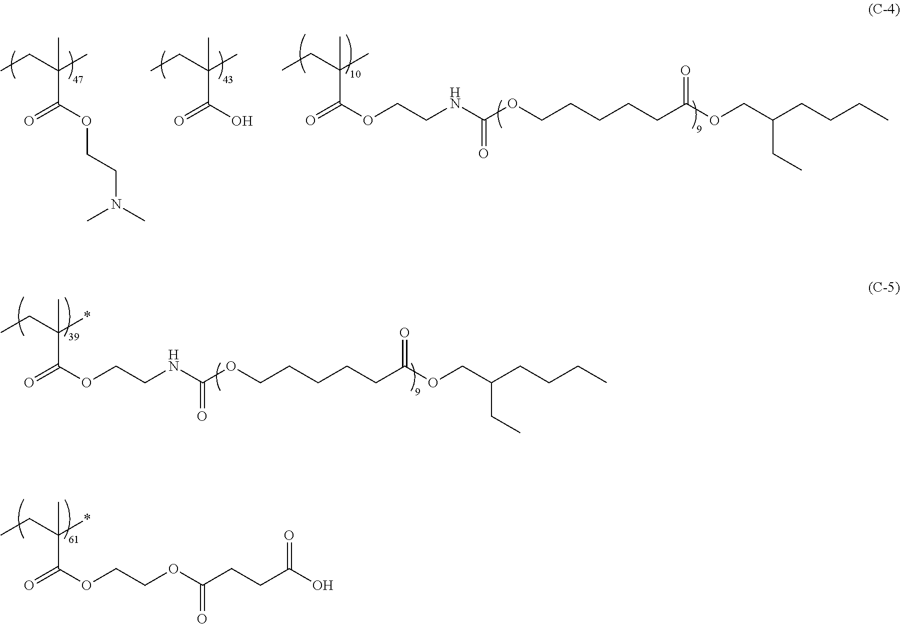

Solvent

PGMEA: Propylene glycol monomethyl ether acetate

[Preparation of Pigment Dispersion Liquids 1-1 and Manufacturing of 1-1]

The mixture liquid in the composition below was mixed and dispersed by using zirconia beads having a diameter of 0.3 mm with a beads mill (a high pressure disperser with a pressure reduction mechanism NANO-3000-10 (manufactured by Beryu corp.)) until a near-infrared absorption coloring agent had an average particle diameter represented in the table below, so as to prepare a pigment dispersion liquid. The amounts used (unit: parts by mass) of the corresponding components were represented in the table.

The average particle diameter of the near-infrared absorption coloring agent in the pigment dispersion liquid was measured in a volume basis by using MICROTRACUPA 150 manufactured by Nikkiso Co., Ltd. The measurement results are presented below.

[Preparation of Pigment Dispersion Liquids 2-1 and 2-2]

The mixture liquid in the composition below was mixed and dispersed for three hours by using zirconia beads having a diameter of 0.3 mm with a beads mill (a high pressure disperser with a pressure reduction mechanism NANO-3000-10 (manufactured by Beryu corp.)) so as to prepare a pigment dispersion liquid. The amounts used (unit: parts by mass) of the corresponding components were represented in the table.

TABLE 2

| | Colorant | | | | |
|---|---|---|---|---|---|
| | IR colorant | | | | |
| | | Average | | | |
| | | particle | Second | | |
| | Type | diameter (nm) | colorant | Resin | Organic solvent |
| Pigment | Compound (A-1) | 75 | | Dispersed resin | ANONE (84.0) |
| dispersion | (10.0) | | | 1 (6.0) | |
| liquid 1-1 | | | | | |
| Pigment | Compound (A-1) | 200 | | Dispersed resin | ANONE (84.0) |
| dispersion | (10.0) | | | 1 (6.0) | |
| liquid 1-2 | | | | | |
| Pigment | | | PR254 (9.0) | Dispersed resin | PGMEA (80.0) |
| dispersion | | | PY139 (4.0) | 2 (7.0) | |
| liquid 2-1 | | | | | |
| Pigment | | | PB15:6 (10.0) | Dispersed resin | PGMEA (50.0) |
| dispersion | | | PV23 (3.0) | 3 (3.0) | ANONE (34.0) |
| liquid 2-2 | | | | | |

Abbreviations of the respective components in the table are as below.

[Second Colorant (Colorant Having Absorption Maximum in a Wavelength Range of 400 to 700 nm)]
PR254: C. I. pigment red 254
PB15:6: C. I. pigment blue 15:6
PY139: C. I. pigment yellow 139
PV23: C. I. pigment violet 23

[Resin]
Dispersed resin 1: Structure below (Mw: 19,700, x/y/z=10/78/12 (mass %))

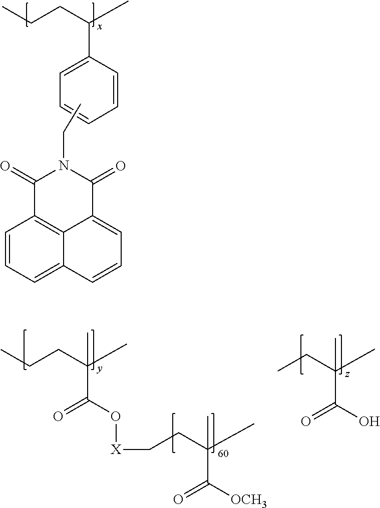

Dispersed resin 2: Structure below (Mw: 11,000)

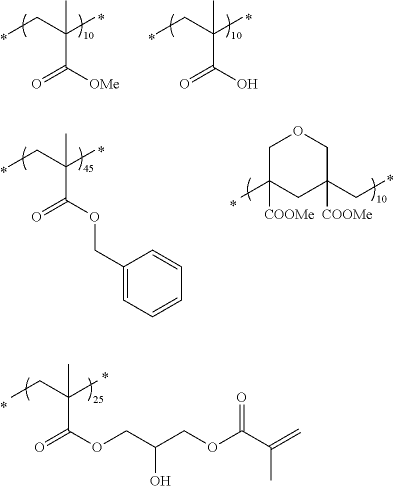

Dispersed resin 3: Structure below (Mw: 14,000)

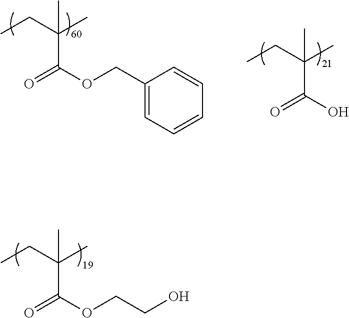

[Organic Solvent]
PGMEA: Propylene glycol methyl ether acetate
ANONE: Cyclohexanone

### Examples 19 and 20 and Comparative Example 3

[Preparing of Coloring Composition (Curable Composition)]

Components in the table below were mixed in a ratio presented in the table below, so as to prepare a coloring composition. In the table, amounts used (unit: parts by mass) of the corresponding components are presented.

TABLE 3

| | | | Comparative |
|---|---|---|---|
| | Example 19 | Example 20 | Example 3 |
| Pigment dispersion liquid 1-1 | 32.33 | | |
| Pigment dispersion liquid 1-2 | | 32.33 | |
| Pigment dispersion liquid 2-1 | 29.50 | 29.50 | 29.50 |
| Pigment dispersion liquid 2-2 | 23.79 | 23.79 | 23.79 |
| Polymerizable compound 1 | 1.73 | 1.73 | 2.85 |
| Alkali soluble resin 1 | 1.33 | 1.33 | 5.40 |
| Polymerization initiator 1 | 0.85 | 0.85 | 0.85 |
| Surfactant 1 | 0.04 | 0.04 | 0.04 |
| Polymerization inhibitor 1 | 0.001 | 0.001 | 0.001 |
| Organic solvent 1 | 10.43 | 10.43 | 37.57 |

Abbreviations of the respective components in the table are as below.
Polymerizable compound 1: KAYARAD DPHA (manufactured by Nippon Kayaku Co., Ltd.)
Alkali soluble resin 1: Structure below (Mw: 11,000)

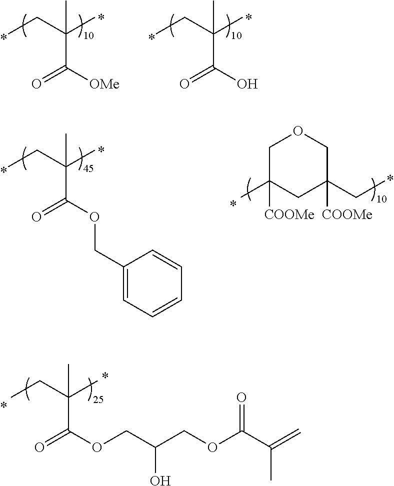

Polymerization initiator 1: Structure below

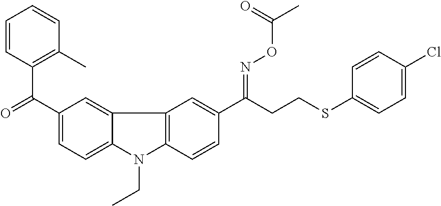 [SMILES: CCn1c2ccc(C(=O)c3ccccc3C)cc2c2cc(/C(CCSc3ccc(Cl)cc3)=N/OC(C)=O)ccc21]

Surfactant 1: MEGAFACE F-781F (manufactured by DIC Corporation, fluorine-containing polymer-type surfactant)
Polymerization inhibitor 1: p-methoxyphenol (manufactured by SANRITSU CHEMICALS)
Organic solvent 1: Propylene glycol methyl ether acetate

[Absorbance and Spectroscopic Properties]

A glass substrate was spin-coated with a coloring composition, coated such that a film thickness after post baking became 3.0 μm, and dried with a hot plate at 100° C. for 120 seconds, and a heating treatment (post baking) was further performed for 300 seconds by using a hot plate of 200° C.

Light transmittance at a wavelength range of 300 to 1,300 nm, the minimum value A of absorbance at a wavelength range of 400 to 830 nm, and the maximum value B of absorbance at a wavelength range of 1,000 to 1,300 nm were measured by using a substrate having a coloration layer and a ultraviolet-visible near-infrared spectrophotometer U-4100 (manufactured by Hitachi High-Technologies Corporation) (ref. glass substrate).

[Manufacturing of Color Filter]

Silicon wafers were coated with coloring compositions of Examples 19 and 20 and Comparative Example 3 by using a spin coater such that film thicknesses after drying were 1.0 μm, and a heating treatment (prebaking) was performed for 120 seconds by using a hot plate of 100° C.

Subsequently, a photo mask in which pixel patterns in a square shape having 1.4 jam on each side were formed by using the i-ray stepper exposure device FPA-3000i5+(manufactured by Canon Inc.) was used, an optimum exposure amount for resolving the pixel patterns in a square shape was determined by increasing from 50 to 750 mJ/cm² by 50 mJ/cm², and exposure was performed in this optimum exposure amount.

Thereafter, the silicon wafer on which the exposed coated film was formed was placed on a horizontal rotation table of a spin and shower developing machine (DW-30 type, manufactured by Chemitronics Co., Ltd.), puddle development was performed by using CD-2060 (manufactured by FUJIFILM Electronic Materials) at 23° C. for 60 seconds, and a colaration pattern was formed on the silicon wafer.

A rinse treatment was performed with pure water on the silicon wafer on which the colaration pattern was formed, and spray drying was performed.

A heating treatment (post baking) was performed for 300 seconds by using a hot plate of 200° C., so as to obtain a silicon wafer having a coloration pattern as each of Example 19 and 20 and Comparative Example 3.

<Evaluation>

[Heat Resistance]

A color filter was heated on a hot plate at 260° C. for 300 seconds. The transmittance (unit %) at a wavelength of 400 to 830 nm of light with respect to the color filter before and after heating was measured and the change of the transmittance was evaluated.

Change of transmittance=(transmittance after heating−transmittance before heating)

<Evaluation Standard>

3: A rate of the change of the transmittance before and after the heating was less than 3%

2: A rate of the change of the transmittance before and after the heating was 3% or greater and less than 5%

1: A rate of the change of the transmittance before and after the heating was 5% or greater

[Spectroscopic Recognition]

The obtained color filter was incorporated to the solid-state imaging device as a near-infrared filter by to a well-known method. The obtained solid-state imaging device was irradiated with a near-infrared LED light source having a light emitting wavelength of 940 nm under the circumstance of low illuminance (0.001 Lux), images were captured, and image properties were compared and evaluated. The evaluation standards were as below.

<Evaluation Standards>

3: An object was able to be clearly recognized on a satisfactory image.

2: An object was able to be recognized on a slightly satisfactory image.

1: An object was not able to be recognized on an unsatisfactory image.

TABLE 4

| | | | Maximum | Minimum | Minimum | Maximum | Absorbance |
|---|---|---|---|---|---|---|---|
| | Spectroscopic | Heat | transmittance | transmittance | absorbance | absorbance | ratio |
| | recognition | resistance | 400~830 nm | 1,000~1,300 nm | A: 400~830 nm | B: 1,000~1,300 nm | A/B |
| Example 19 | 3 | 3 | 0.50% | 84% | 2.32 | 0.07 | 33.1 |
| Example 20 | 3 | 3 | 3.49% | 71% | 1.46 | 0.15 | 9.7 |
| Comparative | 1 | 3 | 83% | 96% | 0.08 | 0.02 | 3.2 |
| Example 3 | | | | | | | |

All of Examples 19 and 20 in which the coloring composition according to the invention was used transmitted near-infrared rays at a light emitting wavelength of 940 nm in a state in which there were less noises caused by visible light and spectroscopic recognition was satisfactory. Subsequently, in Comparative Example 3, there were many noises caused by visible light and thus spectroscopic recognition was not satisfactory.

### Test Example 2

<Preparation 2 of Composition (Dispersion Liquid)>

2.1 parts by mass of a near-infrared absorbing coloring agent (A-1) subjected to a soft milling treatment, 4.3 parts by mass of another coloring agent (PR254), 1.9 parts by mass of a coloring agent derivative (B-1), 6.6 parts by mass of a dispersed resin (C-3), 85 parts by mass of a solvent (PGMEA), and 400 parts by mass of zirconia beads having a diameter of 0.5 mm were subjected to a dispersion treatment for 30 seconds with a paint shaker, filtration was performed by using DFA4201NXEY (0.45 μm nylon filter) manufactured by Nihon Pall Ltd., and the beads were separated by filtration, so as to prepare a composition (dispersion liquid) of Example 101.

With respect to the compositions in the other examples, respective components were mixed in ratios presented in the table below, and the compositions were prepared under the conditions above. The amounts used (unit: parts by mass) of the corresponding components in the table were presented.

TABLE 5

| | | | Coloring | | |
|---|---|---|---|---|---|
| | Near-infrared absorbing | Other coloring | agent | Dispersed | |
| | coloring agent | agent | derivative | resin | Solvent |
| Example 101 | A-1 (3.2) | PR254 (3.2) | B-30 (1.9) | C-7 (6.7) | PGMEA (85) |
| Example 102 | A-1 (3.4) | PB15:6 (3.4) | B-30 (0.7) | C-7 (7.5) | PGMEA (85) |
| Example 103 | A-1 (3.2) | PR254 (3.2) | B-30 (1.9) | C-1 (6.7) | PGMEA (85) |
| Example 104 | A-1 (3.4) | PB15:6 (3.4) | B-30 (0.7) | C-1 (7.5) | PGMEA (85) |
| Example 105 | A-1 (4.8) | PY139 (4.8) | B-27 (1.2) | C-5 (4.3) | PGMEA (85) |
| Example 106 | A-1 (4.8) | PY139 (4.8) | B-27 (1.2) | C-6 (4.3) | PGMEA (85) |
| Example 107 | A-1 (4.2) | PV23 (4.2) | B-57 (1.0) | C-3 (5.8) | PGMEA (85) |
| Example 108 | A-1 (3.2) | PR254 (3.2) | B-30 (1.9) | C-7 (6.7) | PGMEA (85) |
| Example 109 | A-1 (3.4) | PB15:6 (3.4) | B-30 (0.7) | C-7 (7.5) | Cyclohexanone |
| | | | | | (85) |
| Example 110 | A-1 (3.2) | PR254 (3.2) | B-30 (1.9) | C-1 (6.7) | Cyclohexanone |
| | | | | | (85) |
| Example 111 | A-1 (3.4) | PB15:6 (3.4) | B-30 (0.7) | C-1 (7.5) | Cyclohexanone |
| | | | | | (85) |
| Example 112 | A-1 (4.8) | PY139 (4.8) | B-27 (1.2) | C-5 (4.3) | Cyclohexanone |
| | | | | | (85) |
| Example 113 | A-1 (4.2) | PV23 (4.2) | B-57 (1.0) | C-3 (5.8) | Cyclohexanone |
| | | | | | (85) |
| Example 114 | A-1 (4.2) | PV23 (4.2) | B-57 (1.0) | C-6 (5.8) | Cyclohexanone |
| | | | | | (85) |
| Example 115 | A-1 (2.1) | PR254 (2.15) | B-30 (1.9) | C-7 (6.6) | PGMEA(85) |
| | | PB15:6 (2.15) | | | |
| Example 116 | A-1 (2.1) | PR254 (2.15) | B-30 (1.9) | C-7 (6.6) | Cyclohexanone |
| | | PB15:6 (2.15) | | | (85) |

The reference numerals in the table above represent the following compounds.
PR254: C. I. pigment red 254
PB15:6: C. I. pigment blue 15:6
PY139: C. I. pigment yellow 139
PV23: C. I. pigment violet 23
PGMEA: Propylene glycol methyl ether acetate
Dispersed resin C-1, C-3, and C-5: Dispersed resins C-1, C-3, and C-5 described above
Dispersed resin C-6 and C-7: Structures below

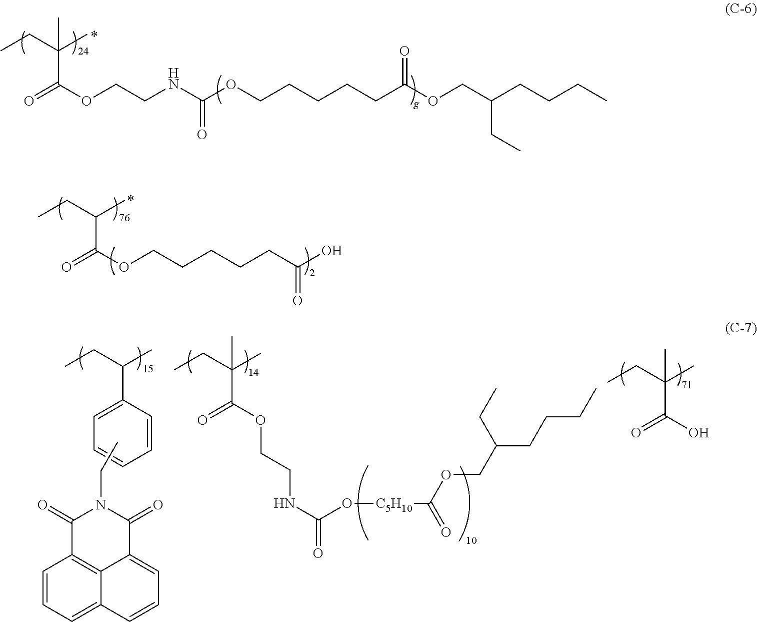

<Synthesis of Dispersed Resin (C-7)>

A dispersed resin (C-7) was synthesized by schemes below.

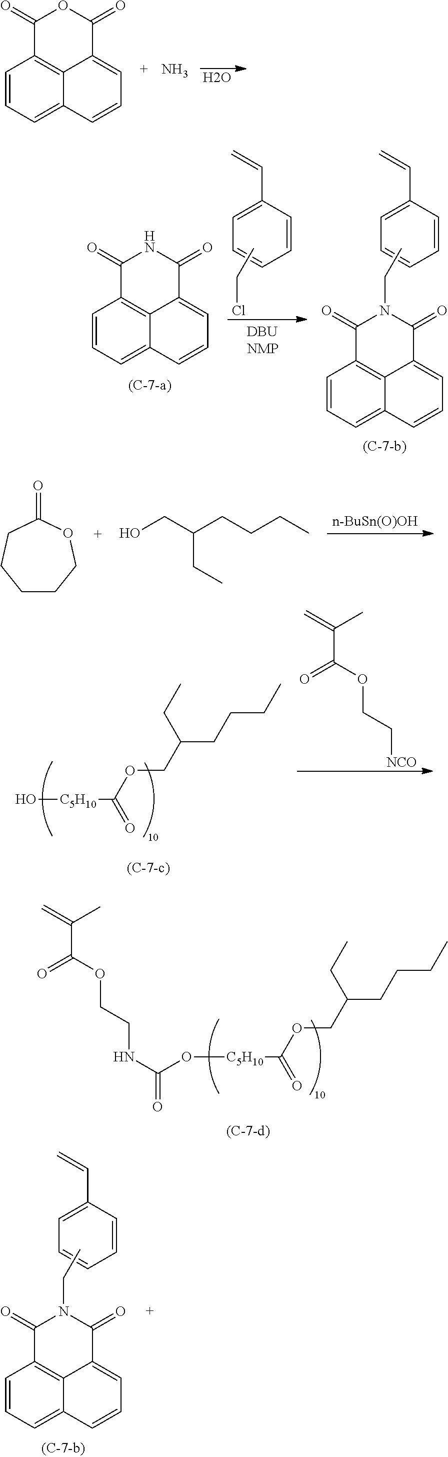

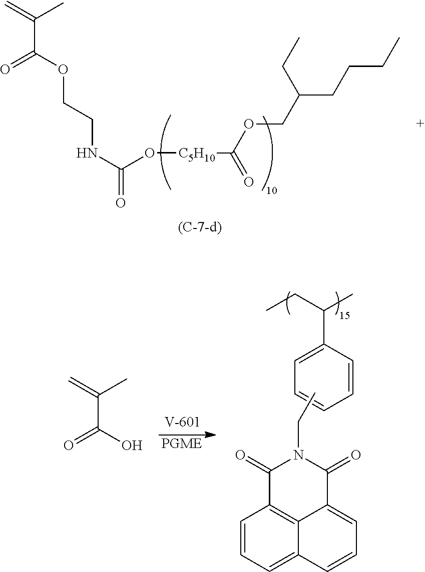

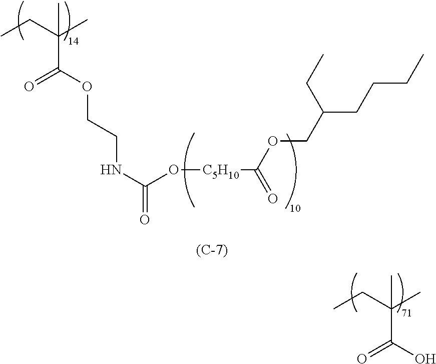

36 parts by mass of 28% aqueous ammonia, 39 parts by mass of 1,8-naphthalic anhydride, and 200 parts by mass of water were stirred at 75° C. for two hours, cooling was performed to 20° C., and precipitated crystals were filtrated and washed with 20 parts by mass of water and 20 parts by mass of methanol. The obtained crystals were subjected to blast drying at 40° C. for 20 hours, so as to obtain 36.1 parts by mass of (C-7-a). 34.5 parts by mass of (C-7-a), 40 parts by mass of chloromethylstyrene (CMS-P, manufactured by AGC Semi Chemical Co., Ltd.), 0.06 parts by mass of nitrobenzene, 29.3 parts by mass of diazabicycloundecene (DBU), and 145 parts by mass of N-methylpyrrolidone were stirred at 50° C. for four hours, cooling was performed to 30° C., and 272 parts by mass of methanol was added. After stirring was performed at 5° C. for 30 minutes, precipitated crystals were filtrated and washed with 150 parts by mass of methanol. If the obtained crystals were subjected to blast drying at 40° C. for 20 hours, so as to obtain 46.5 parts by mass of (C-7-b).

1,757 parts by mass of ε-caprolactone, 200 parts by mass of 2-ethylhexanol, and 0.9 parts by mass of monobutyl tin oxide were stirred at 90° C. for 5 hours, stirring was performed at 110° C. for 10 hours, so as to obtain (C-7-c). Cooling was performed to 80° C., 0.6 parts by mass of dibutylhydroxytoluene (BHT), and 242 parts by mass of KARENZMOI (manufactured by Showa Denko K.K.) were added and stirred at 80° C. for one hour. 2,200 parts by mass of propylene glycol monomethyl ether acetate (PGMEA) was added, and a 50 mass % solution of (C-7-d) was obtained.

65 parts by mass of (C-7-b), 700 parts by mass of a 50 mass % solution of (C-7-d), 85 parts by mass of methacrylic acid, 478 parts by mass of propylene glycol monomethyl ether (PGME), and 37.3 parts by mass of dodecanethiol were stirred in a nitrogen atmosphere at 80° C. 2.1 parts by mass of V-601 (manufactured by Wako Pure Chemical Industries, Ltd.) was added, an operation of stirring at 80° C. for two hours was performed three times, stirring was performed at 90° C. for two hours, and 644 parts by mass of PGMEA was added, so as to obtain 2,023 parts by mass of a 25 mass % solution of (C-7). A result of GPC measurement (tetrahydrofuran (THF) solution, in terms of standard polystyrene) was a weight-average molecular weight of 8,000, and a result of acid value measurement (THF/aqueous solution, titration liquid: 0.1 N NaOH aqueous solution) was 105 mgKOH/g.

<Preparation of Curable Composition>

After components described below were mixed, filtration was performed by using DFA4201NXEY (0.45 μm nylon filter) manufactured by Nihon Pall Ltd., so as to manufacture the curable composition.
Dispersion liquid described above: 13.5 parts by mass
Polymerizable compound: CYCLOMER P (ACA) 230AA (manufactured by Daicel Corporation): 25 parts by mass
Polymerizable compound: KAYARAD DPHA (manufactured by Nippon Kayaku Co., Ltd.): 3.2 parts by mass
Photopolymerization initiator: IRGACURE OXE01 (manufactured by BASF SE): 2 parts by mass
Polymerization inhibitor: p-Methoxyphenol: 0.001 parts by mass
   Surfactant: MEGAFACE F-781F (manufactured by DIC Corporation, fluorine-containing polymer-type surfactant): 0.004 parts by mass
Organic solvent: Propylene glycol monomethyl ether acetate: 56 parts by mass

A cured film was manufactured by applying the method of manufacturing the cured film of Test Example 1. The viscosity of the dispersion liquid, an average primary particle diameter and an average secondary particle diameter of the coloring agent particles included in the dispersion liquid right after the manufacturing, and light fastness of the cured film were evaluated by the evaluation method of Test Example 1. Thixotropy was evaluated by the method below. The thixotropy of the composition of Example 1 was evaluated.

<Thixotropy>

Viscosity of the dispersion liquid at 25° C. and at 20 rpm and 50 rpm was measured by using an E-type viscometer, and viscosity (20 rpm)/viscosity (50 rpm) was defined as a thixotropy index (TI value) and evaluated in the following standards.

A: A satisfactory TI value was 1 or greater and 1.3 or less

B: A slightly satisfactory TI value was greater than 1.3 and 1.5 or less

C: A sufficient TI value was greater than 1.5 and 2 or less

D: An unsatisfactory TI value was greater than 2

TABLE 6

| | | | Average | Average | |
|---|---|---|---|---|---|
| | Viscosity of | Light | primary | secondary | |
| | dispersion | fastness of | particle | particle | IT |
| | liquid | cured film | diameter | diameter | value |
| Example 101 | A | A | A | A | A |
| Example 102 | A | A | A | A | A |
| Example 103 | A | A | A | A | A |
| Example 104 | A | A | A | A | A |
| Example 105 | A | A | A | A | B |
| Example 106 | A | A | A | A | B |
| Example 107 | A | A | A | A | B |
| Example 108 | A | A | A | A | A |
| Example 109 | A | A | A | A | A |
| Example 110 | A | A | A | A | A |
| Example 111 | A | A | A | A | A |
| Example 112 | A | A | A | A | B |
| Example 113 | A | A | A | A | B |
| Example 114 | A | A | A | A | B |
| Example 115 | A | A | A | A | A |
| Example 116 | A | A | A | A | A |
| Example 1 | A | A | A | A | C |

As clearly understood from the results above, the composition (dispersion liquid) according to the invention has low viscosity and dispersibility of the coloring agent particles was satisfactory. The cured film obtained by using the curable composition according to the invention had excellent light fastness. It was found that Examples 101 to 116 obtained by codispersing the coloring agent represented by Formula (1) and the other coloring agents were excellent in view of thixotropy, compared with Example 1 obtained by dispersing the coloring agent represented by Formula (1) singly.

In Example 101, the same effect as Example 101 was able to be obtained even if the pigment derivative was changed to B-2 to 29, and 31 to 60. Even if a ratio of the near-infrared absorption coloring agent and the near-infrared absorption coloring agent in the other pigment in Example 101 was changed to 1 to 80 mass %, the effect of Example 101 was able to be obtained.

[Preparation of Pigment Dispersion Liquids 3-1, 3-2, and 3-3]

The mixture liquid of the composition below was mixed and dispersed with a beads mill (a high pressure dispersing machine with a pressure reduction mechanism NANO-3000-10 (manufactured by Beryu corp.)) by using zirconia beads having a diameter of 0.3 mm, until a near-infrared absorption coloring agent had an average particle diameter represented in the table below, so as to prepare a pigment dispersion liquid. In the table, amounts used of the corresponding components (unit: parts by mass) are presented.

TABLE 7

| | Colorant | | | | | |
|---|---|---|---|---|---|---|
| | IR colorant | | | Coloring | | |
| | | Average particle | Other coloring | agent | | Organic |
| | Type | diameter (nm) | agent | derivative | Resin | solvent |
| Pigment dispersion | Compound A-1 | 200 | PR254 (4.0) | B-30 (2.0) | C-7 (6.4) | PGMEA (85) |
| liquid 3-1 | (2.6) | | | | | |
| Pigment dispersion | Compound A-1 | 200 | PB15:6 (4.4) | | C-7 (7.7) | PGMEA (85) |
| liquid 3-2 | (2.9) | | | | | |
| Pigment dispersion | Compound A-1 | 200 | PR254 (2.1) | B-30 (1.9) | C-7 (6.8) | PGMEA (85) |
| liquid 3-3 | (2.1) | | PB15:6 (2.1) | | | |

### Examples 117 and 118

[Preparation of Curable Composition (Coloring Composition)]

The components of the table below were mixed in ratios presented in the table, so as to prepare the coloring composition. In the table, amounts used of the corresponding components (unit: parts by mass) are presented.

TABLE 8

| | Example 117 | Example 118 |
|---|---|---|
| Pigment dispersion liquid 3-1 | 49.77 | |
| Pigment dispersion liquid 3-2 | 40.84 | |
| Pigment dispersion liquid 3-3 | | 95.04 |
| Polymerizable compound 1 | 1.96 | 1.84 |
| Alkali soluble resin 1 | 1.51 | 1.02 |
| Polymerization initiator 1 | 0.941 | 0.883 |
| Surfactant 1 | 0.04 | 0.04 |
| Polymerization inhibitor 1 | 0.001 | 0.001 |
| Organic solvent 1 | 4.94 | 1.18 |

A polymerizable compound 1, an alkali soluble resin 1, a polymerization initiator 1, a polymerization inhibitor 1, a surfactant 1, and an organic solvent 1 are materials described in the preparation of the coloring composition of Test Example 1.

Color filters were manufactured by using the coloring compositions of Examples 117 and 118 in the same manner as Examples 19 and 20, and the evaluation of the heat resistance and the spectroscopic recognition was performed in the same manner as Examples 19 and 20, such that satisfactory results were able to be obtained as in Examples 19 and 20.

<Preparation of Curable Composition (Near-Infrared Absorbing Composition)>

Components below were mixed, so as to prepare the near-infrared absorbing composition of Example 201. In the near-infrared absorbing composition of Example 201, the dispersion liquid of Example 101 was changed to dispersion liquids of Examples 102 to 116, so as to prepare the near-infrared absorbing compositions of Examples 202 to 216.
Dispersion liquid of Example 101: 28.0 parts by mass
Polymerizable compound 1: 6.83 parts by mass
Alkali soluble resin 1: 6.73 parts by mass
Polymerization initiator 1: 1.96 parts by mass
Polymerization inhibitor 1: 0.003 parts by mass
Surfactant 1: 0.04 parts by mass
Organic solvent 1: 56.44 parts by mass

The polymerizable compound 1, the alkali soluble resin 1, the polymerization initiator 1, the polymerization inhibitor 1, the surfactant 1, and the organic solvent 1 were materials described in the preparation of the coloring composition of Test Example 1.

<Manufacturing of Cured Film>

The glass substrate was coated with the near-infrared absorbing composition by a spin coating method, a hardening treatment was performed by using a hot plate at 100° C. for two minutes and at 230° C. for five minutes, so as to obtain a cured film of about 2.0 μm.

<Near-Infrared Shielding Evaluation>

Spectral transmittance of the cured film manufactured above was measured by using a spectrophotometer U-4100 (manufactured by Hitachi High-Technologies Corporation). It was found that, in the cured film of Example 201, minimum transmittance at a wavelength of 500 to 600 nm was 85%, maximum transmittance at a wavelength of 800 to 850 nm was 10%, minimum transmittance at a wavelength of 1,000 to 1,300 nm was 90% or greater. The same spectrums were able to be obtained in Examples 202 to 216. According to the invention, it was understood that high near-infrared shielding properties were able to be obtained when the curable composition was formed to a cured film.

### Test Example 3

<Preparation of Composition (Dispersion Liquid)>

After 10 parts by mass of a near-infrared absorbing coloring agent subjected to the soft milling treatment, 3.0 parts by mass of a coloring agent derivative presented in the table below, 7.8 parts by mass of a dispersed resin presented in the table below, 109 parts by mass of a solvent presented in the table below, and 520 parts by mass of zirconia beads having a diameter of 0.5 mm presented in the table below were subjected to a dispersion treatment with a paint shaker for 30 minutes, filtration was performed by using DFA4201NXEY (0.45 μm nylon filter) manufactured by Nihon Pall Ltd., and beads were separated by filtration so as to prepare the composition (dispersion liquid).

The curable composition was prepared by using the obtained composition (dispersion liquid) in the same manner as Test Example 1, and a cured film was manufactured by applying the method of manufacturing the cured film of Test Example 1. Viscosity of the dispersion liquid, an average primary particle diameter and an average secondary particle diameter of the coloring agent particles included in the dispersion right after the manufacturing, and light fastness of the cured film were evaluated by the evaluation method of Test Example 1.

The reference numerals in the table below represent the following compounds.

A-1 to A-10: Compounds described above

B-1, B-30, B-57, B-58, and B-60: Compounds described above

B-61 and B-62: Structures below

C-3, C-4, C-5, and C-7: Dispersed resins described above

C-8: Structure below (weight-average molecular weight=13,800, acid value=6 mgKOH/g, amine value=106 mgKOH/g)

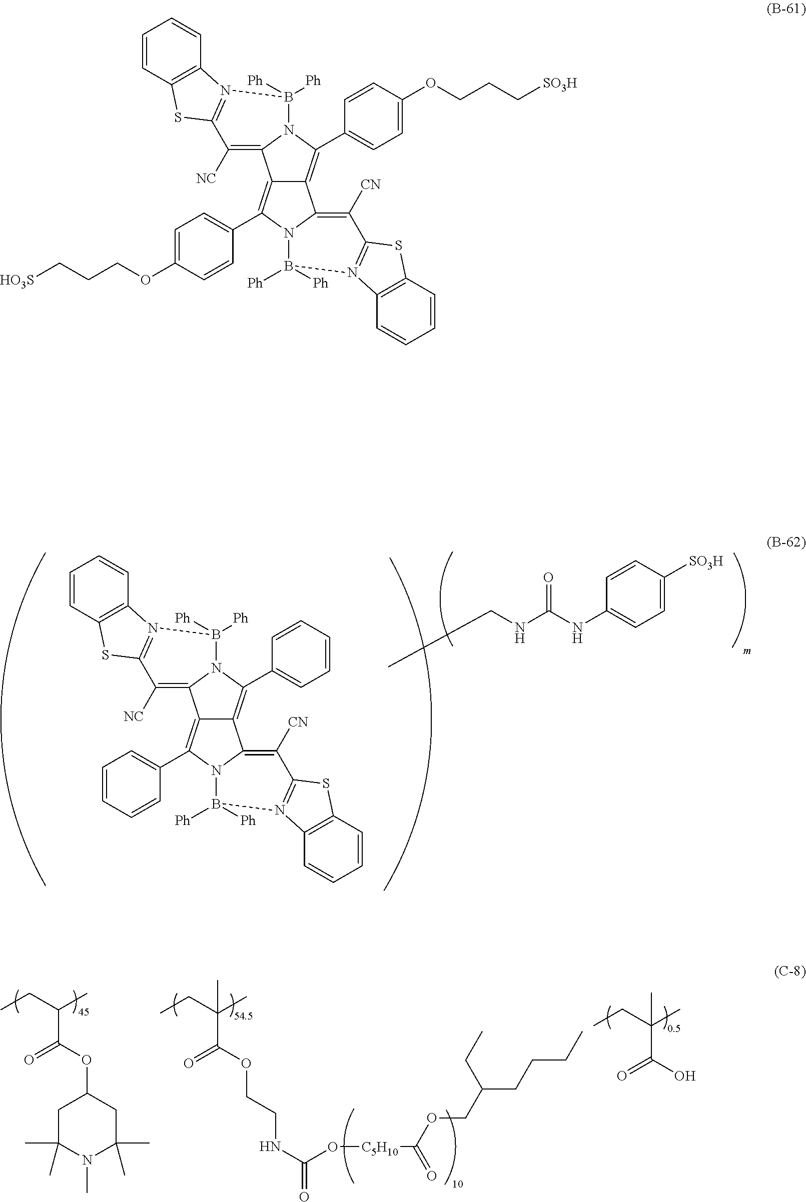

TABLE 9

| | | | | | Viscosity | Light | Average | Average |
|---|---|---|---|---|---|---|---|---|
| | Near-infrared | | | | of | fastness | primary | secondary |
| | absorption | Pigment | Dispersed | | dispersion | of cured | particle | particle |
| | coloring agent | derivative | resin | Solvent | liquid | film | diameter | diameter |
| Example 301 | A-1 | B-1 | C-8 | PGMEA | A | A | A | A |
| Example 302 | A-1 | B-57 | C-8 | PGMEA | A | A | A | A |
| Example 303 | A-1 | B-60 | C-8 | PGMEA | A | A | A | A |
| Example 304 | A-1 | B-61 | C-3 | PGMEA | A | A | A | A |
| Example 305 | A-1 | B-61 | C-4 | PGMEA | A | A | A | A |
| Example 306 | A-1 | B-61 | C-8 | PGMEA | A | A | A | A |
| Example 307 | A-1 | B-62 | C-3 | PGMEA | A | A | A | A |
| Example 308 | A-1 | B-62 | C-4 | PGMEA | A | A | A | A |
| Example 309 | A-1 | B-62 | C-8 | PGMEA | A | A | A | A |
| Example 310 | A-2 | B-30 | C-5 | PGMEA | A | A | A | A |
| Example 311 | A-2 | B-58 | C-7 | PGMEA | A | A | A | A |
| Example 312 | A-2 | B-57 | C-3 | PGMEA | A | A | A | A |
| Example 313 | A-2 | B-60 | C-8 | PGMEA | A | A | A | A |
| Example 314 | A-3 | B-30 | C-5 | PGMEA | A | A | A | A |
| Example 315 | A-3 | B-58 | C-7 | PGMEA | A | A | A | A |
| Example 316 | A-3 | B-57 | C-3 | PGMEA | A | A | A | A |
| Example 317 | A-3 | B-60 | C-8 | PGMEA | A | A | A | A |
| Example 318 | A-4 | B-30 | C-5 | PGMEA | A | A | A | A |
| Example 319 | A-4 | B-58 | C-7 | PGMEA | A | A | A | A |
| Example 320 | A-4 | B-57 | C-3 | PGMEA | A | A | A | A |
| Example 321 | A-4 | B-60 | C-8 | PGMEA | A | A | A | A |
| Example 322 | A-5 | B-30 | C-5 | PGMEA | A | A | A | A |
| Example 323 | A-5 | B-58 | C-7 | PGMEA | A | A | A | A |
| Example 324 | A-5 | B-57 | C-3 | PGMEA | A | A | A | A |
| Example 325 | A-5 | B-60 | C-8 | PGMEA | A | A | A | A |
| Example 326 | A-6 | B-30 | C-5 | PGMEA | A | A | A | A |
| Example 327 | A-6 | B-58 | C-7 | PGMEA | A | A | A | A |
| Example 328 | A-6 | B-57 | C-3 | PGMEA | A | A | A | A |
| Example 329 | A-6 | B-60 | C-8 | PGMEA | A | A | A | A |
| Example 330 | A-7 | B-30 | C-5 | PGMEA | A | A | A | A |
| Example 331 | A-7 | B-58 | C-7 | PGMEA | A | A | A | A |
| Example 332 | A-7 | B-57 | C-3 | PGMEA | A | A | A | A |
| Example 333 | A-7 | B-60 | C-8 | PGMEA | A | A | A | A |
| Example 334 | A-8 | B-30 | C-5 | PGMEA | A | A | A | A |
| Example 335 | A-8 | B-58 | C-7 | PGMEA | A | A | A | A |
| Example 336 | A-8 | B-57 | C-3 | PGMEA | A | A | A | A |
| Example 337 | A-8 | B-60 | C-8 | PGMEA | A | A | A | A |
| Example 338 | A-9 | B-30 | C-5 | PGMEA | A | A | A | A |
| Example 339 | A-9 | B-58 | C-7 | PGMEA | A | A | A | A |
| Example 340 | A-9 | B-57 | C-3 | PGMEA | A | A | A | A |
| Example 341 | A-9 | B-60 | C-8 | PGMEA | A | A | A | A |
| Example 342 | A-10 | B-30 | C-5 | PGMEA | A | A | A | A |
| Example 343 | A-10 | B-58 | C-7 | PGMEA | A | A | A | A |
| Example 344 | A-10 | B-57 | C-3 | PGMEA | A | A | A | A |
| Example 345 | A-10 | B-60 | C-8 | PGMEA | A | A | A | A |

As clearly understood from the results above, the composition (dispersion liquid) according to the invention had low viscosity and satisfactory dispersibility of the coloring agent particles. The cured film obtained by using the curable composition according to the invention had excellent light fastness.

<Preparation of Curable Composition (Near-Infrared Absorbing Composition)>

The components below were mixed so as to prepare a near-infrared absorbing composition of Example 401. In the near-infrared absorbing composition of Example 401, the dispersion liquid of Example 301 was changed to dispersion liquids of Examples 302 to 345, so as to prepare near-infrared absorbing compositions of Examples 402 to 445.
Dispersion liquid of Example 301: 28.0 parts by mass
Polymerizable compound 1: 6.83 parts by mass
Alkali soluble resin 1: 6.73 parts by mass
Polymerization initiator 1: 1.96 parts by mass
Polymerization inhibitor 1: 0.003 parts by mass
Surfactant 1: 0.04 parts by mass
Organic solvent 1: 56.44 parts by mass

The polymerizable compound 1, the alkali soluble resin 1, the polymerization initiator 1, the polymerization inhibitor 1, the surfactant 1, and the organic solvent 1 were materials described in the preparation of the coloring composition of Test Example 1.

<Method of Manufacturing Cured Film>

A glass substrate was coated with a near-infrared absorbing composition by a spin coating method, a hardening treatment was thereafter performed by using a hot plate, at 100° C. for two minutes and at 230° C. for five minutes, so as to obtain a cured film of about 2.0 μm.

<Near-Infrared Shielding Evaluation>

The spectral transmittance of the cured film manufactured above was measured by using a spectrophotometer U-4100 (manufactured by Hitachi High-Technologies Corporation). It was understood that, in the cured films of Examples 401 to 441, minimum transmittance at a wavelength of 500 to 600 nm was 85%, maximum transmittance at a wavelength of 800 to 850 nm was 10%, and minimum transmittance at a wavelength of 1,000 to 1,300 nm was 90% or greater. It was understood that, in the cured films of Examples 442 to 445, minimum transmittance at a wavelength of 600 to 700 nm was 85%, maximum transmittance at a wavelength of 900 to 950 nm was 10%, and minimum transmittance at a wavelength of 1,100 to 1,300 nm was 90% or greater. According to the invention, it was found that it was possible to form a cured film having high near-infrared shielding properties.

### EXPLANATION OF REFERENCES

110: solid-state imaging device
111: near-infrared cut filter
112: color filter
113: infrared transmission filter
114: range
115: microlens
116: planarizing layer
201: lens optical system
210: solid-state imaging device
220: signal processing unit
230: signal switching unit
240: controller
250: signal accumulating unit
260: light emitting controller
280, 281: image output unit

What is claimed is:

1. A composition comprising:
particles including a coloring agent represented by Formula (1),
wherein an average secondary particle diameter of the particles is 500 nm or less, 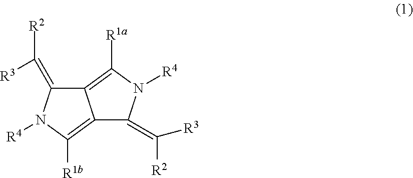
in Formula (1), R^{1a} and R^{1b} each independently represent an alkyl group, an aryl group, or a heteroaryl group,
R² and R³ each independently represent a hydrogen atom or a substituent, and R² and R³ may be bonded to each other to form a ring,
R⁴'s each independently represent a hydrogen atom, an alkyl group, an aryl group, a heteroaryl group, —BR^{4A}R^{4B}, or a metal atom, and R⁴'s may form a covalent bond or a coordinate bond with at least one selected form R^{1a}, R^{1b}, and R³, and
R^{4A} and R^{4B} each independently represent a hydrogen atom or a substituent.

2. The composition according to claim 1, further comprising:
a coloring agent derivative represented by Formula (2) below, 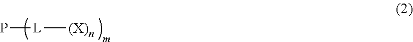
in Formula (2), P represents a coloring agent structure, L represents a single bond or a linking group, X represents an acidic group, a basic group, a group having a salt structure, or a phthalimide group, m represents an integer of 1 or greater, n represents an integer of 1 or greater, and in a case where m is 2 or greater, plural L's and plural X's may be different from each other, and in a case where n is 2 or greater, plural X's may be different from each other.

3. A composition comprising:
a coloring agent represented by Formula (1); and
a coloring agent derivative represented by Formula (2) below, 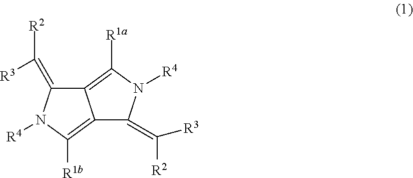
in Formula (1), R^{1a} and R^{1b} each independently represent an alkyl group, an aryl group, or a heteroaryl group,
R² and R³ each independently represent a hydrogen atom or a substituent, and R² and R³ may be bonded to each other to form a ring,
R⁴'s each independently represent a hydrogen atom, an alkyl group, an aryl group, a heteroaryl group, —BR^{4A}R^{4B}, or a metal atom, and R⁴'s may form a covalent bond or a coordinate bond with at least one selected from R^{1a}, R^{1b}, and R³, and
R^{4A} and R^{4B} each independently represent a hydrogen atom or a substituent, and 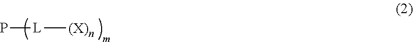
in Formula (2), P represents a coloring agent structure, L represents a single bond or a linking group, X represents an acidic group, a basic group, a group having a salt structure, or a phthalimide group, m represents an integer of 1 or greater, n represents 1 or greater, in a case where m is 2 or greater, plural L's and plural X's may be different from each other, and in a case where n is 2 or greater, plural X's may be different from each other.

4. The composition according to claim 1,
wherein the composition has viscosity of 100 mPa·s or less at 25° C.

5. The composition according to claim 2,
wherein, in Formula (2), P is at least one selected from a pyrrolopyrrole coloring agent structure, a diketopyrrolopyrrole coloring agent structure, a quinacridone coloring agent structure, an anthraquinone coloring agent structure, a dianthraquinone coloring agent structure, a benzoisoindole coloring agent structure, a thiazine indigo coloring agent structure, an azo coloring agent structure, a quinophthalone coloring agent structure, a phthalocyanine coloring agent structure, a dioxazine coloring agent structure, a perylene coloring agent structure, a perinone coloring agent structure, and a benzimidazolinone coloring agent structure.

6. The composition according to claim 2,
wherein, in Formula (2), P is at least one selected from a pyrrolopyrrole coloring agent structure, a diketopyrrolopyrrole coloring agent structure, a quinacridone coloring agent structure, and a benzimidazolinone coloring agent structure.

7. The composition according to claim 2,
wherein, in Formula (2), X is at least one selected from a carboxyl group, a sulfo group, a phthalimide group, and groups represented by Formulae (X-1) to (X-9), 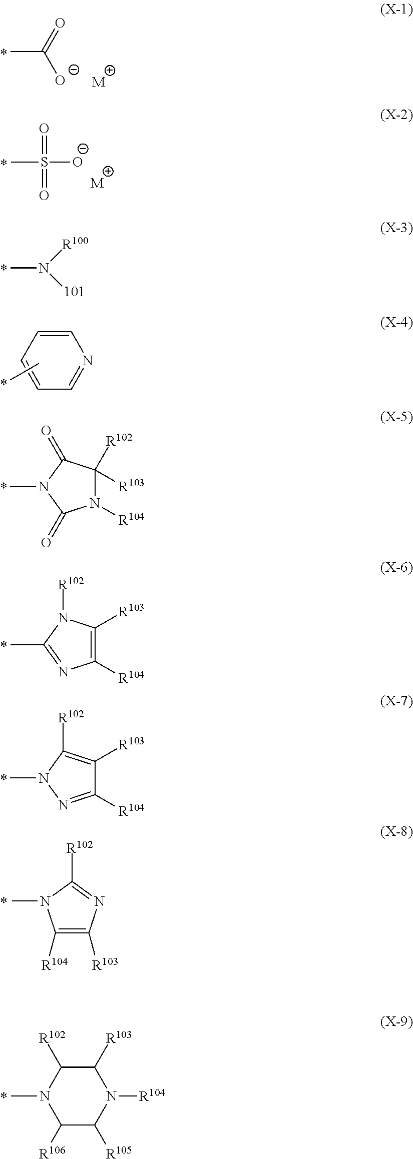
in Formulae (X-1) to (X-9), * represents a coupler hand with L of Formula (2), R¹⁰⁰ to R¹⁰⁶ each independently represent a hydrogen atom, an alkyl group, an alkenyl group, or an aryl group, R¹⁰⁰ and R¹⁰¹ may be linked to each other to form a ring, and M represents an atom or an atomic group that forms an anion or salt.

8. The composition according to claim 2,
wherein the coloring agent derivative is a compound represented by Formula (3), 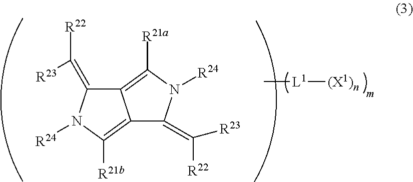
in Formula (3), R^{21a} and R^{21b} each independently represent an alkyl group, an aryl group, or a heteroaryl group,
R²² and R²³ each independently represent a cyano group, an acyl group, an alkoxycarbonyl group, an alkyl group, an arylsulfinyl group, or a heteroaryl group, and R²² and R²³ may be bonded to each other to form a ring,
R²⁴'s each independently represent a hydrogen atom, an alkyl group, an aryl group, a heteroaryl group, —BR^{24A}R^{24B}, or a metal atom, and R²⁴'s may form a covalent bond or a coordinate bond with at least one selected from R^{21a}, R^{21b}, and R²³,
R^{24A} and R^{24B} each independently represent a hydrogen atom, a halogen atom, an alkyl group, an aryl group, or a heteroaryl group,
L¹ represents a single bond or a linking group consisting of an alkylene group, a nitrogen-containing heterocyclic group, —NR′—, —CO—, or —SO₂—, and a combination thereof,
R represents a hydrogen atom, an alkyl group, or an aryl group,
X¹ represents an acidic group, a basic group, a group having a salt structure, or a phthalimide group,
m represents an integer of 1 or greater, n represents an integer of 1 or greater, in a case where m is 2 or greater, plural L¹'s and plural X¹'s may be different from each other, and in a case where n is 2 or greater, plural X¹'s may be different from each other.

9. The composition according to claim 2,
wherein 1 to 30 parts by mass of the coloring agent derivative represented by Formula (2) with respect to 100 parts by mass of the coloring agent represented by Formula (1) is included.

10. The composition according to claim 1,
wherein a maximum absorption wavelength of the coloring agent represented by Formula (1) is in a range of 700 to 1,200 nm.

11. The composition according to claim 1,
wherein an average primary particle diameter of particles including the coloring agent represented by Formula (1) is 5 to 100 nm.

12. The composition according to claim 1, further comprising:
at least one selected from a resin, an organic solvent, and a coloring agent different from the coloring agent represented by Formula (1).

13. A method of manufacturing composition comprising:
dispersing a coloring agent represented by Formula (1) and a coloring agent other than the coloring agent represented by Formula (1) in presence of at least one selected from a resin and an organic solvent, 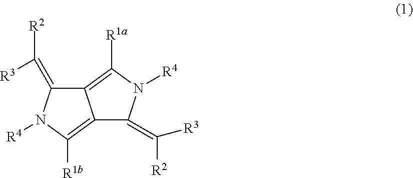
in Formula (1), R^{1a} and R^{1b} each independently represent an alkyl group, an aryl group, or a heteroaryl group,
R² and R³ each independently represent a hydrogen atom or a substituent, and R² and R³ may be bonded to each other to form a ring,
R⁴'s each independently represent a hydrogen atom, an alkyl group, an aryl group, a heteroaryl group, —BR^{4A}R^{4B}, or a metal atom, and R⁴'s may form a covalent bond or a coordinate bond with at least one selected from R^{1a}, R^{1b}, and R³, and
R^{4A} and R^{4B} each independently represent a hydrogen atom or a substituent.

14. The method of manufacturing a composition according to claim 13,
wherein the dispersion is further performed in presence of a coloring agent derivative represented by Formula (2), 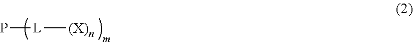
in Formula (2), P represents a coloring agent structure, L represents a single bond or a linking group, X represents an acidic group, a basic group, a group having a salt structure, or a phthalimide group, m represents an integer of 1 or greater, n represents an integer of 1 or greater, in a case where m is 2 or greater, plural L's and plural X's may be different from each other, and in a case where n is 2 or greater, plural X's may be different from each other.

15. A curable composition comprising:
the composition according to claim 1; and
a curable compound.

16. The curable composition according to claim 15, further comprising:
a photopolymerization initiator,
wherein the curable compound is a polymerizable compound.

17. A cured film obtained by hardening the curable composition according to claim 15.

18. A near-infrared cut filter obtained by using the curable composition according to claim 15.

19. A solid-state imaging device comprising:
a cured film obtained by using the curable composition according to claim 15.

20. An infrared sensor comprising:
the cured film obtained by using the curable composition according to claim 15.

21. A camera module comprising:
a solid-state imaging device; and
the near-infrared cut filter according to claim 18.

22. A compound represented by Formula (3) below, 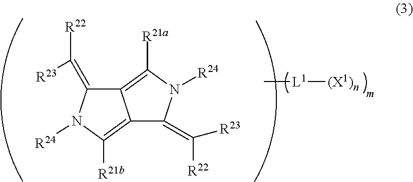
in Formula (3), R^{21a} and R^{21b} each independently represent an alkyl group, an aryl group, or a heteroaryl group,
R²² and R²³ each independently represent a cyano group, an acyl group, an alkoxycarbonyl group, an alkyl group, an arylsulfinyl group, or a heteroaryl group, and R²² and R²³ may be bonded to each other to form a ring,
R²⁴'s each independently represent a hydrogen atom, an alkyl group, an aryl group, a heteroaryl group, —BR^{24A}R^{24B}, or a metal atom, and R²⁴'s may form a covalent bond or a coordinate bond with at least one selected from R^{21a}, R^{21b,} and R²³,
R^{24A} and R^{24B} each independently represent a hydrogen atom, a halogen atom, an alkyl group, an aryl group, or a heteroaryl group,
L¹ represents a single bond or a linking group consisting of an alkylene group, a nitrogen-containing heterocyclic group, —NR′—, —CO—, or —SO₂—, and a combination thereof,
R′ represents a hydrogen atom, an alkyl group, or an aryl group,
X¹ represents an acidic group, a basic group, a group having a salt structure, or a phthalimide group,
m represents an integer of 1 or greater, n represents an integer of 1 or greater, in a case where m is 2 or greater, plural L¹'s and plural X¹'s may be different from each other, and in a case where n is 2 or greater, plural X¹'s may be different from each other.
